(19) United States
(12) Patent Application Publication
(10) Pub. No.: US 2026/0059740 A1
(43) Pub. Date: Feb. 26, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tsutomu MURAKAWA, Isehara (JP); Motomu KURATA, Isehara (JP)

(21) Appl. No.: 19/121,242

(22) PCT Filed: Sep. 19, 2023
(86) PCT No.: PCT/IB2023/059255

§ 371 Date: Apr. 15, 2025

(30) Foreign Application Priority Data
Nov. 11, 2022 (JP) 2022-180865
Nov. 11, 2022 (JP) 2022-180870

(51) Int. Cl. H10B 12/00

(52) U.S. Cl. CPC H10B 12/31

(57) ABSTRACT

A semiconductor device that can be miniaturized or highly integrated is provided. The semiconductor device includes a first insulator, an oxide semiconductor over the first insulator, a first conductor, a second conductor, and a third insulator over the oxide semiconductor, a second insulator over the first insulator, the first conductor, and the second conductor, and a third conductor over the third insulator. The oxide semiconductor includes a first region overlapping with the first conductor, a second region overlapping with the second conductor, and a third region positioned between the first region and the second region. The second insulator includes an opening portion in a region overlapping with the third region, and the third insulator and the third conductor are provided in the opening portion. The first region and the second region are in contact with the first insulator and the second insulator, and the third region is in contact with the first insulator and the third insulator. The first insulator and the second insulator contain silicon and nitrogen.

### TECHNICAL FIELD

One embodiment of the present invention relates to a semiconductor device, a storage device, and an electronic appliance. Another embodiment of the present invention relates to a method for manufacturing the semiconductor device.

Note that one embodiment of the present invention is not limited to the above technical field. Examples of the technical field of one embodiment of the present invention include a semiconductor device, a display device, a light-emitting device, a power storage device, a storage device, an electronic appliance, a lighting device, an input device (e.g., a touch sensor), an input/output device (e.g., a touch panel), a method for driving any of them, and a method for manufacturing any of them.

Note that in this specification and the like, a semiconductor device refers to a general device that can function by utilizing semiconductor characteristics. A semiconductor element such as a transistor, a semiconductor circuit, an arithmetic device, and a storage device are each an embodiment of a semiconductor device. It can be sometimes said that a display device (e.g., a liquid crystal display device and a light-emitting display device), a projection device, a lighting device, an electro-optical device, a power storage device, a storage device, a semiconductor circuit, an imaging device, an electronic appliance, and the like include a semiconductor device.

### BACKGROUND ART

In recent years, the development of semiconductor devices has progressed, and LSIs (Large Scale Integrated Circuits), CPUs (Central Processing Units), memories, and the like are mainly used as the semiconductor devices. A CPU is an aggregation of semiconductor elements; the CPU includes a semiconductor integrated circuit (including at least a transistor and a capacitor) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. Furthermore, for example, Patent Document 2 discloses a storage device that can retain stored contents for a long time by utilizing a feature of a low leakage current of the transistor using an oxide semiconductor.

In recent years, demand for an integrated circuit with higher density has risen with reductions in size and weight of electronic appliances. Furthermore, the productivity of a semiconductor device including an integrated circuit is required to be improved. For example, Patent Document 3 and Non-Patent Document 1 disclose a technique to achieve an integrated circuit with higher density by making a plurality of memory cells overlap with each other by stacking a first transistor using an oxide semiconductor film and a second transistor using an oxide semiconductor film. Furthermore, for example, Patent Document 4 discloses a technique for achieving an integrated circuit with a higher density by placing a channel of a transistor using an oxide semiconductor film in the vertical direction.

### REFERENCE

### Patent Document

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be miniaturized or highly integrated. Another object of one embodiment of the present invention is to provide a semiconductor device that operates at high speed. Another object of one embodiment of the present invention is to provide a semiconductor device with favorable electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device. Another object of one embodiment of the present invention is to provide a method for manufacturing a semiconductor device with high productivity. Another object of one embodiment of the present invention is to provide a method for manufacturing a novel semiconductor device.

Another object of one embodiment of the present invention is to provide a storage device that can be miniaturized or highly integrated. Another object of one embodiment of the present invention is to provide a storage device with a large storage capacity. Another object of one embodiment of the present invention is to provide a storage device that operates at high speed. Another object of one embodiment of the present invention is to provide a storage device with low power consumption. Another object of one embodiment of the present invention is to provide a novel storage device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including a first insulator; an oxide semiconductor over the first insulator; a first conductor and a second conductor over the oxide semiconductor; a second insulator over the first insulator, the first conductor, and the second conductor; a third insulator over the oxide semiconductor; and a third conductor over the third insulator. The oxide semiconductor includes a first region overlapping with the first conductor, a second region overlapping with the second conductor, and a third region positioned between the first region and the second region. The second insulator includes an opening portion in a region overlapping with the third region. At least part of each of the third insulator and the third conductor is provided in the opening portion. Each of the first region and the second region is in contact with the first insulator and the second insulator. The third region is in contact with the first insulator and the third insulator. Each of the first insulator and the second insulator contains silicon and nitrogen. The first insulator includes a region with a thickness greater than or equal to 1.0 nm and less than or equal to 5.0 nm.

One embodiment of the present invention is a semiconductor device including a first insulator; an oxide semiconductor over the first insulator; a first conductor and a second conductor over the oxide semiconductor; a second insulator over the first insulator, the first conductor, and the second conductor; a third insulator over the oxide semiconductor; a third conductor over the third insulator; and a fourth insulator over the third insulator and the third conductor. The oxide semiconductor includes a first region overlapping with the first conductor, a second region overlapping with the second conductor, and a third region positioned between the first region and the second region. The second insulator includes an opening portion in a region overlapping with the third region. At least part of each of the third insulator and the third conductor is provided in the opening portion. Each of the first region and the second region is in contact with the first insulator and the second insulator. The third region is in contact with the first insulator and the third insulator. Each of the first insulator, the second insulator, and the fourth insulator contains silicon and nitrogen. The first insulator includes a region with a thickness smaller than a thickness of the fourth insulator. The concentration of an impurity element of the first insulator is higher than the concentration of the impurity element of the fourth insulator.

In the above semiconductor device, the impurity element is preferably fluorine, chlorine, bromine, iodine, hydrogen, or carbon.

It is preferable that the above semiconductor device further include a fourth conductor below the first insulator and the fourth conductor include a region overlapping with the third conductor with the first insulator, the oxide semiconductor, and the third insulator therebetween.

In the above semiconductor device, it is preferable that the first insulator have a belt-like shape and be provided to extend in a direction in which the third conductor extends.

In the above semiconductor device, it is preferable that the first insulator have an island shape, a side end portion of the first insulator be aligned with a side end portion of the oxide semiconductor, and the second insulator be in contact with a side surface of the first insulator.

In the above semiconductor device, it is preferable that the third region of the oxide semiconductor include a crystal on its side surface in the vicinity of the second insulator, the crystal have a crystal structure in which a plurality of layers are stacked, and each of the layers included in the crystal extend parallel or substantially parallel to a side surface of the oxide semiconductor.

One embodiment of the present invention is a semiconductor device including a first insulator; a second insulator over the first insulator; an oxide semiconductor being over the first insulator and covering a top surface and a side surface of the second insulator; a first conductor and a second conductor over the oxide semiconductor; a third insulator over the first insulator, the first conductor, and the second conductor; a fourth insulator over the oxide semiconductor; and a third conductor over the fourth insulator. The oxide semiconductor includes a first region overlapping with the first conductor, a second region overlapping with the second conductor, and a third region positioned between the first region and the second region. The third insulator includes an opening portion in a region overlapping with the third region. At least part of each of the fourth insulator and the third conductor is provided in the opening portion. Each of the first region and the second region is in contact with the first insulator, the second insulator, and the third insulator. The third region is in contact with the first insulator, the second insulator, and the fourth insulator. Each of the first insulator, the second insulator, and the third insulator contains silicon and nitrogen. The first insulator includes a region with a thickness greater than or equal to 1.0 nm and less than or equal to 5.0 nm.

In the above semiconductor device, the height of the second insulator is preferably larger than the length of the second insulator in a direction in which the third conductor extends.

It is preferable that the above semiconductor device further include a fifth insulator over the fourth insulator and the third conductor, the first insulator include a region with a thickness smaller than a thickness of the fifth insulator, and the concentration of an impurity element of the first insulator be higher than the concentration of the impurity element of the fifth insulator.

In the above semiconductor device, the impurity element is preferably fluorine, chlorine, bromine, iodine, hydrogen, or carbon.

In the above semiconductor device, it is preferable that the third region of the oxide semiconductor include a crystal on its side surface in the vicinity of the fourth insulator, the crystal have a crystal structure in which a plurality of layers are stacked, and each of the layers included in the crystal extend parallel or substantially parallel to a surface of the oxide semiconductor.

One embodiment of the present invention is a semiconductor device including a first insulator; a second insulator and a third insulator over the first insulator and a fourth insulator positioned between the second insulator and the third insulator; an oxide semiconductor over the second insulator, the third insulator, and the fourth insulator; a first conductor and a second conductor over the oxide semiconductor; a fifth insulator over the first insulator, the first conductor, and the second conductor; a sixth insulator over the oxide semiconductor; and a third conductor over the sixth insulator. The oxide semiconductor includes a first region overlapping with the first conductor, a second region overlapping with the second conductor, and a third region positioned between the first region and the second region. The fifth insulator includes an opening portion in a region overlapping with the third region. At least part of each of the sixth insulator and the third conductor is provided in the opening portion. The first region is in contact with the second insulator and the fifth insulator. The second region is in contact with the third insulator and the fifth insulator. The third region is in contact with the fourth insulator and the sixth insulator. Each of the second insulator, the third insulator, and the fifth insulator contains silicon and nitrogen. The thicknesses of the second insulator, the third insulator, and the fourth insulator are equal to each other. The second insulator includes a region with a thickness greater than or equal to 1.0 nm and less than or equal to 5.0 nm.

One embodiment of the present invention is a semiconductor device including a first insulator; a second insulator and a third insulator over the first insulator and a fourth insulator positioned between the second insulator and the third insulator; an oxide semiconductor over the second insulator, the third insulator, and the fourth insulator; a first conductor and a second conductor over the oxide semiconductor; a fifth insulator over the first insulator, the first conductor, and the second conductor; a sixth insulator over the oxide semiconductor; a third conductor over the sixth insulator; and a seventh insulator over the sixth insulator and the third conductor. The oxide semiconductor includes a first region overlapping with the first conductor, a second region overlapping with the second conductor, and a third region positioned between the first region and the second region. The fifth insulator includes an opening portion in a region overlapping with the third region. At least part of each of the sixth insulator and the third conductor is provided in the opening portion. The first region is in contact with the second insulator and the fifth insulator. The second region is in contact with the third insulator and the fifth insulator. The third region is in contact with the fourth insulator and the sixth insulator. Each of the second insulator, the third insulator, the fifth insulator, and the seventh insulator contains silicon and nitrogen. The thicknesses of the second insulator, the third insulator, and the fourth insulator are equal to each other. The second insulator includes a region with a thickness smaller than a thickness of the seventh insulator. The concentration of an impurity element of the second insulator is higher than the concentration of the impurity element of the seventh insulator.

In the above semiconductor device, the impurity element is preferably fluorine, chlorine, bromine, iodine, hydrogen, or carbon.

It is preferable that the above semiconductor device further include a fourth conductor below the first insulator and the fourth conductor include a region overlapping with the third conductor with the first insulator, the fourth insulator, the oxide semiconductor, and the sixth insulator therebetween.

In the above semiconductor device, it is preferable that each of the second insulator, the third insulator, and the fourth insulator have a belt-like shape and be provided to extend in a direction in which the third conductor extends.

In the above semiconductor device, it is preferable that each of the second insulator, the third insulator, and the fourth insulator have an island shape, a side end portion of the second insulator be aligned with a side end portion of the oxide semiconductor, a side end portion of the third insulator be aligned with the side end portion of the oxide semiconductor, a side end portion of the fourth insulator be aligned with the side end portion of the oxide semiconductor, and the fifth insulator be in contact with a side surface of the second insulator and a side surface of the third insulator.

In the above semiconductor device, it is preferable that the third region of the oxide semiconductor include a crystal on its side surface in the vicinity of the sixth insulator, the crystal have a crystal structure in which a plurality of layers are stacked, and each of the layers included in the crystal extend parallel or substantially parallel to a side surface of the oxide semiconductor.

One embodiment of the present invention is a semiconductor device including a first insulator; a second insulator and a third insulator over the first insulator and a fourth insulator positioned between the second insulator and the third insulator; a fifth insulator over the second insulator, the third insulator, and the fourth insulator; an oxide semiconductor being over the second insulator, the third insulator, and the fourth insulator and covering a top surface and a side surface of the fifth insulator, a first conductor and a second conductor over the oxide semiconductor; a sixth insulator over the first insulator, the first conductor, and the second conductor; a seventh insulator over the oxide semiconductor; and a third conductor over the seventh insulator. The oxide semiconductor includes a first region overlapping with the first conductor, a second region overlapping with the second conductor, and a third region positioned between the first region and the second region. The sixth insulator includes an opening portion in a region overlapping with the third region. At least part of each of the seventh insulator and the third conductor is provided in the opening portion. The first region is in contact with the second insulator, the fifth insulator, and the sixth insulator. The second region is in contact with the third insulator, the fifth insulator, and the sixth insulator. The third region is in contact with the fourth insulator, the fifth insulator, and the seventh insulator. Each of the second insulator, the third insulator, the fifth insulator, and the seventh insulator contains silicon and nitrogen. The thicknesses of the second insulator, the third insulator, and the fourth insulator are equal to each other. The second insulator includes a region with a thickness greater than or equal to 1.0 nm and less than or equal to 5.0 nm.

In the above semiconductor device, the height of the fifth insulator is preferably larger than the length of the fifth insulator in a direction in which the third conductor extends.

It is preferable that the above semiconductor device further include an eighth insulator over the seventh insulator and the third conductor, the second insulator include a region with a thickness smaller than a thickness of the eighth insulator, and the concentration of an impurity element of the second insulator be higher than the concentration of the impurity element of the eighth insulator.

In the above semiconductor device, the impurity element is preferably fluorine, chlorine, bromine, iodine, hydrogen, or carbon.

In the above semiconductor device, it is preferable that the third region of the oxide semiconductor include a crystal on its side surface in the vicinity of the seventh insulator, the crystal have a crystal structure in which a plurality of layers are stacked, and each of the layers included in the crystal extend parallel or substantially parallel to a surface of the oxide semiconductor.

### Effect of the Invention

One embodiment of the present invention can provide a semiconductor device that can be miniaturized or highly integrated. Another embodiment of the present invention can provide a semiconductor device that operates at high speed. Another embodiment of the present invention can provide a semiconductor device with favorable electrical characteristics. Another embodiment of the present invention can provide a semiconductor device with a small variation in electrical characteristics of transistors. Another embodiment of the present invention can provide a highly reliable semiconductor device. Another embodiment of the present invention can provide a semiconductor device with a high on-state current. Another embodiment of the present invention can provide a semiconductor device with low power consumption. Another embodiment of the present invention can provide a novel semiconductor device. Another embodiment of the present invention can provide a manufacturing method of a semiconductor device with high productivity. Another embodiment of the present invention can provide a method for manufacturing a novel semiconductor device.

Another embodiment of the present invention can provide a storage device that can be miniaturized or highly integrated. Another embodiment of the present invention can provide a storage device with a large storage capacity. Another embodiment of the present invention can provide a memory that operates at high speed. Another embodiment of the present invention can provide a storage device with low power consumption. Another embodiment of the present invention can provide a novel storage device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a semiconductor device. FIG. 1B to FIG. 1D are cross-sectional views illustrating the example of the semiconductor device. FIG. 1E is a schematic perspective view illustrating the example of the semiconductor device.

FIG. 2A and FIG. 2B are cross-sectional views illustrating an example of a semiconductor device.

FIG. 3A and FIG. 3B are cross-sectional views illustrating examples of a semiconductor device.

FIG. 4A is a plan view illustrating an example of a semiconductor device. FIG. 4B to FIG. 4D are cross-sectional views illustrating the example of the semiconductor device.

FIG. 5A is a plan view illustrating an example of a semiconductor device. FIG. 5B to FIG. 5D are cross-sectional views illustrating the example of the semiconductor device.

FIG. 6A is a plan view illustrating an example of a semiconductor device. FIG. 6B to FIG. 6D are cross-sectional views illustrating the example of the semiconductor device.

FIG. 7A is a plan view illustrating an example of a semiconductor device. FIG. 7B to FIG. 7D are cross-sectional views illustrating the example of the semiconductor device.

FIG. 8A is a plan view illustrating an example of a semiconductor device. FIG. 8B to FIG. 8D are cross-sectional views illustrating the example of the semiconductor device.

FIG. 9A is a plan view illustrating an example of a semiconductor device. FIG. 9B to FIG. 9D are cross-sectional views illustrating the example of the semiconductor device.

FIG. 10A is a plan view illustrating an example of a semiconductor device. FIG. 10B to FIG. 10D are cross-sectional views illustrating the example of the semiconductor device.

FIG. 11A is a plan view illustrating an example of a semiconductor device. FIG. 11B to FIG. 11D are cross-sectional views illustrating the example of the semiconductor device.

FIG. 12A is a plan view illustrating an example of a semiconductor device. FIG. 12B to FIG. 12D are cross-sectional views illustrating the example of the semiconductor device.

FIG. 13A is a plan view illustrating an example of a semiconductor device. FIG. 13B to FIG. 13D are cross-sectional views illustrating the example of the semiconductor device.

FIG. 14A is a plan view illustrating an example of a semiconductor device. FIG. 14B to FIG. 14D are cross-sectional views illustrating the example of the semiconductor device. FIG. 14E is a schematic perspective view illustrating the example of the semiconductor device.

FIG. 15 is a cross-sectional view illustrating an example of a semiconductor device.

FIG. 16A is a plan view illustrating an example of a semiconductor device. FIG. 16B to FIG. 16D are cross-sectional views illustrating the example of the semiconductor device.

FIG. 17A is a plan view illustrating an example of a semiconductor device. FIG. 17B to FIG. 17D are cross-sectional views illustrating the example of the semiconductor device.

FIG. 18A is a plan view illustrating an example of a semiconductor device. FIG. 18B to FIG. 18D are cross-sectional views illustrating the example of the semiconductor device.

FIG. 19A is a plan view illustrating an example of a semiconductor device. FIG. 19B to FIG. 19D are cross-sectional views illustrating the example of the semiconductor device.

FIG. 20A is a plan view illustrating an example of a semiconductor device. FIG. 20B to FIG. 20D are cross-sectional views illustrating the example of the semiconductor device.

FIG. 21A is a plan view illustrating an example of a semiconductor device. FIG. 21B to FIG. 21D are cross-sectional views illustrating the example of the semiconductor device.

FIG. 22A is a plan view illustrating an example of a semiconductor device. FIG. 22B to FIG. 22D are cross-sectional views illustrating the example of the semiconductor device.

FIG. 23A is a plan view illustrating an example of a semiconductor device. FIG. 23B to FIG. 23D are cross-sectional views illustrating the example of the semiconductor device.

FIG. 24A is a plan view illustrating an example of a semiconductor device. FIG. 24B to FIG. 24D are cross-sectional views illustrating the example of the semiconductor device.

FIG. 25A is a plan view illustrating an example of a semiconductor device. FIG. 25B to FIG. 25D are cross-sectional views illustrating the example of the semiconductor device.

FIG. 26A is a plan view illustrating an example of a semiconductor device. FIG. 26B to FIG. 26D are cross-sectional views illustrating the example of the semiconductor device.

FIG. 27A is a plan view illustrating an example of a semiconductor device. FIG. 27B to FIG. 27D are cross-sectional views illustrating the example of the semiconductor device.

FIG. 28A is a plan view illustrating an example of a semiconductor device. FIG. 28B to FIG. 28D are cross-sectional views illustrating the example of the semiconductor device.

FIG. 29A is a plan view illustrating an example of a semiconductor device. FIG. 29B to FIG. 29D are cross-sectional views illustrating the example of the semiconductor device.

FIG. 30A is a plan view illustrating an example of a semiconductor device. FIG. 30B to FIG. 30D are cross-sectional views illustrating the example of the semiconductor device.

FIG. 31A is a plan view illustrating an example of a semiconductor device. FIG. 31B to FIG. 31D are cross-sectional views illustrating the example of the semiconductor device.

FIG. 32A is a plan view illustrating an example of a semiconductor device. FIG. 32B to FIG. 32D are cross-sectional views illustrating the example of the semiconductor device.

FIG. 33A is a plan view illustrating an example of a semiconductor device. FIG. 33B to FIG. 33D are cross-sectional views illustrating the example of the semiconductor device.

FIG. 34A and FIG. 34B are cross-sectional views illustrating examples of a semiconductor device.

FIG. 35A and FIG. 35B are cross-sectional views illustrating examples of a semiconductor device.

FIG. 36A is a plan view illustrating an example of a semiconductor device. FIG. 36B to FIG. 36D are cross-sectional views illustrating the example of the semiconductor device.

FIG. 37A is a plan view illustrating an example of a semiconductor device. FIG. 37B to FIG. 37D are cross-sectional views illustrating the example of the semiconductor device.

FIG. 38A to FIG. 38C are cross-sectional views illustrating examples of a semiconductor device.

FIG. 39A to FIG. 39C are cross-sectional views illustrating examples of a semiconductor device.

FIG. 40A is a plan view illustrating an example of a semiconductor device. FIG. 40B to FIG. 40D are cross-sectional views illustrating the example of the semiconductor device.

FIG. 41A is a plan view illustrating an example of a semiconductor device. FIG. 41B to FIG. 41D are cross-sectional views illustrating the example of the semiconductor device.

FIG. 42 is a cross-sectional view illustrating an example of a semiconductor device.

FIG. 43A to FIG. 43D are cross-sectional views illustrating examples of a semiconductor device.

FIG. 44A to FIG. 44C are cross-sectional views illustrating examples of a semiconductor device.

FIG. 45A is a plan view illustrating an example of a semiconductor device. FIG. 45B to FIG. 45D are cross-sectional views illustrating the example of the semiconductor device.

FIG. 46A is a plan view illustrating an example of a semiconductor device. FIG. 46B to FIG. 46D are cross-sectional views illustrating the example of the semiconductor device.

FIG. 47A and FIG. 47B are cross-sectional views illustrating an example of a semiconductor device.

FIG. 48A to FIG. 48C are cross-sectional views illustrating examples of a semiconductor device.

FIG. 49A to FIG. 49C are cross-sectional views illustrating examples of a semiconductor device.

FIG. 50A is a plan view illustrating an example of a semiconductor device. FIG. 50B to FIG. 50D are cross-sectional views illustrating the example of the semiconductor device.

FIG. 51 is a block diagram illustrating an example of a storage device.

FIG. 52A and FIG. 52B are a schematic diagram and a circuit diagram, respectively, illustrating an example of a storage device.

FIG. 53A and FIG. 53B are schematic diagrams illustrating examples of storage devices.

FIG. 54 is a circuit diagram illustrating an example of a storage device.

FIG. 55A and FIG. 55B are cross-sectional views illustrating examples of a storage device.

FIG. 56A and FIG. 56B are cross-sectional views illustrating examples of a storage device.

FIG. 57 is a cross-sectional view illustrating an example of a storage device.

FIG. 58A and FIG. 58B are diagrams illustrating examples of semiconductor devices.

FIG. 59A and FIG. 59B are diagrams illustrating examples of electronic components.

FIG. 60A and FIG. 60B are diagrams illustrating examples of electronic appliances, and FIG. 60C to FIG. 60E are diagrams illustrating an example of a large computer.

FIG. 61 is a diagram illustrating an example of a device for space.

FIG. 62 is a diagram illustrating an example of a storage system that can be used for a data center.

FIG. 63 is a diagram illustrating a stacked-layer structure of stacked films.

FIG. 64A and FIG. 64B show SIMS analysis results of fabricated samples.

FIG. 65A to FIG. 65C show SIMS analysis results of fabricated samples.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Thus, the disclosed invention is not necessarily limited to the position, size, range, and the like disclosed in the drawings.

Furthermore, especially in a plan view (also referred to as a “top view”), a perspective view, or the like, the description of some components is omitted for easy understanding of the invention in some cases. The description of some hidden lines is also omitted in some cases.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”. The term “conductor” can be interchanged with the term “conductive layer” or the term “conductive film” depending on the case or the circumstances. The term “insulator” can be interchanged with the term “insulating layer” or the term “insulating film” depending on the case or the circumstances.

In this specification and the like, the expression “parallel” indicates a state where two straight lines are placed at an angle greater than or equal to −10° and less than or equal to 10°. Accordingly, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, the expression “perpendicular” indicates a state where two straight lines are placed at an angle greater than or equal to 80° and less than or equal to 100°. Accordingly, the case where the angle is greater than or equal to 85° and less than or equal to 95° is also included. Furthermore, the expression “substantially perpendicular” indicates a state where two straight lines are placed at an angle greater than or equal to 60° and less than or equal to 120°.

The term “opening” includes a groove and a slit, for example. A region where an opening is formed is referred to as an opening portion in some cases.

In the drawings used in embodiments, a sidewall of an insulator in an opening portion in the insulator is illustrated as being perpendicular or substantially perpendicular to a substrate surface or a formation surface, but the sidewall may have a tapered shape.

Note that in this specification and the like, the tapered shape refers to a shape such that at least part of a side surface of a component is inclined to a substrate surface or a formation surface. For example, the tapered shape includes a region where the angle formed by the inclined side surface and the substrate surface or the formation surface (hereinafter, such an angle is also referred to as a taper angle in some cases) is less than 90°. Note that the side surface of the component and the substrate surface are not necessarily completely flat and may be substantially flat with a slight curvature or substantially flat with slight unevenness.

Note that in this specification and the like, the expression “level” indicates a structure having the same level from a reference surface (e.g., a flat surface such as a substrate surface) in a cross-sectional view. For example, in a manufacturing process of a storage device, planarization treatment (typically, CMP treatment) is performed, whereby the surface of a single layer or the surfaces of a plurality of layers is/are exposed in some cases. In that case, the surfaces on which the CMP treatment is performed are at the same level from a reference surface. Note that a plurality of layers may be at different levels depending on a treatment apparatus, a treatment method, or a material of the treated surfaces, used for the CMP treatment. This case is also regarded as being “level” in this specification and the like. For example, the expression “level” includes the case where two layers (here, given as a first layer and a second layer) having different levels with respect to the reference surface are included, and the difference between the top-surface level of the first layer and the top-surface level of the second layer is less than or equal to 20 nm.

Note that in this specification and the like, the expression “side end portions are aligned” means that outlines of stacked layers at least partly overlap with each other in a plan view. For example, the case of processing the upper layer and the lower layer with use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “side end portions are aligned”.

In general, it is difficult to clearly differentiate being “perfectly aligned” from being “substantially aligned”. Therefore, in this specification and the like, the expression being “aligned” includes both being “perfectly aligned” and being “substantially aligned”.

Note that in this specification and the like, the expression “the first thickness and the second thickness are equal to each other” means that a value obtained by dividing the absolute value of the difference between the first thickness and the second thickness by the first thickness is less than or equal to 0.1. Alternatively, the expression means that a value obtained by dividing the absolute value of the difference between the first thickness and the second thickness by the second thickness is less than or equal to 0.1.

Note that in this specification and the like, the expression “the distance A and the distance B are equal to each other” means that a value obtained by dividing the absolute value of the difference between the distance A and the distance B by the distance A is less than or equal to 0.1. Alternatively, the expression means that a value obtained by dividing the absolute value of the difference between the distance A and the distance B by the distance B is less than or equal to 0.1.

### Embodiment 1

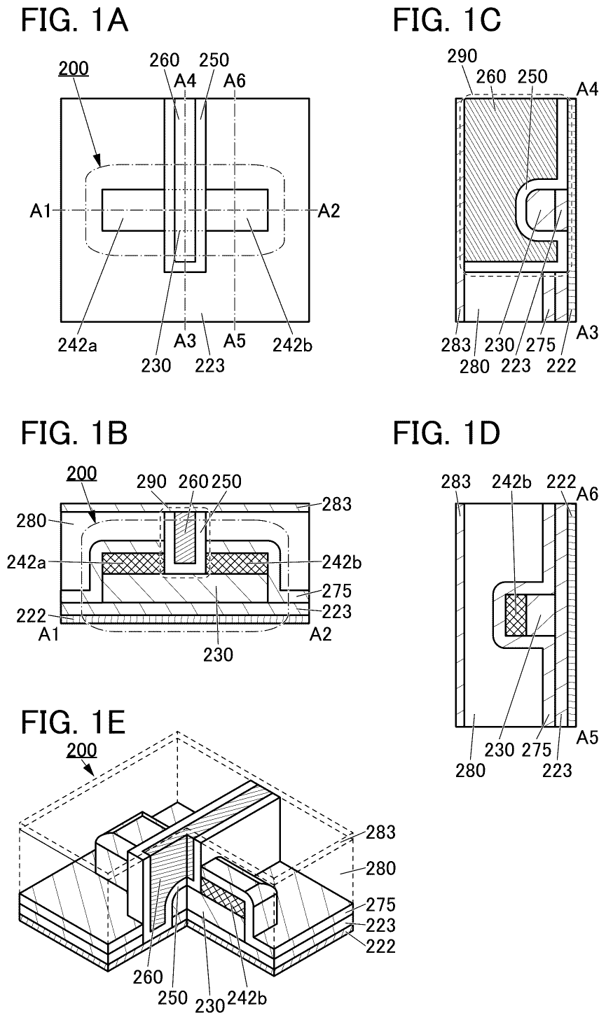

In this embodiment, structure examples of a semiconductor device of one embodiment of the present invention will be described with reference to FIG. 1A to FIG. 32D. The semiconductor device of one embodiment of the present invention includes a transistor.

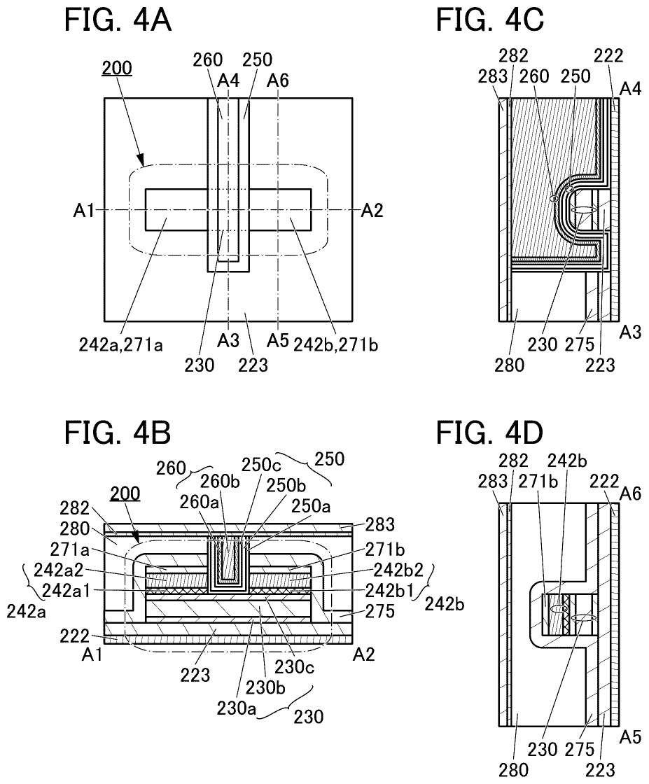

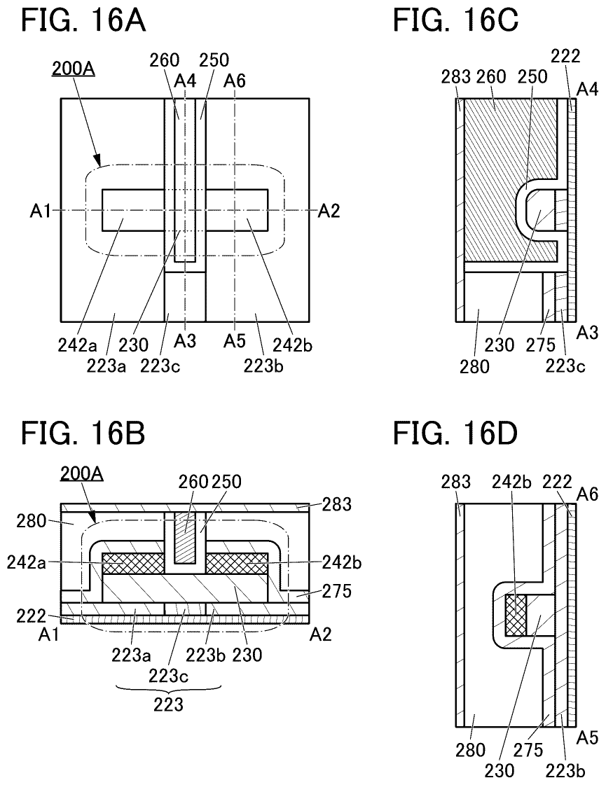

In FIG. 1A to FIG. 1D, FIG. 4A to FIG. 14D, and FIG. 16A to FIG. 32D, A of each drawing is a plan view of a semiconductor device. Moreover, B of each drawing is a cross-sectional view corresponding to a portion indicated by the dashed-dotted line A1-A2 in A of each drawing, and is also a cross-sectional view in the channel length direction of a transistor. Furthermore, C of each drawing is a cross-sectional view corresponding to a portion indicated by the dashed-dotted line A3-A4 in A of each drawing, and is also a cross-sectional view in the channel width direction of the transistor. Furthermore, D of each drawing is a cross-sectional view corresponding to a portion indicated by the dashed-dotted line A5-A6 in A of each drawing. For clarity of the drawings, some components are omitted in the plan view of A of each drawing.

### Structure Example 1

### Structure Example 1-1

A structure example of a semiconductor device is described with reference to FIG. 1A to FIG. 1D. FIG. 1A to FIG. 1D are a top view and cross-sectional views of a semiconductor device including a transistor 200.

The semiconductor device illustrated in FIG. 1A to FIG. 1D includes an insulator 222 over a substrate (not illustrated), the transistor 200 over the insulator 222, an insulator 280 over the transistor 200, and an insulator 283 over the insulator 280. The insulator 222, the insulator 280, and the insulator 283 each function as an interlayer insulating film.

The transistor 200 includes an insulator 223 over the insulator 222, an oxide semiconductor 230 over the insulator 223, a conductor 242a and a conductor 242b over the oxide semiconductor 230, an insulator 275 over the insulator 223, the conductor 242a, and the conductor 242b, an insulator 250 over the oxide semiconductor 230, and a conductor 260 being positioned over the insulator 250 and overlapping with part of the oxide semiconductor 230.

The conductor 260 functions as a gate electrode of the transistor 200. The insulator 250 functions as a gate insulator of the transistor 200. The conductor 242a functions as one of a source electrode and a drain electrode of the transistor 200, and the conductor 242b functions as the other of the source electrode and the drain electrode of the transistor 200. At least part of a region that is of the oxide semiconductor 230 and overlaps with the conductor 260 functions as a channel formation region of the transistor 200.

FIG. 1E is a schematic perspective view of the semiconductor device. In FIG. 1E, parts of the insulator 222, the insulator 223, the oxide semiconductor 230, the conductor 242b, the insulator 250, the conductor 260, the insulator 275, and their periphery are cut for easy viewing. In FIG. 1E, only outlines of some components (e.g., the insulator 280 and the insulator 283) are indicated by dashed lines.

The oxide semiconductor 230 is provided in contact with the top surface of the insulator 223.

The conductor 242a and the conductor 242b are provided in contact with the top surface of the oxide semiconductor 230.

The insulator 275 is placed over the insulator 223, the oxide semiconductor 230, the conductor 242a, and the conductor 242b. Specifically, the insulator 275 is provided in contact with the top surface of the insulator 223, the side surface of the oxide semiconductor 230, the top surface and the side surface of the conductor 242a, and the top surface and the side surface of the conductor 242b.

The insulator 280 is provided in contact with the top surface of the insulator 275.

An opening portion reaching the oxide semiconductor 230 is provided in each of the insulator 280 and the insulator 275. In addition, an opening portion is provided in the insulator 223 in a region where the above opening portion does not overlap with the oxide semiconductor 230. Hereinafter, the opening portion provided in the insulator 280 is referred to as a first opening portion, the opening portion provided in the insulator 275 is referred to as a second opening portion, and the opening portion provided in the insulator 223 is referred to as a third opening portion. The first opening portion, the second opening portion, and the third opening portion are collectively referred to as an opening portion 290.

The insulator 250 and the conductor 260 are provided in the opening portion 290. That is, at least part of the insulator 250 and at least part of the conductor 260 are provided in the first opening portion, in the second opening portion, and in the third opening portion. The insulator 250 and the conductor 260 are provided between the conductor 242a and the conductor 242b in the channel length direction of the transistor 200.

In the opening portion 290, the insulator 250 is in contact with the side surface of the insulator 280 and the side surface of the insulator 275. The insulator 250 is in contact with the side surface of the conductor 242a on the conductor 260 side and the side surface of the conductor 242b on the conductor 260 side. In the opening portion 290, the insulator 250 is in contact with the top surface and the side surface of the oxide semiconductor 230, the side surface of the insulator 223, and the top surface of the insulator 222, as illustrated in FIG. 1C.

The conductor 260 is formed in a self-aligned manner to fill the opening portion 290. The formation of the conductor 260 in this manner allows the conductor 260 to be placed properly in a region between the conductor 242a and the conductor 242b without alignment. The top surface of the conductor 260 is level with those of the insulator 250 and the insulator 280.

In FIG. 1B, the sidewall of the opening portion 290 is perpendicular or substantially perpendicular to the formation surface of the oxide semiconductor 230; however, this embodiment is not limited to this. For example, the bottom surface of the opening portion 290 may have a U-shape with a moderate curve. The sidewall of the opening portion 290 may have a tapered shape, for example. Here, the sidewall of the opening portion 290 corresponds to the side surface of the insulator 280 in the opening portion 290, the side surface of the insulator 275 in the opening portion 290, and the side surface of the insulator 223 in the opening portion 290.

The insulator 283 is placed over the insulator 280, the insulator 250, and the conductor 260.

In the transistor 200, a metal oxide functioning as a semiconductor (hereinafter also referred to as an oxide semiconductor) is preferably used for the oxide semiconductor 230 including the channel formation region. As the oxide semiconductor 230, a single layer or stacked layers of any of the metal oxides in the later-described section [Metal oxide] can be used.

As the oxide semiconductor 230, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is specifically used. Note that a composition in the neighborhood includes the range of +30% of an intended atomic ratio. Gallium is preferably used as the element M.

The oxide semiconductor 230 may have a structure not containing the element M. For example, a metal oxide used as the oxide semiconductor 230 may be an In—Zn oxide. Specifically, the oxide semiconductor 230 can have a composition of In:Zn=1:1 [atomic ratio] or in the neighborhood thereof or a composition of In:Zn=4:1 [atomic ratio] or in the neighborhood thereof.

For analysis of the composition of the metal oxide used for the oxide semiconductor 230, for example, energy dispersive X-ray spectroscopy (EDX: Energy Dispersive X-ray Spectroscopy), X-ray photoelectron spectroscopy (XPS: X-ray Photoelectron Spectroscopy), inductively coupled plasma-mass spectrometry (ICP-MS: Inductively Coupled Plasma-Mass Spectrometry), or inductively coupled plasma-atomic emission spectroscopy (ICP-AES: Inductively Coupled Plasma-Atomic Emission Spectrometry) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an atomic layer deposition (ALD: Atomic Layer Deposition) method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

Examples of the ALD method include a thermal ALD method, in which a precursor and a reactant react with each other only by thermal energy, and a plasma ALD (PEALD: Plasma Enhanced ALD) method, in which a reactant excited by plasma is used.

The ALD method enables atomic layers to be deposited one by one, and has advantages such as deposition of an extremely thin film, deposition on a component with a high aspect ratio or on a surface with a large step, deposition of a film with few defects such as pinholes, deposition with excellent coverage, and low-temperature deposition. The use of plasma in a PEALD method is sometimes preferable because it enables deposition at a lower temperature. Note that a precursor used in the ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or secondary ion mass spectrometry (SIMS: Secondary Ion Mass Spectrometry). Note that the deposition method of the metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object to be processed. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. For example, in the case where a metal oxide has a stacked-layer structure of a first metal oxide and a second metal oxide, a method in which a sputtering method is used to deposit the first metal oxide and an ALD method is used to deposit the second metal oxide over the first metal oxide can be given. For example, in the case where the first metal oxide has a crystal part, crystal growth occurs in the second metal oxide with the use of the crystal part as a nucleus.

In the ALD method, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is not required. Thus, the productivity of the storage device can be increased in some cases.

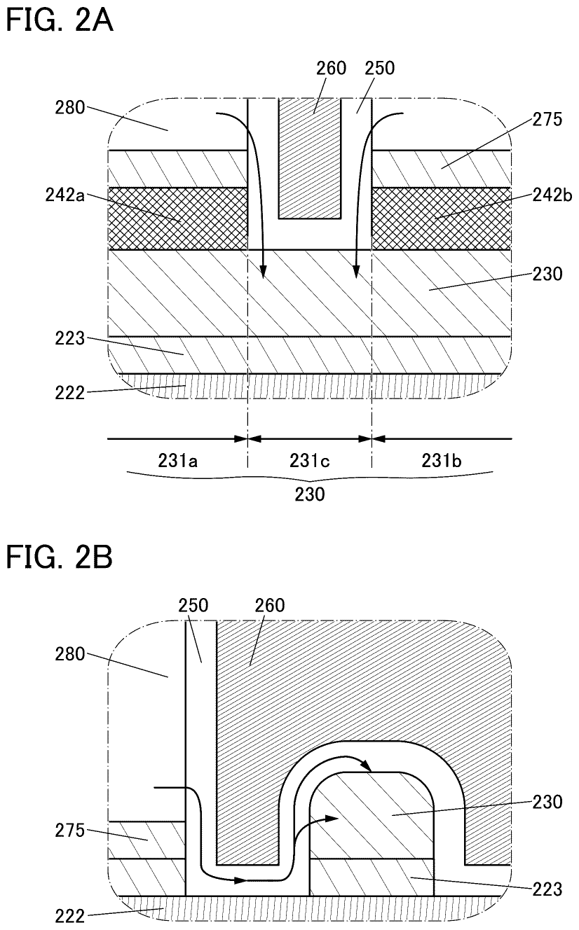

Here, FIG. 2A shows an enlarged view of the channel formation region in FIG. 1B and its vicinity, and FIG. 2B shows an enlarged view of the channel formation region in FIG. 1C and its vicinity. As illustrated in FIG. 2A, the oxide semiconductor 230 includes a region 231a overlapping with the conductor 242a, a region 231b overlapping with the conductor 242b, and a region 231c positioned between the region 231a and the region 231b. In other words, the oxide semiconductor 230 includes the region 231c and the region 231a and the region 231b provided such that the region 231c is sandwiched therebetween.

At least part of the region 231c overlaps with the conductor 260. The region 231c includes a region overlapping with the opening portion 290. That is, the region 231c includes a region overlapping with the first opening portion provided in the insulator 280 and the second opening portion provided in the insulator 275. In other words, the insulator 280 includes the first opening portion in a region overlapping with the region 231c, and the insulator 275 includes the second opening portion in a region overlapping with the region 231c.

The region 231c functions as the channel formation region of the transistor 200. The region 231a functions as one of a source region and a drain region of the transistor 200, and the region 231b functions as the other of the source region and the drain region of the transistor 200.

In the case where an oxide semiconductor is used for the semiconductor layer of the transistor, the channel formation region of the transistor is a high-resistance region having a low carrier concentration. Thus, the channel formation region of the transistor can be regarded as being i-type (intrinsic) or substantially i-type. The source region and the drain region of the transistor are regions that have a higher carrier concentration and a lower resistance (low-resistance n-type regions) than the channel formation region.

When impurities or oxygen vacancies exist in a channel formation region of an oxide semiconductor in a transistor including the oxide semiconductor in a semiconductor layer, electrical characteristics of the transistor may vary easily and the reliability thereof may worsen. In some cases, hydrogen in the vicinity of an oxygen vacancy forms a defect that is an oxygen vacancy into which hydrogen has entered (hereinafter sometimes referred to as VoH), which generates an electron serving as a carrier. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Accordingly, it is preferable that the channel formation region in the oxide semiconductor contain fewer oxygen vacancies, contain fewer VoH, or have a lower concentration of an impurity such as hydrogen, nitrogen, or a metal element than the source region and the drain region.

In contrast, it is preferable that the source region and the drain region in the oxide semiconductor include more oxygen vacancies, include a larger amount of VoH, or have a higher concentration of an impurity such as hydrogen, nitrogen, or a metal element than the channel formation region.

Thus, an insulator containing oxygen that is released by heating (hereinafter sometimes referred to as excess oxygen) is preferably provided in the vicinity of the oxide semiconductor. By performing heat treatment after the insulator is provided, oxygen can be supplied from the insulator to the channel formation region of the oxide semiconductor and oxygen vacancies and VoH can be reduced. However, supply of an excess amount of oxygen to the source region and the drain region of the oxide semiconductor might cause a decrease in the on-state current or field-effect mobility of the transistor. Furthermore, a variation of the amount of oxygen supplied to the source region or the drain region in the substrate plane leads to a variation in electrical characteristics of the transistor. That is, it is preferable that an excess amount of oxygen be prevented from being supplied to the source region and the drain region of the oxide semiconductor.

In view of this, in this embodiment, it is preferable that an insulator containing excess oxygen be used as an insulator in contact with the top surface and the side surface of the region 231c, and a barrier insulator against oxygen in the later-described section [Insulator] be used as an insulator in contact with the bottom surface of the oxide semiconductor 230 (the region 231a to the region 231c). In the semiconductor device described in this embodiment, the insulator 250 is in contact with the top surface and the side surface of the region 231c, and the insulator 223 is in contact with the bottom surface of the oxide semiconductor 230.

Note that in the case where an insulator containing excess oxygen is provided in the vicinity of the insulator 250, an insulator that is likely to transmit oxygen may be used as the insulator 250. With such a structure, oxygen contained in the insulator containing excess oxygen can be supplied to the region 231c through the insulator 250. In the semiconductor device described in this embodiment, the insulator 280 is given as an example of the insulator provided in the vicinity of the insulator 250.

In the case where an insulator containing excess oxygen is used as the insulator 280, a barrier insulator against oxygen is preferably provided between the insulator 280 and each of the region 231a and the region 231b. With such a structure, the amount of oxygen supplied to the source region or the drain region of the oxide semiconductor 230 can be reduced. In the semiconductor device described in this embodiment, the insulator 275 is provided between the insulator 280 and each of the region 231a and the region 231b.

For the insulator 223 and the insulator 275, silicon nitride is preferably used, for example, silicon nitride formed by an ALD method is further preferably used, and silicon nitride formed by a PEALD method is still further preferably used. In that case, each of the insulator 223 and the insulator 275 contains silicon and nitrogen. An ALD method provides excellent step coverage and excellent thickness uniformity and thus is suitable for forming a thin film or covering a surface with a high aspect ratio.

For example, in the case where a silicon nitride film is deposited by a PEALD method, a precursor containing a halogen such as fluorine, chlorine, bromine, or iodine is suitably used. After the precursor is introduced, plasma treatment is performed in an atmosphere to which a nitriding agent such as N₂, N₂O, NH₃, NO, NO₂, or N₂O₂ is introduced, so that a high-quality silicon nitride film can be deposited.

The insulator 275 is in contact with part of the top surface of the insulator 223 as illustrated in FIG. 1D. In that case, each of the region 231a and the region 231b is surrounded by the insulator 223 and the insulator 275. Each of the region 231a and the region 231b is in contact with the insulator 223 and the insulator 275.

As illustrated in FIG. 1C, the insulator 250 is in contact with the side surface of the insulator 223 and part of the top surface of the insulator 222. In that case, the region 231c is surrounded by the insulator 223 and the insulator 250. The region 231c is in contact with the insulator 223 and the insulator 250.

In this specification and the like, a structure in which a structure body is surrounded by the first insulator and the second insulator refers to a structure in which the first insulator is positioned on at least part of the top surface and at least part of the side surface of the structure body and the second insulator is positioned on at least part of the bottom surface of the structure body, or a structure in which the first insulator is positioned on at least part of the top surface of the structure body and the second insulator is positioned on at least part of the side surface and at least part of the bottom surface of the structure body. Note that another structure body may be provided between the first insulator and the structure body. Another structure body may be provided between the second insulator and the structure body.

The arrows illustrated in FIG. 2A and FIG. 2B visualize a state where oxygen contained in the insulator 280 diffuses into the region 231c through the insulator 250.

In this embodiment, microwave treatment is preferably performed in an atmosphere containing oxygen in a state where the conductor 242a and the conductor 242b are provided over the oxide semiconductor 230.

In this specification and the like, the microwave treatment refers to treatment using an apparatus including a power source that generates high-density plasma with use of a microwave. In this specification and the like, the microwave refers to an electromagnetic wave having a frequency greater than or equal to 300 MHz and less than or equal to 300 GHz. The microwave treatment can also be referred to as microwave excitation high-density plasma treatment.

The microwave treatment in an oxygen-containing atmosphere converts an oxygen gas into plasma using a high-frequency wave such as a microwave or RF and activates the oxygen plasma. At this time, the region 231c can be irradiated with the high-frequency wave such as a microwave or RF. By the effect of the plasma, the microwave, or the like, VoH in the region 231c can be divided into an oxygen vacancy (Vo) and hydrogen (H); the hydrogen can be removed from the region 231c and the oxygen vacancy can be filled with oxygen. As a result, the hydrogen concentration, oxygen vacancies, and VoH in the region 231c can be reduced to lower the carrier concentration.

In the microwave treatment in an oxygen-containing atmosphere, the effect of the high-frequency wave such as the microwave or RF, the oxygen plasma, or the like is blocked by the conductor 242a and the conductor 242b and does not reach the region 231a and the region 231b. In addition, the effect of the oxygen plasma can be reduced by the insulator 275 and the insulator 280 that are provided to cover the oxide semiconductor 230, the conductor 242a, and the conductor 242b. Hence, a reduction in VoH and supply of an excess amount of oxygen do not occur in the region 231a and the region 231b in the microwave treatment, preventing a decrease in carrier concentration.

After an insulating film to be the insulator 250 is formed, microwave treatment is preferably performed in an oxygen-containing atmosphere. By performing the microwave treatment in an oxygen-containing atmosphere through the insulator 250 in such a manner, oxygen can be efficiently supplied into the region 231c. In addition, the insulator 250 is placed to be in contact with the side surface of the conductor 242a, the side surface of the conductor 242b, and a surface of the region 231c, thereby inhibiting supply of oxygen more than necessary to the region 231c and inhibiting oxidation of the side surfaces of the conductor 242a and the conductor 242b.

The oxygen implanted into the region 231c is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Note that the oxygen implanted into the region 231c is in any one or more of the above forms, and an oxygen radical is particularly suitable. Furthermore, the film quality of the insulator 250 can be improved, leading to higher reliability of the transistor 200.

In the above manner, oxygen vacancies and VoH can be selectively removed from the region 231c functioning as a channel formation region, whereby the region 231c can be an i-type or substantially i-type region. Furthermore, supply of an excess amount of oxygen to the region 231a and the region 231b functioning as the source region and the drain region can be inhibited and the state of the n-type regions before the microwave treatment is performed can be maintained. As a result, a change in the electrical characteristics of the transistor 200 can be inhibited, and thus a variation in the electrical characteristics of the transistors 200 in the substrate plane can be inhibited.

The above-described structure enables oxygen to be supplied to the region 231c efficiently as illustrated in FIG. 2A and FIG. 2B, resulting in formation of an i-type channel formation region. Furthermore, the region 231a and the region 231b are supplied with a smaller amount of oxygen than the region 231c; thus, the carrier concentrations in the source region and the drain region can be prevented from being reduced.

As the insulator 223 and the insulator 275, a barrier insulator against hydrogen in the later-described section [Insulator] is preferably used. With such a structure, hydrogen contained in a structure body provided below the insulator 223 or a structure body provided above the insulator 275 can be inhibited from entering the oxide semiconductor 230. Silicon nitride has a barrier property against hydrogen and thus is suitably used for the insulator 275 and the insulator 223.

Silicon nitride that can be used for the insulator 223 and the insulator 275 has a barrier property against oxygen when the thickness is greater than or equal to 1.0 nm, for example, and has a high barrier property against oxygen when the thickness is greater than or equal to 1.4 nm, for example. Furthermore, silicon nitride has a barrier property against hydrogen when the thickness is greater than or equal to 2.5 nm, for example, and has a high barrier property against hydrogen when the thickness is greater than or equal to 3.3 nm, for example.

Since the insulator 223 preferably has at least a barrier property against oxygen, the thickness of the insulator 223 is preferably greater than or equal to 1.0 nm, further preferably greater than or equal to 1.4 nm. Although there is no particular limitation on the upper limit of the thickness of the insulator 223, for miniaturization or high integration of the semiconductor device, increased productivity of the semiconductor device, and the like, the thickness of the insulator 223 is preferably less than or equal to 20 nm, less than or equal to 10 nm, or less than or equal to 5.0 nm. Thus, the insulator 223 preferably includes a region with a thickness greater than or equal to 1.0 nm and less than or equal to 10 nm, further preferably includes a region with a thickness greater than or equal to 1.0 nm and less than or equal to 5.0 nm. The insulator 223 preferably includes a region with a thickness greater than or equal to 1.4 nm and less than or equal to 10 nm, further preferably includes a region with a thickness greater than or equal to 1.4 nm and less than or equal to 5.0 nm.

In the case where the insulator 223 and the insulator 275 are formed with the same insulating material, the third opening portion is formed in the insulator 223 at the time of forming the second opening portion by etching the insulator 275. At this time, in the third opening portion, the insulator 250 is in contact with the insulator 222 (see FIG. 1C).

An insulator that can be used as the insulator 223 and the insulator 275 is not limited to silicon nitride. For example, aluminum oxide or hafnium oxide may be used. The insulator 223 and the insulator 275 may each have a stacked-layer structure. For example, a stacked-layer structure of silicon nitride and aluminum oxide over the silicon nitride may be used for the insulator 223, and a stacked-layer structure of aluminum oxide and silicon nitride over the aluminum oxide may be used for the insulator 275. Alternatively, a stacked-layer structure of aluminum oxide and silicon nitride over the aluminum oxide may be used for the insulator 223, and a stacked-layer structure of silicon nitride and aluminum oxide over the silicon nitride may be used for the insulator 275.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide semiconductor 230, the CAAC-OS or the nc-OS is preferably used, and the CAAC-OS is particularly preferably used.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide semiconductor 230, oxygen extraction from the oxide semiconductor 230 by the source electrode or the drain electrode can be inhibited. This can inhibit oxygen extraction from the oxide semiconductor 230 even when heat treatment is performed; thus, the transistor 200 is stable with respect to high temperatures in a manufacturing process (what is called thermal budget).

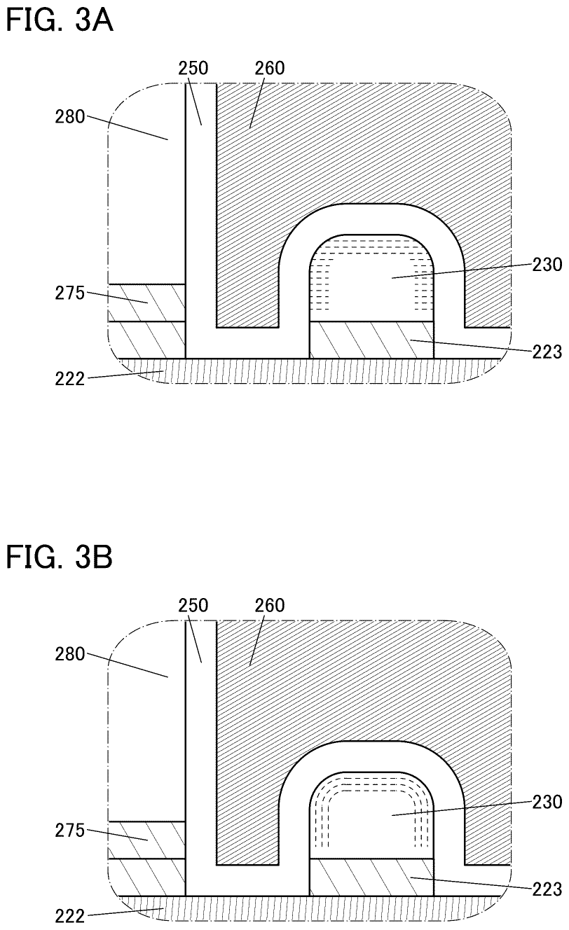

Here, FIG. 3A and FIG. 3B show enlarged views of the channel formation region in FIG. 1C and its vicinity.

The CAAC-OS includes a plurality of crystals, and each of the plurality of crystals has a crystal structure in which a plurality of layers are stacked. It is preferable that the c-axis of a crystal included in the CAAC-OS used as the oxide semiconductor 230 be aligned in a direction perpendicular to the channel length direction. It is preferable that the c-axis of a crystal included in the region 231c functioning as the channel formation region be aligned in a direction perpendicular to the channel length direction. With such a structure, the layer included in the crystal extends in the channel length direction of the transistor 200, so that the on-state current of the transistor 200 can be increased.

In particular, in the semiconductor device illustrated in FIG. 1A to FIG. 1D, it can be said that the channel formation region is electrically surrounded by the electric field of the conductor 260. Accordingly, the side surface of the region 231c also functions as the channel formation region. Thus, it is preferable that the c-axis of a crystal included in the vicinity of the side surface of the region 231c that faces the insulator 250 be also aligned in a direction perpendicular to the channel length direction. In other words, it is preferable that the region 231c have a crystal on its side surface in the vicinity of the insulator 250 and the c-axis of the crystal be aligned in a direction perpendicular to the channel length direction.

An example of the above structure is a structure in which a layer included in a crystal extends parallel or substantially parallel to a formation surface of the oxide semiconductor 230 (see FIG. 3A). Note that when the above-described crystal is formed at the time of depositing an oxide semiconductor film to be the oxide semiconductor 230, the oxide semiconductor 230 including the crystal can be formed. For example, the oxide semiconductor film is preferably formed while the substrate is heated. Note that an oxide semiconductor film formed by a sputtering method easily has crystallinity and thus is suitable for forming the oxide semiconductor 230 including the crystal.

Another example of the above structure is a structure in which a layer included in a crystal extends parallel or substantially parallel to a surface (a top surface or a side surface) of the oxide semiconductor 230 (see FIG. 3B). Note that the oxide semiconductor film to be the oxide semiconductor 230 is processed into an island shape and then treatment is performed, whereby the oxide semiconductor 230 including the above crystal can be formed. For example, it is preferable that an oxide semiconductor film with low crystallinity be formed and processed into an island shape and then one or more kinds of treatment selected from plasma treatment, microwave treatment, and heat treatment be performed so that the oxide semiconductor 230 includes a crystal. Note that in the case where an oxide semiconductor film is deposited by an ALD method, impurities contained in a raw material such as a precursor remain, so that the oxide semiconductor film sometimes has low crystallinity. Thus, the above treatment is performed after the oxide semiconductor film is formed and processed into an island shape, whereby the impurity concentration of the oxide semiconductor 230 can be reduced and crystal growth from the surface side of the oxide semiconductor 230 can be promoted.

Note that there is no particular limitation on the method for forming the oxide semiconductor film to be the oxide semiconductor 230. For example, the oxide semiconductor film can be formed by a CVD method, an MBE method, a PLD method, or the like. Alternatively, an ALD method may be employed to obtain the structure illustrated in FIG. 3A, or a sputtering method may be employed to obtain the structure illustrated in FIG. 3B.

The crystallinity of the oxide semiconductor 230 can be analyzed with X-ray diffraction (XRD), a transmission electron microscope (TEM), or electron diffraction (ED), for example. Alternatively, some of these methods may be performed in combination.

Although the oxide semiconductor 230 being a single layer is illustrated in FIG. 1B and FIG. 1C, the present invention is not limited thereto. The oxide semiconductor 230 may have a stacked-layer structure of a plurality of oxide layers with different chemical compositions. For example, a structure in which a plurality of kinds of metal oxides selected from the above-described metal oxides and metal oxides to be described later in the section [Metal oxide] are stacked as appropriate may be used.

For example, as illustrated in FIG. 4A to FIG. 4D, the oxide semiconductor 230 may have a stacked-layer structure of an oxide semiconductor 230a, an oxide semiconductor 230b over the oxide semiconductor 230a, and an oxide semiconductor 230c over the oxide semiconductor 230b.

The atomic ratio of the element M to In in the metal oxide used as the oxide semiconductor 230a is preferably greater than the atomic ratio of the element M to In in the metal oxide used as the oxide semiconductor 230b. With such a structure, impurities and oxygen can be inhibited from being diffused into the oxide semiconductor 230b from the components formed below the oxide semiconductor 230a. In addition, diffusion of the element contained in the insulator 223 into the oxide semiconductor 230b can be inhibited.

For example, in the case where the thickness of the insulator 223 is small, the effect of inhibiting diffusion of hydrogen by the insulator 223 is sometimes low. In such a case, providing the oxide semiconductor 230a between the insulator 223 and the oxide semiconductor 230b can inhibit diffusion of hydrogen into the oxide semiconductor 230b from the substrate side.

Note that in the case where the insulator 223 is highly effective in inhibiting diffusion of hydrogen and oxygen, the oxide semiconductor 230a is not necessarily provided. For example, in the case where the thickness of the insulator 223 is greater than or equal to 2.5 nm, preferably greater than or equal to 3.3 nm, the oxide semiconductor 230a is not necessarily provided. In that case, the oxide semiconductor 230 may have a stacked-layer structure of the oxide semiconductor 230b and the oxide semiconductor 230c over the oxide semiconductor 230b. Note that the thickness of the insulator 223 is not limited to the above depending on the structure of the insulator 222. Even when the thickness of the insulator 223 is greater than or equal to 1.0 nm or greater than or equal to 1.4 nm and less than or equal to 2.5 nm, the oxide semiconductor 230a is not necessarily provided in some cases.

For example, in the case where an oxide semiconductor film is formed by a formation method that causes less damage to the insulator 223, the oxide semiconductor 230a is not necessarily provided. For example, in the case where an oxide semiconductor film to be the oxide semiconductor 230b is formed by an ALD method or a CVD method, the oxide semiconductor 230a is not necessarily provided. In the case where the oxide semiconductor film is formed by an ALD method or a CVD method, damage to the insulator 223 is reduced, so that diffusion of the element contained in the insulator 223 into the oxide semiconductor film can be inhibited.

Note that in the case where the oxide semiconductor 230a and the oxide semiconductor 230b have different compositions, the conductivity of a material used for the oxide semiconductor 230b may be different from the conductivity of a material used for the oxide semiconductor 230a. The band gap of the material used for the oxide semiconductor 230b is different from the band gap of the material used for the oxide semiconductor 230a in some cases.

The conductivity of a material used for the oxide semiconductor 230b is preferably different from the conductivity of a material used for the oxide semiconductor 230c. For example, a material having higher conductivity than a material for the oxide semiconductor 230c can be used for the oxide semiconductor 230b. The use of a material having high conductivity for the oxide semiconductor 230b enables the transistor to have a high on-state current.

Note that a material having higher conductivity than a material for the oxide semiconductor 230a is preferably used for the oxide semiconductor 230b. The use of a material having high conductivity for the oxide semiconductor 230b enables the transistor to have a high on-state current.

In order to obtain the above structure, for example, the atomic ratio of In to Zn in the oxide semiconductor 230b is preferably larger than the atomic ratio of In to Zn in the oxide semiconductor 230a. Furthermore, the atomic ratio of In to Zn in the oxide semiconductor 230b is preferably larger than the atomic ratio of In to Zn in the oxide semiconductor 230c. Alternatively, for example, the thickness of the oxide semiconductor 230b is preferably larger than the thickness of the oxide semiconductor 230a and the thickness of the oxide semiconductor 230c.

Here, in the case where a material having high conductivity is used for the oxide semiconductor 230c provided on the conductor 260 side functioning as the gate electrode, the threshold voltage of the transistor 200 is shifted and a drain current flowing when the gate voltage is 0 V (hereinafter also referred to as cut-off current) becomes large in some cases. Specifically, the threshold voltage might be low when the transistor 200 is an n-channel transistor. Thus, a material having lower conductivity than a material for the oxide semiconductor 230b is preferably used for the oxide semiconductor 230c. Accordingly, the transistor 200 can have high threshold voltage in the case where the transistor 200 is an n-channel transistor, in which case the transistor 200 can have low cut-off current. Note that the low cut-off current is sometimes referred to as normally-off.

When a material having higher conductivity than the material for the oxide semiconductor 230c is used for the oxide semiconductor 230b as described above, the transistor can be normally-off and can have high on-state current. Consequently, the semiconductor device can have both low power consumption and high performance.

The carrier concentration of the oxide semiconductor 230b is preferably higher than the carrier concentration of the oxide semiconductor 230c. Increasing the carrier concentration of the oxide semiconductor 230b increases the conductivity, which enables the transistor to have high on-state current. Reducing the carrier concentration of the oxide semiconductor 230c reduces the conductivity, which enables the transistor to be normally off.

Although an example in which a material having higher conductivity than the material for the oxide semiconductor 230c is used for the oxide semiconductor 230b is described here, one embodiment of the present invention is not limited thereto. A material having lower conductivity than the material for the oxide semiconductor 230c may be used for the oxide semiconductor 230b. The carrier concentration of the oxide semiconductor 230b may be lower than the carrier concentration of the oxide semiconductor 230c.

The band gap of a first metal oxide used for the oxide semiconductor 230b and the band gap of a second metal oxide used for the oxide semiconductor 230c are preferably different from each other. For example, a difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the oxide semiconductor 230b can be smaller than the band gap of the second metal oxide used for the oxide semiconductor 230c. With such a structure, the transistor can have a high on-state current. Furthermore, the transistor 200 can have high threshold voltage in the case where the transistor 200 is an n-channel transistor, and the transistor 200 can be a normally-off transistor.

Although an example in which the band gap of the first metal oxide is smaller than the band gap of the second metal oxide is described here, one embodiment of the present invention is not limited thereto. The band gap of the first metal oxide can be larger than the band gap of the second metal oxide in some cases.

The oxide semiconductor 230c preferably has a higher barrier property against oxygen than the oxide semiconductor 230b. The oxide semiconductor 230c is placed between the conductor 242a and the oxide semiconductor 230b and between the conductor 242b and the oxide semiconductor 230b, whereby the conductor 242a and the conductor 242b can be inhibited from being oxidized by oxygen contained in the oxide semiconductor 230b and having an increased resistivity and a lower on-state current. Thus, the electrical characteristics, field-effect mobility, and reliability of the transistor 200 can be improved.

In the case where the oxide semiconductor 230 has the three-layer structure, the oxide semiconductor 230 may have a structure in which a metal oxide with a composition of In:Ga:Zn=1:1:1 [atomic ratio] or in the neighborhood thereof is used for the oxide semiconductor 230a, a metal oxide with a composition of In:Zn=1:1 [atomic ratio] or in the neighborhood thereof or with a composition of In:Zn=4:1 [atomic ratio] or in the neighborhood thereof is used for the oxide semiconductor 230b, and a metal oxide with a composition of In:Ga:Zn=1:1:1 [atomic ratio] or in the neighborhood thereof is used for the oxide semiconductor 230c. With this structure, the transistor 200 can have high on-state current and high reliability with small variations.

Note that in the case where the compositions and thicknesses of the oxide semiconductor 230a and the oxide semiconductor 230b are set as appropriate and characteristics required for the transistor 200 can be obtained, the oxide semiconductor 230c is not necessarily provided. In that case, the oxide semiconductor 230 may have a stacked-layer structure of the oxide semiconductor 230a and the oxide semiconductor 230b over the oxide semiconductor 230a.

As the insulator 250, a single layer or stacked layers of any of the insulators in the later-described section [Insulator] can be used. For the insulator 250, silicon oxide or silicon oxynitride can be used, for example. Silicon oxide and silicon oxynitride are preferable because of being thermally stable.

As the insulator 250, any of the materials with high dielectric constants, that is, high-k materials, in the later-described section [Insulator] may be used. For example, hafnium oxide, aluminum oxide, or the like may be used.

The insulator 250 is provided in the opening portion formed in the insulator 280 and the like, together with the conductor 260. The thickness of the insulator 250 is preferably small for miniaturization of the transistor 200. The thickness of the insulator 250 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulator 250 has a region with the above-described thickness.

The concentration of impurities such as water and hydrogen in the insulator 250 is preferably reduced. This can inhibit entry of impurities such as water and hydrogen into the channel formation region of the oxide semiconductor 230.

Although the insulator 250 being a single layer is illustrated in FIG. 1B and FIG. 1C, the present invention is not limited thereto. The insulator 250 may have a stacked-layer structure. For example, as illustrated in FIG. 4A to FIG. 4D, the insulator 250 may have a stacked-layer structure of an insulator 250a, an insulator 250b over the insulator 250a, and an insulator 250c over the insulator 250b.

As the insulator 250b, an insulator that can be used as the insulator 250 described above is preferably used.

As the insulator 250a, any of the barrier insulators against oxygen in the later-described section [Insulator] is preferably used. The insulator 250a includes a region in contact with the oxide semiconductor 230. When the insulator 250a has a barrier property against oxygen, release of oxygen from the oxide semiconductor 230 at the time of performing heat treatment or the like can be inhibited. This can inhibit formation of oxygen vacancies in the oxide semiconductor 230. Accordingly, the transistor 200 can have favorable electrical characteristics and higher reliability. As the insulator 250a, aluminum oxide is preferably used, for example. In that case, the insulator 250a contains at least oxygen and aluminum.

As the insulator 250c, any of the barrier insulators against hydrogen in the later-described section [Insulator] is preferably used. In that case, diffusion of impurities contained in the conductor 260 into the oxide semiconductor 230 can be inhibited. Silicon nitride is suitably used for the insulator 250c because of its high hydrogen barrier property. In this case, the insulator 250c contains at least nitrogen and silicon.

The insulator 250c may further have a barrier property against oxygen. The insulator 250c is provided between the insulator 250b and the conductor 260. Thus, diffusion of oxygen contained in the insulator 250b into the conductor 260 can be prevented, which can inhibit oxidation of the conductor 260. Furthermore, a reduction in the amount of oxygen supplied to the region 231c can be inhibited.

An insulator may be provided between the insulator 250b and the insulator 250c. For the insulator, any of the insulators having a function of capturing or fixing hydrogen in the later-described section [Insulator] is preferably used. By providing the insulator, hydrogen contained in the oxide semiconductor 230 can be captured or fixed more effectively. Thus, the hydrogen concentration in the oxide semiconductor 230 can be lowered. As the insulator, for example, hafnium oxide is preferably used. In that case, the above insulator contains at least oxygen and hafnium. Alternatively, the insulator may have an amorphous structure.

The thicknesses of the insulator 250a to the insulator 250c are preferably small and preferably within the above range for miniaturization of the transistor 200. Typically, the thicknesses of the insulator 250a, the insulator 250b, the insulator having a function of capturing or fixing hydrogen, and the insulator 250c are 1 nm, 2 nm, 2 nm, and 1 nm, respectively. Such a structure enables the transistor 200 to have favorable electrical characteristics even when the transistor 200 is miniaturized or highly integrated.

To form the insulator 250a to the insulator 250c each having a small thickness as described above, an ALD method is preferably used for deposition. Furthermore, in the case where the insulator 250a to the insulator 250c are provided in the opening portion in the insulator 280 and the like, an ALD method is preferably employed.

Although FIG. 4A to FIG. 4D illustrate the structure in which the insulator 250 has a three-layer structure of the insulator 250a to the insulator 250c, the present invention is not limited to the structure. The insulator 250 may have a stacked-layer structure of two layers or four or more layers. In that case, the layers included in the insulator 250 are preferably selected as appropriate from the insulator 250a to the insulator 250c and the insulator having a function of capturing or fixing hydrogen.

The insulator 280, which functions as an interlayer film, preferably has a low relative permittivity. When a material with a low dielectric constant is used for an interlayer film, parasitic capacitance generated between wirings can be reduced. As the insulator 280, a single layer or stacked layers of insulators containing any of the materials with low dielectric constants in the later-described section [Insulator] can be used. Silicon oxide and silicon oxynitride are preferable because of being thermally stable.

The concentration of impurities such as water and hydrogen in the insulator 280 is preferably reduced. This can inhibit entry of impurities such as water and hydrogen into the channel formation region of the oxide semiconductor 230.

As the insulator 283, any of the barrier insulators against hydrogen in the later-described section [Insulator] is preferably used. This can inhibit diffusion of hydrogen from the outside of the transistor 200 into the oxide semiconductor 230 through the insulator 250. Silicon nitride and silicon nitride oxide can be suitably used for the insulator 283 because they release fewer impurities (e.g., water and hydrogen) and are less likely to transmit oxygen and hydrogen.

A film of silicon nitride formed by a sputtering method is particularly preferably used as the insulator 283. In that case, the insulator 283 contains at least silicon and nitrogen. Since a sputtering method does not need to use a molecule containing hydrogen as a deposition gas, the hydrogen concentration in the insulator 283 can be reduced. When the insulator 283 is deposited by a sputtering method, high-density silicon nitride can be formed.

The thickness of the insulator 223 may be different from the thickness of the insulator 283. For example, the thickness of the insulator 223 is preferably smaller than the thickness of the insulator 283. At least part of the insulator 223 includes a region having a thickness smaller than that of the insulator 283. As described above, the insulator 223 preferably has at least a barrier property against oxygen, and the insulator 283 preferably has a barrier property against hydrogen. Thus, the insulator 223 may include a region having a thickness smaller than that of the insulator 283.

The concentration of the impurity element in the insulator 223 may be different from the concentration of the impurity element in the insulator 283. For example, the concentration of the impurity element in the insulator 223 is higher than the concentration of the impurity element in the insulator 283 in some cases. Note that the impurity element is hydrogen, carbon, or halogen such as fluorine, chlorine, bromine, or iodine. As described above, the insulator 223 is preferably deposited by an ALD method, and the insulator 283 is preferably deposited by a sputtering method. In the case where an insulator is deposited by an ALD method, impurities contained in a raw material such as a precursor remain. Thus, the insulator deposited by an ALD method tends to have a high concentration of the impurity element. For example, in the case where a precursor including halogen such as fluorine, chlorine, bromine, or iodine is used, the insulator deposited by an ALD method tends to have a high concentration of halogen. That is, the halogen concentration in the insulator 223 is higher than the halogen concentration in the insulator 283 in some cases. For example, in the case where a precursor formed of an organic substance (hereinafter referred to as an organic precursor) is used, the insulator deposited by an ALD method tends to have a high hydrogen concentration and a high carbon concentration. That is, the hydrogen concentration in the insulator 223 is higher than the hydrogen concentration in the insulator 283 in some cases. The carbon concentration in the insulator 223 is higher than the carbon concentration in the insulator 283 in some cases.

As the insulator 222, any of the barrier insulators against hydrogen in the later-described section [Insulator] is preferably used. The insulator 222 having a barrier property against hydrogen can inhibit diffusion of hydrogen from below the insulator 222 into the oxide semiconductor 230 even when the thickness of the insulator 223 is reduced.

Alternatively, a metal oxide with an amorphous structure is preferably used for the insulator 222. With such a structure, hydrogen contained in the channel formation region of the transistor 200 can be captured or fixed.

Note that the insulator 222 may have a barrier property against oxygen. With the insulator 222 and the insulator 223 having a barrier property against oxygen, release of oxygen from the oxide semiconductor 230 can be inhibited.

As the insulator 222, an insulator functioning as an etching stopper film in forming the third opening portion by etching the insulator 223 is preferably selected.

Although the insulator 222 being a single layer is illustrated in FIG. 1B and FIG. 1C, the present invention is not limited thereto. The insulator 222 may have a stacked-layer structure. For example, a stacked-layer structure of silicon nitride and hafnium oxide over the silicon nitride may be employed. Such a structure can inhibit diffusion of hydrogen from below the insulator 222 into the oxide semiconductor 230.

As the conductor 260, a single layer or stacked layers of any of the conductors in the later-described section [Conductor] can be used. For example, a conductive material with high conductivity such as tungsten can be used for the conductor 260.

In addition, a conductive material that is less likely to be oxidized, a conductive material having a function of inhibiting diffusion of oxygen, or the like is preferably used for the conductor 260. Examples of the conductive material include a conductive material containing nitrogen (e.g., titanium nitride or tantalum nitride) and a conductive material containing oxygen (e.g., ruthenium oxide). In the case where a conductive material containing metal and nitrogen is used for the conductor 260, the conductor 260 contains at least metal and nitrogen. This can inhibit a decrease in the conductivity of the conductor 260.

Although the conductor 260 being a single layer is illustrated in FIG. 1B and FIG. 1C, the present invention is not limited to this structure. The conductor 260 may have a stacked-layer structure. For example, as illustrated in FIG. 4B and FIG. 4C, the conductor 260 may have a stacked-layer structure of the conductor 260a and the conductor 260b over the conductor 260a.

The conductor 260a is preferably formed using a conductive material having a function of inhibiting diffusion of oxygen. Thus, the conductivity of the conductor 260b can be inhibited from being lowered because of oxidation caused by oxygen contained in the insulator 280 and the like. Titanium nitride can be used for the conductor 260a, for example.

The conductor 260b is preferably formed using a conductive material having high conductivity. For example, tungsten can be used for the conductor 260b. When a layer including tungsten is provided in this manner, the conductor 260 can have improved conductivity and thus can serve well as a wiring.

Although FIG. 4B and FIG. 4C illustrate the structure in which the conductor 260 has the two-layer structure of the conductor 260a and the conductor 260b, the present invention is not limited to this structure. The conductor 260 may have a stacked-layer structure of three or more layers.

As the conductor 242a and the conductor 242b, a single layer or stacked layers of any of the conductors in the later-described section [Conductor] can be used. For example, a conductive material with high conductivity such as tungsten can be used for the conductor 242a and the conductor 242b.

The conductor 242a and the conductor 242b are preferably formed using a conductive material that is less likely to be oxidized or a conductive material having a function of inhibiting diffusion of oxygen, for example, like the conductor 260. For example, titanium nitride, tantalum nitride, or the like can be used. In that case, the conductor 242a and the conductor 242b each contain at least metal and nitrogen. Such a structure can inhibit excessive oxidation of the conductor 242a and the conductor 242b due to the oxide semiconductor 230.

Although the conductor 242a and the conductor 242b each being a single layer are illustrated in FIG. 1B and FIG. 1C, the present invention is not limited thereto. Each of the conductor 242a and the conductor 242b may have a stacked-layer structure. For example, as illustrated in FIG. 4B and FIG. 4C, the conductor 242a may have a stacked-layer structure of a conductor 242a1 and a conductor 242a2 over the conductor 242a1. The conductor 242b may have a stacked-layer structure of a conductor 242b1 and a conductor 242b2 over the conductor 242b1. In that case, titanium nitride or tantalum nitride may be used for the conductor 242a1 and the conductor 242b1, and tungsten may be used for the conductor 242a2 and the conductor 242b2, for example. When a layer including tungsten is provided in this manner, the conductor 242a and the conductor 242b can have improved conductivity and thus can serve well as a wiring.

Although the insulator 275 is provided in contact with the top surface of the conductor 242a and the top surface of the conductor 242b in FIG. 1B and FIG. 1D, the present invention is not limited thereto. For example, as illustrated in FIG. 4B and FIG. 4D, an insulator 271a may be provided between the conductor 242a and the insulator 275, and an insulator 271b may be provided between the conductor 242b and the insulator 275.

The insulator 271a and the insulator 271b function as etching stoppers for protecting the conductor 242a and the conductor 242b, respectively. Accordingly, as illustrated in FIG. 4B and FIG. 4D, it is preferable that a side end portion of the insulator 271a be aligned with a side end portion of the conductor 242a and a side end portion of the insulator 271b be aligned with a side end portion of the conductor 242b in the cross-sectional view of the transistor 200.

Since the insulator 271a and the insulator 271b are respectively in contact with the conductor 242a and the conductor 242b, the insulator 271a and the insulator 271b are preferably inorganic insulators that are less likely to oxidize the conductor 242a and the conductor 242b. For example, an insulator that can be used for the insulator 275 is preferably used for the insulator 271a and the insulator 271b.

Although FIG. 4B and FIG. 4D illustrate each of the insulator 271a and the insulator 271b as a single layer, the present invention is not limited thereto. Each of the insulator 271a and the insulator 271b may have a stacked-layer structure.

Although the insulator 283 is provided in contact with the top surface of the insulator 280, the top surface of the insulator 250, and the top surface of the conductor 260 in FIG. 1B to FIG. 1D, the present invention is not limited thereto. For example, as illustrated in FIG. 4B to FIG. 4D, an insulator 282 may be provided between the insulator 283 and the insulator 280, the insulator 250, and the conductor 260.

As the insulator 282, an insulator enabling oxygen to be added to the insulator 280 is preferably used. As the insulator 282, for example, aluminum oxide is preferably used. In that case, the insulator 282 contains at least oxygen and aluminum. The insulator 282 or an insulating film to be the insulator 282 is preferably deposited by a sputtering method and further preferably deposited by a sputtering method in an oxygen-containing atmosphere. The insulator 282 is deposited by a sputtering method in an oxygen-containing atmosphere, whereby oxygen can be added to the insulator 280 during the deposition. Thus, excess oxygen can be contained in the insulator 280.

As the insulator 282, a metal oxide having an amorphous structure is preferably used. In such a metal oxide having an amorphous structure, an oxygen atom with a dangling bond exists and sometimes has a property of capturing or fixing hydrogen with the dangling bond. When such a metal oxide having an amorphous structure is used as a component of the transistor 200 or provided around the transistor 200, hydrogen contained in the transistor 200 can be captured or fixed. In particular, hydrogen contained in the channel formation region of the transistor 200 is preferably captured or fixed. With this structure, the transistor 200 with favorable characteristics and high reliability can be manufactured.

Note that the insulator 282 preferably has an amorphous structure but may partly include a region having a polycrystalline structure. Alternatively, the insulator 282 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

Although the insulator 282 being a single layer is illustrated in FIG. 4B to FIG. 4D, the present invention is not limited thereto. The insulator 282 may have a stacked-layer structure.

### Structure Example 1-2

Although FIG. 1A to FIG. 1D illustrate the case where the transistor 200 has a single-gate structure, which includes one gate, the present invention is not limited to this structure. For example, the transistor 200 may include a back gate.

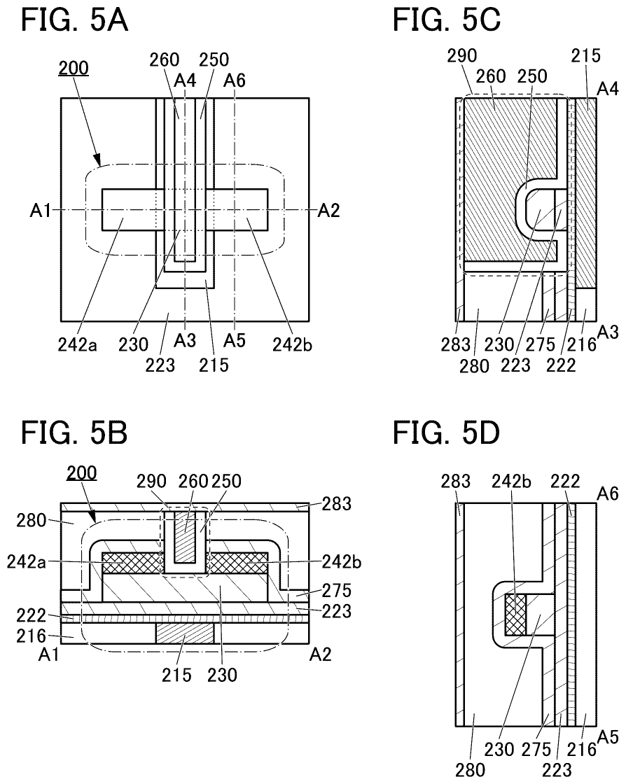

Another structure example of a semiconductor device is described with reference to FIG. 5A to FIG. 5D. FIG. 5A to FIG. 5D are a plan view and cross-sectional views of a semiconductor device. The semiconductor device illustrated in FIG. 5A to FIG. 5D is different from the semiconductor device illustrated in FIG. 1A to FIG. 1D mainly in including a conductor 215 and an insulator 216. Portions different from the above description of [Structure example 1-1] are mainly described below; description of the same portion is omitted in some cases and the description of [Structure example 1-1] is referred to.

As illustrated in FIG. 5A to FIG. 5D, the insulator 216 and the conductor 215 are provided below the insulator 222. The conductor 215 is placed to be embedded in an opening portion formed in the insulator 216. Here, the top surface of the conductor 215 is level with the top surface of the insulator 216.

In the transistor 200 illustrated in FIG. 5A to FIG. 5D, the conductor 260 functions as a first gate (also referred to as a top gate) electrode, and the conductor 215 functions as a second gate (also referred to as a back gate) electrode. The insulator 250 functions as a first gate insulator, and part of the insulator 222 and part of the insulator 223 function as a second gate insulator. Thus, it can be said that the transistor 200 further includes the conductor 215 and the insulator 222.

The conductor 215 includes a region overlapping with the conductor 260 with the insulator 222, the insulator 223, the oxide semiconductor 230, and the insulator 250 therebetween.

As illustrated in FIG. 5B, the conductor 215 is preferably provided to be larger than a region of the oxide semiconductor 230 that does not overlap with the conductor 242a and the conductor 242b. As illustrated in FIG. 5C, it is particularly preferable that the conductor 215 extend to a region outside end portions of the oxide semiconductor 230 in the channel width direction. That is, the conductor 215 and the conductor 260 preferably overlap with each other with the insulators therebetween on the outer side of the side surface of the oxide semiconductor 230 in the channel width direction. With such a structure, the channel formation region of the oxide semiconductor 230 can be electrically surrounded by the electric field of the conductor 260 functioning as a first gate electrode and the electric field of the conductor 215 functioning as the second gate electrode.

Note that in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor 200 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 200 has the S-Channel structure, the GAA structure, or the LGAA structure, the channel formation region that is formed at the interface between the oxide semiconductor 230 and the gate insulator or in the vicinity of the interface can be formed in the entire bulk of the oxide semiconductor 230. Accordingly, the density of current flowing through the transistor can be increased, which can be expected to increase the on-state current of the transistor or increase the field-effect mobility of the transistor.

Furthermore, as illustrated in FIG. 5C, the conductor 215 is extended to function as a wiring as well. However, without limitation to this structure, a structure in which a conductor functioning as a wiring is provided below the conductor 215 may be employed. In addition, the conductor 215 is not necessarily provided in each transistor. For example, the conductor 215 may be shared by a plurality of transistors.

Although FIG. 5B shows a structure where the conductor 215 is provided as a single layer, the present invention is not limited this structure. For example, the conductor 215 may have a stacked-layer structure of two or more layers.

The conductor 215 sometimes functions as the second gate electrode. In that case, by changing a potential applied to the conductor 215 not in conjunction with but independently of a potential applied to the conductor 260, the threshold voltage (Vₜₕ) of the transistor 200 can be controlled. In particular, by applying a negative potential (a potential lower than the source potential) to the conductor 215, Vₜₕ of the transistor 200 can be higher, and its off-state current can be reduced. Thus, a drain current at the time when a potential applied to the conductor 260 is 0 V can be lower in the case where a negative potential is applied to the conductor 215 than in the case where the negative potential is not applied to the conductor 215.

The electric resistivity of the conductor 215 is designed in consideration of the potential applied to the conductor 215, and the thickness of the conductor 215 is determined in accordance with the electric resistivity. The thickness of the insulator 216 is substantially equal to that of the conductor 215. Here, the conductor 215 and the insulator 216 are preferably as thin as possible in the allowable range of the design of the conductor 215. When the thickness of the insulator 216 is reduced, the absolute amount of impurities such as hydrogen contained in the insulator 216 can be reduced, inhibiting diffusion of the impurities into the oxide semiconductor 230.

The insulator 216, which functions as an interlayer film, preferably has a low dielectric constant. When a material with a low dielectric constant is used for an interlayer film, parasitic capacitance generated between wirings can be reduced. As the insulator 216, a single layer or stacked layers of insulators containing any of the materials with low dielectric constants in the later-described section [Insulator] can be used. Silicon oxide and silicon oxynitride are preferable because of being thermally stable.

The concentration of impurities such as water and hydrogen in the insulator 216 is preferably reduced. This can inhibit entry of impurities such as water and hydrogen into the channel formation region of the oxide semiconductor 230.

### Structure Example 1-3

Although the side end portion of the conductor 242a and the side end portion of the oxide semiconductor 230 are aligned with each other and the side end portion of the conductor 242b and the side end portion of the oxide semiconductor 230 are aligned with each other in FIG. 5A to FIG. 5D, the present invention is not limited to this structure. For example, the conductor 242a and the conductor 242b may each include a region in contact with the side surface of the oxide semiconductor 230.

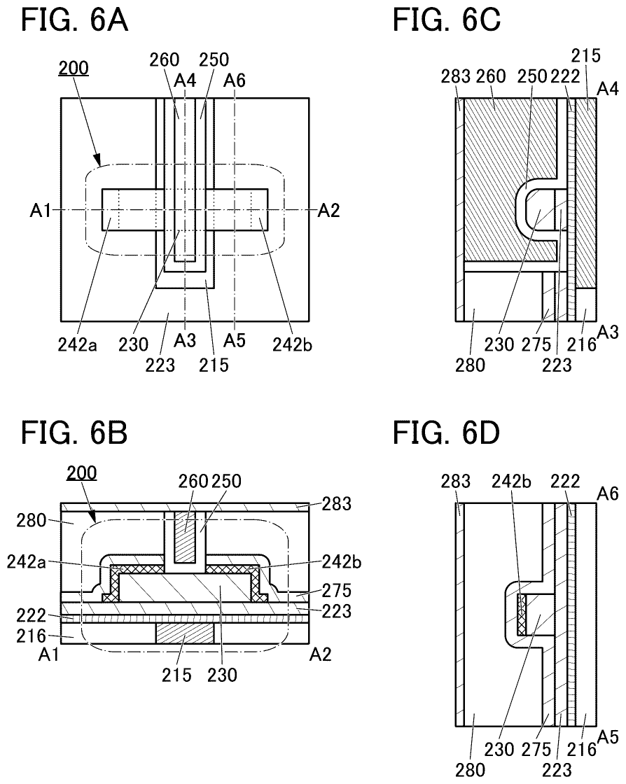

Another structure example of the semiconductor device is described with reference to FIG. 6A to FIG. 6D. FIG. 6A to FIG. 6D are a top view and cross-sectional views of the semiconductor device including the transistor 200. The transistor 200 illustrated in FIG. 6A to FIG. 6D is different from the transistor 200 illustrated in FIG. 5A to FIG. 5D mainly in the shapes of the conductor 242a and the conductor 242b. Portions different from the above description of [Structure example 1-1] and [Structure example 1-2] are mainly described below; the description of the same portions is omitted in some cases and the description of [Structure example 1-1] and [Structure example 1-2] is referred to.

The conductor 242a includes a region in contact with the top surface of the insulator 223 and the side surface of the oxide semiconductor 230 on the A1 side. The conductor 242b includes a region in contact with the top surface of the insulator 223 and the side surface of the oxide semiconductor 230 on the A2 side. With such a structure, the contact area between the oxide semiconductor 230 and each of the conductor 242a and the conductor 242b can be increased, so that the on-state current, field-effect mobility, and frequency characteristics of the transistor 200 can be improved.

The conductor 242a may include a region extending in the channel length direction, the channel width direction, or the like of the transistor 200. In that case, the conductor 242a can also function as a wiring. The same applies to the conductor 242b.

### Structure Example 1-4

Although the insulator 250 is in contact with the side surface of the insulator 280, the side surface of the insulator 275, and the side surface of the insulator 223 in the opening portion 290 in FIG. 5A to FIG. 5D, the present invention is not limited to this structure. For example, in the opening portion 290, an insulator may be provided between the insulator 250 and the insulator 280, the insulator 275, and the insulator 223.

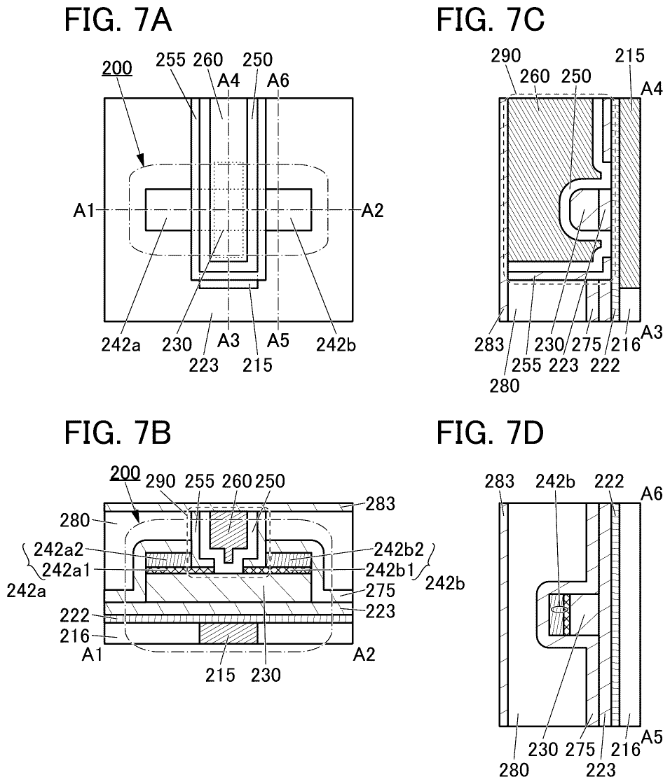

Another structure example of the semiconductor device is described with reference to FIG. 7A to FIG. 7D. FIG. 7A to FIG. 7D are a top view and cross-sectional views of the semiconductor device including the transistor 200. The transistor 200 illustrated in FIG. 7A to FIG. 7D is different from the transistor 200 illustrated in FIG. 5A to FIG. 5D mainly in including an insulator 255. FIG. 7A to FIG. 7D illustrate a structure in which the conductor 242a and the conductor 242b each have a stacked-layer structure of two layers. Portions different from the above description of [Structure example 1-1] and [Structure example 1-2] are mainly described below; the description of the same portions is omitted in some cases and the description of [Structure example 1-1] and [Structure example 1-2] is referred to.

The conductor 242a includes the conductor 242a1 and the conductor 242a2 over the conductor 242a1, and the conductor 242b includes the conductor 242b1 and the conductor 242b2 over the conductor 242b1.

The insulator 255 is provided between the insulator 250 and the insulator 280, the insulator 275, and the insulator 223. Specifically, in the opening portion 290, the insulator 250 is in contact with the side surface of the insulator 280, the side surface of the insulator 250, the side surface of the conductor 242a2, the top surface of the conductor 242a1, the side surface of the conductor 242b2, the top surface of the conductor 242b1, the side surface of the insulator 223, and the top surface of the insulator 222. The insulator 255 includes an opening portion in a region between the conductor 242a1 and the conductor 242b1. Hereinafter, the opening portion provided in the insulator 255 is referred to as a fourth opening portion.

As illustrated in FIG. 7B, in a cross-sectional view of the transistor 200 in the channel length direction, a distance between the conductor 242a1 and the conductor 242b1 (referred to as a first distance) is smaller than a distance between the conductor 242a2 and the conductor 242b2 (referred to as a second distance). With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operation speed.

The opening portion 290 overlaps with a region between the conductor 242a2 and the conductor 242b2. The conductor 242a1 and the conductor 242b1 are formed to partly extend toward the inside of the opening portion 290. Thus, in the opening portion 290, the insulator 255 is in contact with the top surface of the conductor 242a1, the top surface of the conductor 242b1, the side surface of the conductor 242a2, and the side surface of the conductor 242b2. The insulator 250 is in contact with the top surface of the oxide semiconductor 230 in a region between the conductor 242a1 and the conductor 242b1.

The insulator 255 is preferably an insulator that is not easily oxidized, such as nitride. The insulator 255 is formed in contact with the side surface of the conductor 242a2 and the side surface of the conductor 242b2 and has a function of protecting the conductor 242a2 and the conductor 242b2. Heat treatment in an atmosphere containing oxygen is preferably performed after the separation into the conductor 242a2 and the conductor 242b2 and before the formation of the insulator 250. At this time, since the insulator 255 is formed in contact with the side surface of the conductor 242a2 and the side surface of the conductor 242b2, excessive oxidation of the conductor 242a2 and the conductor 242b2 can be prevented.

The thickness of the insulator 255 is preferably greater than or equal to 1 nm and less than or equal to 20 nm, further preferably greater than or equal to 1 nm and less than or equal to 15 nm, still further preferably greater than or equal to 3 nm and less than or equal to 10 nm, and for example, can be approximately 5 nm. When the insulator 255 has the above thickness, the distance between the conductor 260 and the conductor 242a or the conductor 242b can be increased, so that the parasitic capacitance can be reduced. In this case, at least part of the insulator 255 has a region with the above-described thickness.

As the insulator 255, an insulator that can be used as the insulator 223 described above is preferably used. For the insulator 255, silicon nitride is preferably used, for example, and silicon nitride formed by an ALD method is further preferably used. By an ALD method, the insulator 255 can be formed to have a small thickness and good coverage on the sidewalls of the first opening portion and the second opening portion, the side surfaces of the conductor 242a2 and the conductor 242b2, and the like.

A portion of the insulator 255 that is placed in the opening portion 290 reflects the shape of the opening portion 290. Thus, the insulator 255 is provided to cover part of the bottom portion and the sidewall of the opening portion 290.

Portions of the insulator 250 and the conductor 260 that are placed in the opening portion 290 and the fourth opening portion reflect the shapes of the opening portion 290 and the fourth opening portion. Thus, the insulator 250 is provided to cover the insulator 255 and the bottom portion and the sidewall of the fourth opening portion, and the conductor 260 is provided to fill a depressed portion of the insulator 250 that reflects the shapes of the opening portion 290 and the fourth opening portion.

As illustrated in FIG. 7B, in a cross-sectional view of the transistor 200 in the channel length direction, the conductor 260 includes a first region having a first width and a second region having a second width and being over the first region. The first width is smaller than the second width.

### Structure Example 1-5

Although the insulator 255 in FIG. 7A to FIG. 7D includes a region positioned between the insulator 250 and the oxide semiconductor 230, the present invention is not limited to this structure. For example, the insulator 255 does not necessarily include a region positioned between the insulator 250 and the oxide semiconductor 230.

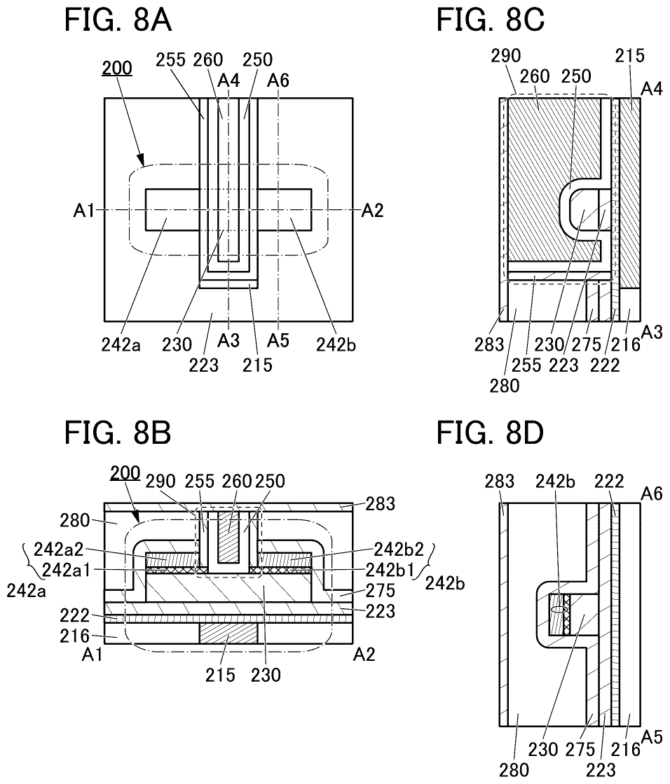

Another structure example of the semiconductor device is described with reference to FIG. 8A to FIG. 8D. FIG. 8A to FIG. 8D are a top view and cross-sectional views of the semiconductor device including the transistor 200. The transistor 200 illustrated in FIG. 8A to FIG. 8D is different from the transistor 200 illustrated in FIG. 7A to FIG. 7D mainly in the shapes of the insulator 255, the insulator 250, and the conductor 260. Portions different from the above description of [Structure example 1-4] and the like are mainly described below; the description of the same portions is omitted in some cases and the description of [Structure example 1-4] and the like is referred to.

As illustrated in FIG. 8B, in a cross-sectional view of the transistor 200 in the channel length direction, the distance between the conductor 242a1 and the conductor 242b1 (the first distance) is smaller than the distance between the conductor 242a2 and the conductor 242b2 (the second distance). Specifically, the difference between the first distance and the second distance is equal to twice the thickness of the insulator 255. In other words, the first distance is equal to the sum of the second distance and twice the thickness of the insulator 255. Here, the thickness of the insulator 255 corresponds to the thickness in the A1-A2 direction of at least part of the insulator 255. With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operation speed.

In a cross-sectional view of the transistor 200 in the channel length direction, the side surface of the insulator 255 on the insulator 250 side is aligned with the side surface of the conductor 242a1. The side surface of the insulator 255 on the insulator 250 side is aligned with the side surface of the conductor 242b1.

By anisotropic etching, the insulator 255 is formed in a sidewall shape to be in contact with a sidewall of the opening portion 290. The insulator 255 is formed in contact with the side surface of the conductor 242a2 and the side surface of the conductor 242b2 and has a function of protecting the conductor 242a2 and the conductor 242b2. Note that heat treatment in an atmosphere containing oxygen is preferably performed after the separation into the conductor 242a1 and the conductor 242b1 and before the formation of the insulator 250. At this time, since the insulator 255 is formed in contact with the side surface of the conductor 242a2 and the side surface of the conductor 242b2, excessive oxidation of the conductor 242a2 and the conductor 242b2 can be prevented. Furthermore, even in the case where microwave treatment is performed after the division of the conductive layer into the conductor 242a1 and the conductor 242b1, formation of an oxide film on the side surfaces of the conductor 242a and the conductor 242b can be inhibited.

Portions of the insulator 250 and the conductor 260 that are placed in the opening portion 290 reflect the shape of the opening portion 290. Thus, the insulator 250 is provided to cover the insulator 255, the bottom portion and the sidewall of the opening portion, and the conductor 260 is provided to fill a depressed portion defined by the insulator 250.

### Structure Example 1-6

Although the oxide semiconductor 230 is provided over the insulator 223 in FIG. 1A to FIG. 1D, the present invention is not limited to this structure. For example, an insulator may be provided between the insulator 223 and the oxide semiconductor 230.

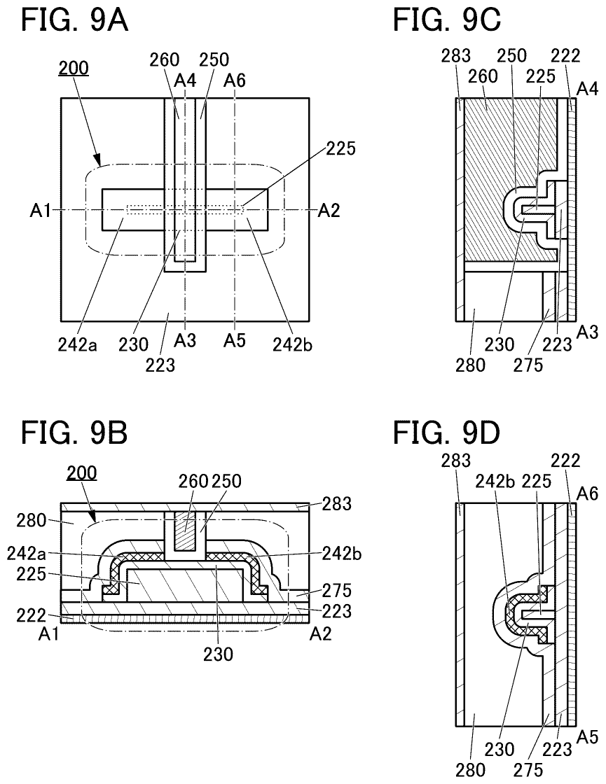

Another structure example of the semiconductor device is described with reference to FIG. 9A to FIG. 9D. FIG. 9A to FIG. 9D are a top view and cross-sectional views of the semiconductor device including the transistor 200. The transistor 200 illustrated in FIG. 9A to FIG. 9D is different from the transistor 200 illustrated in FIG. 1A to FIG. 1D mainly in including an insulator 225. Portions different from the above description of [Structure example 1-1] are mainly described below; the description of the same portions is omitted in some cases and the description of [Structure example 1-1] is referred to.

The insulator 225 is provided between the insulator 223 and the oxide semiconductor 230. Specifically, the insulator 225 is provided over the insulator 223, and the oxide semiconductor 230 is provided to cover the top surface and the side surface of the insulator 225. The oxide semiconductor 230 is in contact with the top surface and the side surface of the insulator 225 and the top surface of the insulator 223.

In the above structure, the source region and the drain region are each surrounded by the insulator 223 and the insulator 275 together with the insulator 225. Each of the source region and the drain region is in contact with the insulator 223, the insulator 225, and the insulator 275.

The channel formation region is surrounded by the insulator 223 and the insulator 250 together with the insulator 225. The channel formation region is in contact with the insulator 223, the insulator 225, and the insulator 250.

As described above, since the insulator 225 is surrounded by the insulator 223 and the insulator 275, there is no particular limitation on the material used for the insulator 225. For example, the insulator 225 is formed with an insulating material that can be used for the insulator 222, the insulator 223, the insulator 280, the insulator 250, or the like. Since the insulator 225 has a shape with a high aspect ratio, the insulator 225 is preferably formed in a sidewall shape on the side surface of the sacrificial layer. The insulator 225 is preferably formed by an ALD method that provides good coverage. For example, silicon nitride or hafnium oxide deposited by an ALD method can be used for the insulator 225. In the case where silicon nitride is used for the insulator 225, the insulator 225 contains silicon and nitrogen.

The insulator 225 is formed over and in contact with the insulator 222. As illustrated in FIG. 9C, the insulator 225 has a shape with a high aspect ratio in the cross-sectional view in the channel width direction. Here, the aspect ratio of the insulator 225 in the cross-sectional view in the channel width direction refers to the ratio of the length of the insulator 225 in the A3-A4 direction to the length perpendicular to the formation surface of the insulator 225. Here, the length of the insulator 225 in the A3-A4 direction can also be referred to as the width of the insulator 225 or the length of the insulator 225 in the direction in which the conductor 260 extends. The formation surface of the insulator 225 is the insulator 222, for example. The length in the direction perpendicular to the formation surface of the insulator 225 can also be referred to as the height of the insulator 225.

The height of the insulator 225 is larger than at least the length of the insulator 225 in the A3-A4 direction. The height of the insulator 225 is greater than one time the width of the insulator 225, preferably greater than or equal to twice, further preferably greater than or equal to five times, still further preferably greater than or equal to ten times the width of the insulator 225. The height of the insulator 225 is preferably less than or equal to 20 times the width of the insulator 225.

The oxide semiconductor 230, the conductor 242a, and the conductor 242b are provided to cover the insulator 225 having such a high aspect ratio. In the transistor 200, as illustrated in FIG. 9C, the oxide semiconductor 230 is provided to be folded in half with the insulator 225 therebetween, and the insulator 250 and the conductor 260 are provided to cover the oxide semiconductor 230. Thus, in a cross-sectional view in the channel width direction, the oxide semiconductor 230 and the conductor 260 face each other with the insulator 250 therebetween in the upper portion, the side surface on the A3 side, and the side surface on the A4 side of the insulator 225. That is, the oxide semiconductor 230 positioned in the upper portion, the side surface on the A3 side, and the side surface on the A4 side of the insulator 225 functions as a channel formation region. Thus, the channel width of the transistor 200 is larger than that in the case where the insulator 225 is not provided by the oxide semiconductor 230 positioned on the side surface on the A3 side and the side surface on the A4 side of the insulator 225.

The transistor 200 having such a large channel width can have a high on-state current, high field-effect mobility, excellent frequency characteristics, and the like. Thus, a semiconductor device with high operating speed can be provided. In the above structure, providing the insulator 225 enables the channel width to be increased without an increase in the area occupied by the transistor 200. In this manner, miniaturization and high integration of the semiconductor device can be achieved.

As illustrated in FIG. 9C, the oxide semiconductor 230 is provided to be folded in half with the insulator 225 therebetween. Also in the oxide semiconductor 230 in such a state, the c-axis of the crystal included in the oxide semiconductor 230 is preferably aligned in a direction perpendicular to the channel length direction. Furthermore, the c-axis of the crystal included in the channel formation region is preferably aligned in a direction perpendicular to the channel length direction. With such a structure, the layer included in the crystal extends in the channel length direction of the transistor 200, so that the on-state current of the transistor 200 can be increased.

As described in [Structure example 1-1], it is preferable that the c-axis of a crystal included in the vicinity of the side surface of the region 231c that faces the insulator 250 be also aligned in a direction perpendicular to the channel length direction. In other words, it is preferable that the region 231c have a crystal on its side surface in the vicinity of the insulator 250 and the c-axis of the crystal be aligned in a direction perpendicular to the channel length direction. In that case, in the structure illustrated in FIG. 9C, the layer included in the crystal extends parallel or substantially parallel to the surface (the top surface or the side surface) of the oxide semiconductor 230. In addition, the layer included in the crystal extends parallel or substantially parallel to the formation surface of the oxide semiconductor 230.

### <Materials for Semiconductor Device>

Materials that can be used for the semiconductor device are described below.

### [Substrate]

As the substrate where the transistor 200 is formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. In contrast, when a low-dielectric-constant material is used for the insulator functioning as an interlayer film, parasitic capacitance generated between wirings can be reduced. Thus, a material is preferably selected depending on the function of the insulator. Note that the low-dielectric-constant material is a material with high dielectric strength.

Examples of the high-dielectric-constant (high-k) material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the low-dielectric-constant material include inorganic insulating materials such as silicon oxide, silicon oxynitride, and silicon nitride oxide and resins such as polyester, polyolefin, polyamide (e.g., nylon and aramid), polyimide, polycarbonate, and acrylic. Other examples of low-dielectric-constant inorganic insulating materials include silicon oxide to which fluorine is added, silicon oxide to which carbon is added, and silicon oxide to which carbon and nitrogen are added. Another example is porous silicon oxide. Note that these silicon oxides may contain nitrogen.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of the semiconductor layer, such as a gate insulator, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of the barrier insulator against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the barrier insulator against hydrogen include aluminum oxide, magnesium oxide, hafnium oxide, gallium oxide, indium gallium zinc oxide, silicon nitride, and silicon nitride oxide.

The barrier insulator against oxygen and the barrier insulator against hydrogen can each be regarded as an barrier insulator against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond and sometimes has a property of capturing or fixing hydrogen with the dangling bond. Note that these metal oxides preferably have an amorphous structure, but a crystal region may be partly formed.

Note that in this specification and the like, a barrier insulator refers to an insulator having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule and OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is less likely to be oxidized, a conductive material having a function of inhibiting oxygen diffusion, or a material maintaining its conductivity even after absorbing oxygen. Note that examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

In addition, a conductive material containing tungsten, copper, or aluminum as its main component is preferable because it has high conductivity.

A stack of a plurality of conductive layers formed of the above-described materials may be used. For example, a stacked-layer structure combining a material containing the above-described metal element and a conductive material containing oxygen may be employed. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes has a lattice defect. Examples of the lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor might lead to unstable electrical characteristics of the transistor. Hence, a metal oxide used in a semiconductor layer, especially a channel formation region, of a transistor preferably has a small number of lattice defects.

The kind of lattice defect that is likely to exist in a metal oxide and the number of lattice defects that exist vary depending on the structure of the metal oxide, a film formation method of the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, a transistor with high reliability can be achieved.

For the channel formation region of a transistor, a metal oxide that increases the on-state current of the transistor is preferably used. To increase the on-state current of the transistor, the carrier mobility of the metal oxide used for the transistor is increased. To increase the carrier mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal further preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS, and the like.

The c-axis of the above crystal is preferably aligned in the normal direction with respect to the formation surface or film surface of the metal oxide. This enables the plurality of layers to be placed parallel or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or plurality of metal elements included in the first layer is preferably equal to the valence of the one or plurality of metal elements included in the second layer. The first layer and the second layer may include the same metal element. The valence of the one or plurality of metal elements included in the first layer is preferably different from the valence of the one or plurality of metal elements included in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three kinds selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

For example, as the metal oxide semiconductor of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be given as an example.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with large period numbers in the periodic table of the elements can have high field-effect mobility in some cases. Examples of the metal element with large period numbers in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Accordingly, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, an atomic layer is preferably deposited one by one. Since an ALD method is employed as the film formation method of a metal oxide in one embodiment of the present invention, a metal oxide having the layered crystal structure is easily formed.

### [[Transistor Including Metal Oxide]]

Next, the case where a metal oxide (oxide semiconductor) is used for a transistor will be described. Hereinafter, a transistor with a semiconductor layer of an oxide semiconductor is sometimes referred to as an OS transistor, and a transistor with a semiconductor layer of silicon is sometimes referred to as a Si transistor.

The use of the metal oxide (oxide semiconductor) of one embodiment of the present invention for a transistor enables the transistor to have high field-effect mobility. In addition, a transistor with high reliability can be achieved. Furthermore, a miniaturized or highly integrated transistor can be achieved. For example, a transistor with a channel length of greater than or equal to 2 nm and less than or equal to 30 nm can be manufactured.

An oxide semiconductor having a low carrier concentration is preferably used for a channel formation region of a transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1× 10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that impurities in an oxide semiconductor refer to, for example, elements other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, an OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be manufactured, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure where the channel formation region is an n⁻-type region and the source region and the drain region are n⁺-type regions.

The OS transistor with the above structure can have favorable electrical characteristics even when a storage device is miniaturized or highly integrated. For example, the OS transistor can have favorable electrical characteristics even when the channel length or gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### [[Impurity in Metal Oxide]]

Here, the influence of each impurity in the metal oxide (oxide semiconductor) will be described.

When silicon or carbon, which is one of Group 14 elements, is contained in the oxide semiconductor, defect states are formed in the oxide semiconductor. Accordingly, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### [Other Semiconductor Materials]

The oxide semiconductor 230 can be rephrased as a semiconductor layer including a channel formation region of the transistor. A semiconductor material that can be used for the semiconductor layer is not limited to the above metal oxides. A semiconductor material that has a band gap (a semiconductor material that is not a zero-gap semiconductor) may be used for the semiconductor layer. For example, a single-element semiconductor, a compound semiconductor, or a layered substance (also referred to as an atomic layer substance or a two-dimensional material) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon, nitrogen, and boron atoms arranged in a hexagonal lattice structure on a plane. Chalcogenide is a compound containing chalcogen. Chalcogen is a general term for elements belonging to Group 16, which includes oxygen, sulfur, selenium, tellurium, polonium, and livermorium. Examples of chalcogenide include transition metal chalcogenide and chalcogenide of Group 13 elements. For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a storage device with a high on-state current to be provided.

### Modification Example 1

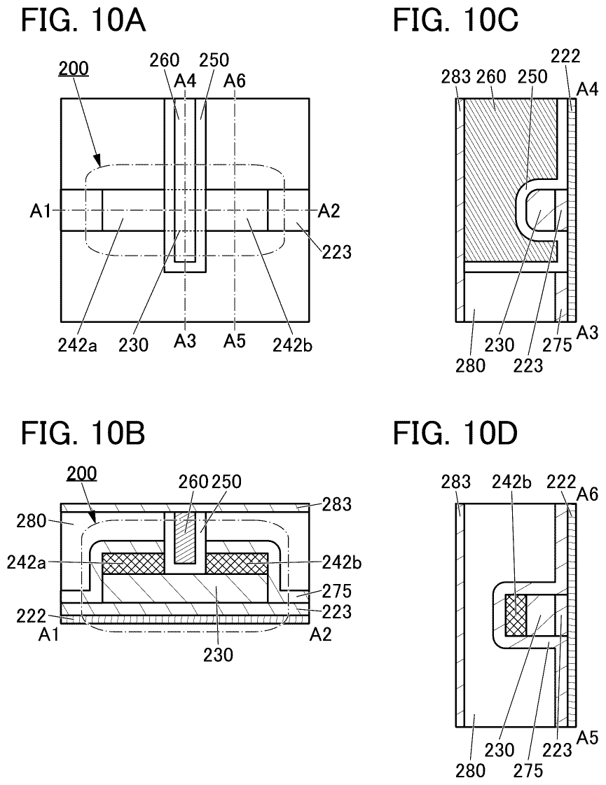

An example of the semiconductor device of one embodiment of the present invention is described below with reference to FIG. 10A to FIG. 13D.

The semiconductor devices illustrated in the respective diagrams with reference to A to D among FIG. 10A to FIG. 13D are each different from the semiconductor device illustrated in FIG. 1A to FIG. 1D in the shape of the insulator 223. Portions different from the above description of <Structure example 1> are mainly described below; description of the same portion is omitted in some cases and the description of <Structure example 1> is referred to.

In the semiconductor device illustrated in the respective diagrams with reference to A to D, components having the same functions as the components included in the semiconductor device described in <Structure example 1> are denoted by the same reference numerals. Note that the materials described in detail in <Structure example 1> can be used as materials for the semiconductor device also in this section.

### Modification Example 1-1

FIG. 10A to FIG. 10D illustrate a modification example of the semiconductor device illustrated in FIG. 1A to FIG. 1D. FIG. 10A to FIG. 10D are a plan view and cross-sectional views of the semiconductor device.

In the semiconductor device illustrated in FIG. 10A to FIG. 10D, the insulator 223 is processed into a band-like shape. For example, as illustrated in FIG. 10A and FIG. 10B, the insulator 223 is provided to extend in the channel length direction (A1-A2 direction).

As illustrated in FIG. 10A and FIG. 10D, the side end portion of the insulator 223 on the A5 side is aligned with the side end portion of the oxide semiconductor 230 on the A5 side. A side end portion of the insulator 223 on the A6 side is aligned with a side end portion of the oxide semiconductor 230 on the A6 side.

In the above structure, as illustrated in FIG. 10B and FIG. 10D, the insulator 275 is provided in contact with the top surface of the insulator 222, the top surface and the side surface of the insulator 223, the side surface of the oxide semiconductor 230, the side surface and the top surface of the conductor 242a, and the side surface and the top surface of the conductor 242b. Also in such a structure, the region 231a and the region 231b are each surrounded by the insulator 223 and the insulator 275.

The insulator 223 is preferably formed before the oxide semiconductor film to be the oxide semiconductor 230 is formed.

Although FIG. 10A and FIG. 10D illustrate a structure in which the side end portion of the insulator 223 is aligned with the side end portion of the oxide semiconductor 230 in a cross-sectional view in the channel width direction, the present invention is not limited thereto. For example, in a cross-sectional view in the channel width direction, the side end portion of the insulator 223 may be positioned outward from the side end portion of the oxide semiconductor 230.

### Modification Example 1-2

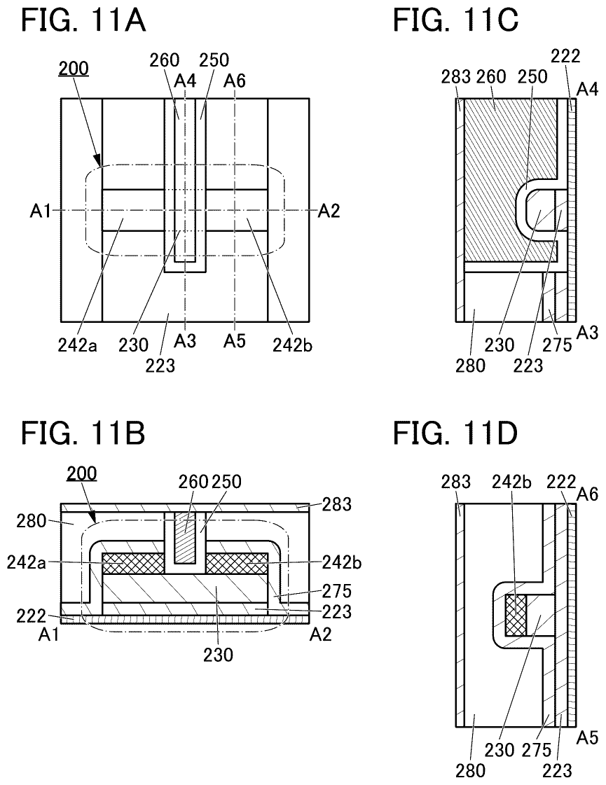

FIG. 11A to FIG. 11D illustrate a modification example of the semiconductor device illustrated in FIG. 1A to FIG. 1D. FIG. 11A to FIG. 11D are a plan view and cross-sectional views of the semiconductor device.

In the semiconductor device illustrated in FIG. 11A to FIG. 11D, the insulator 223 is processed into a band-like shape. For example, as illustrated in FIG. 11A and FIG. 11D, the insulator 223 is provided to extend in the channel width direction (A3-A4 direction). The insulator 223 is provided to extend in the direction in which the conductor 260 extends.

As illustrated in FIG. 11A and FIG. 11B, the side end portion of the insulator 223 on the A1 side is aligned with the side end portion of the oxide semiconductor 230 on the A1 side. A side end portion of the insulator 223 on the A2 side is aligned with a side end portion of the oxide semiconductor 230 on the A2 side.

In the above structure, as illustrated in FIG. 11B and FIG. 11D, the insulator 275 is provided in contact with the top surface of the insulator 222, the top surface and the side surface of the insulator 223, the side surface of the oxide semiconductor 230, the side surface and the top surface of the conductor 242a, and the side surface and the top surface of the conductor 242b. Also in such a structure, the region 231a and the region 231b are each surrounded by the insulator 223 and the insulator 275.

The insulator 223 is preferably formed before the oxide semiconductor film to be the oxide semiconductor 230 is formed.

Although FIG. 11A and FIG. 11B illustrate a structure in which the side end portion of the insulator 223 is aligned with the side end portion of the oxide semiconductor 230 in a cross-sectional view in the channel length direction, the present invention is not limited thereto. For example, in a cross-sectional view in the channel length direction, the side end portion of the insulator 223 may be positioned outward from the side end portion of the oxide semiconductor 230.

### Modification Example 1-3

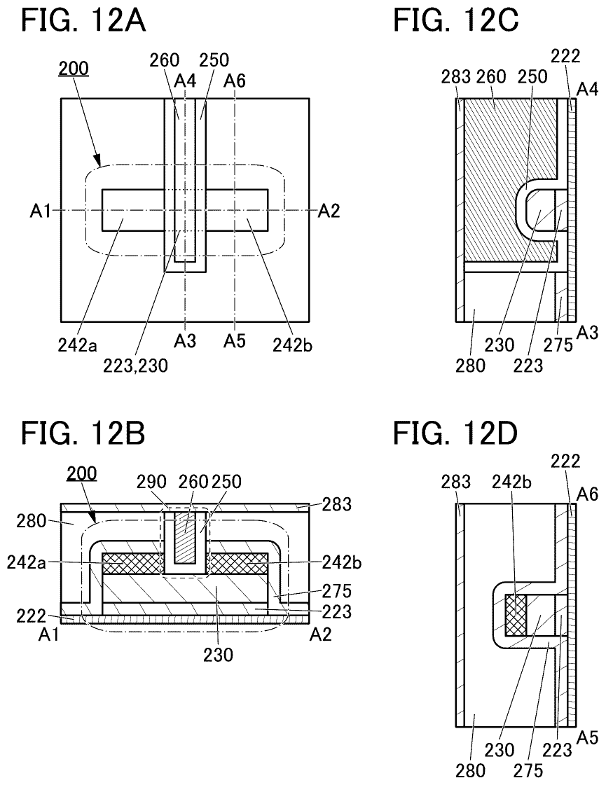

FIG. 12A to FIG. 12D illustrate a modification example of the semiconductor device illustrated in FIG. 1A to FIG. 1E. FIG. 12A to FIG. 12D are a plan view and cross-sectional views of the semiconductor device.

In the semiconductor device illustrated in FIG. 12A to FIG. 12D, the insulator 223 is processed into an island shape. As illustrated in FIG. 12A to FIG. 12D, the side end portion of the insulator 223 is aligned with the side end portion of the oxide semiconductor 230.

Note that in this specification and the like, the term “island shape” or “band shape” refers to a state where two or more layers formed using the same material in the same step are physically separated from each other.

In the above structure, as illustrated in FIG. 12B to FIG. 12D, the insulator 275 is provided in contact with the top surface of the insulator 222, the side surface of the insulator 223, the side surface of the oxide semiconductor 230, the side surface and the top surface of the conductor 242a, and the side surface and the top surface of the conductor 242b. Also in such a structure, the region 231a and the region 231b are each surrounded by the insulator 223 and the insulator 275.

The insulator 223 is preferably formed through the following steps: an insulating film to be the insulator 223 and an oxide semiconductor film to be the oxide semiconductor 230 are formed, and then the oxide semiconductor film and the insulating film are processed into island shapes. When the insulator 223 is formed in such a manner, a side end portion of the insulator 223 and a side end portion of the oxide semiconductor 230 can be aligned with each other.

Note that the method is not limited to the above method, and the insulator 223 may be formed before the oxide semiconductor film to be the oxide semiconductor 230 is formed.

Although FIG. 12A and FIG. 12B illustrate a structure in which the side end portion of the insulator 223 is aligned with the side end portion of the oxide semiconductor 230, the present invention is not limited thereto. For example, in a cross-sectional view in the channel length direction, the side end portion of the insulator 223 may be positioned outward from the side end portion of the oxide semiconductor 230. In the cross-sectional view in the channel width direction, the side end portion of the insulator 223 may be positioned outward from the side end portion of the oxide semiconductor 230.

Although FIG. 12A to FIG. 12D illustrate a structure in which the insulator 222 and the insulator 223 are in contact with each other, the present invention is not limited thereto. For example, an insulator may be provided between the insulator 222 and the insulator 223.

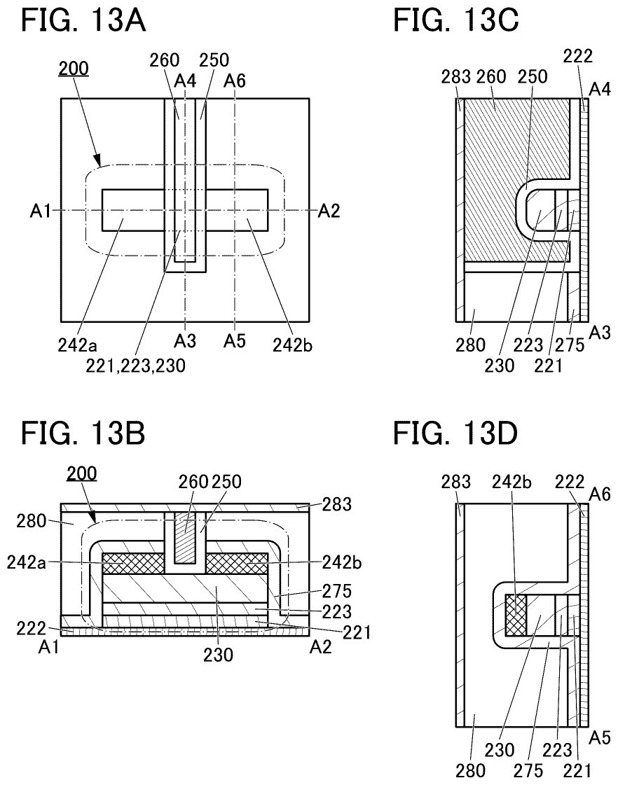

For example, as illustrated in FIG. 13A to FIG. 13D, an island-shaped insulator 221 may be provided between the insulator 222 and the insulator 223. A side end portion of the insulator 221 is aligned with a side end portion of the insulator 223.

The thickness of the insulator 221 is preferably larger than the thickness of the insulator 250. The sum of the thickness of the insulator 221 and the thickness of the insulator 223 is preferably larger than the thickness of the insulator 250. With such a structure, in a cross-sectional view of the transistor 200 in the channel width direction, the bottom surface of the conductor 260 in a region not overlapping with the oxide semiconductor 230 is lower than the bottom surface of the oxide semiconductor 230. The bottom surface of the conductor 260 in the region not overlapping with the oxide semiconductor 230 is positioned closer to the insulator 222 than the bottom surface of the oxide semiconductor 230 is. Thus, the conductor 260 functioning as the gate electrode covers the side surface and the top surface of the channel formation region of the oxide semiconductor 230 with the insulator 250 therebetween, allowing the electric field of the conductor 260 to act easily on the entire channel formation region of the oxide semiconductor 230. Accordingly, the on-state current of the transistor 200 can be increased, and the frequency characteristics of the transistor 200 can be improved.

In the above structure, as illustrated in FIG. 13B and FIG. 13D, the insulator 275 is provided in contact with the top surface of the insulator 222, the side surface of the insulator 221, the side surface of the insulator 223, the side surface of the oxide semiconductor 230, the side surface and the top surface of the conductor 242a, and the side surface and the top surface of the conductor 242b. Also in such a structure, the region 231a and the region 231b are each surrounded by the insulator 223 and the insulator 275.

The insulator 221 is preferably formed through the following steps: an insulating film to be the insulator 221, an insulating film to be the insulator 223, and an oxide semiconductor film to be the oxide semiconductor 230 are formed, and then these films are processed into island shapes. Alternatively, the insulator 221 is preferably formed through the following steps: the insulating film to be the insulator 221 and the insulating film to be the insulator 223 are formed, and then these films are processed into island shapes. When the insulator 221 is formed by any of these methods, the side end portion of the insulator 221 and the side end portion of the insulator 223 can be aligned with each other.

Note that the method is not limited to the above method, and the insulator 221 may be formed before the insulating film to be the insulator 223 is formed.

Although FIG. 13A and FIG. 13B illustrate a structure in which the side end portion of the insulator 221 is aligned with the side end portion of the insulator 223, the present invention is not limited thereto. For example, in a cross-sectional view in the channel length direction, the side end portion of the insulator 221 may be positioned outward from the side end portion of the insulator 223. In the cross-sectional view in the channel width direction, the side end portion of the insulator 221 may be positioned outward from the side end portion of the insulator 223.

The structure body over the insulator 222 and the insulator 223 in the semiconductor device illustrated in respective diagrams with reference to A to D among FIG. 10A to FIG. 13D has the same structure as the structure body over the insulator 222 and the insulator 223 in the semiconductor device illustrated in FIG. 1A to FIG. 1D; however, the present invention is not limited thereto. The structure body over the insulator 222 and the insulator 223 in the semiconductor device illustrated in the respective diagrams with reference to A to D may have the same structure as the structure body over the insulator 222 and the insulator 223 in the semiconductor device illustrated in any of FIG. 4A to FIG. 9D.

Like the semiconductor device illustrated in FIG. 5A to FIG. 5D, the semiconductor device illustrated in respective diagrams with reference to A to D may include the conductor 215 and the insulator 216 below the insulator 222.

### Structure Example 2

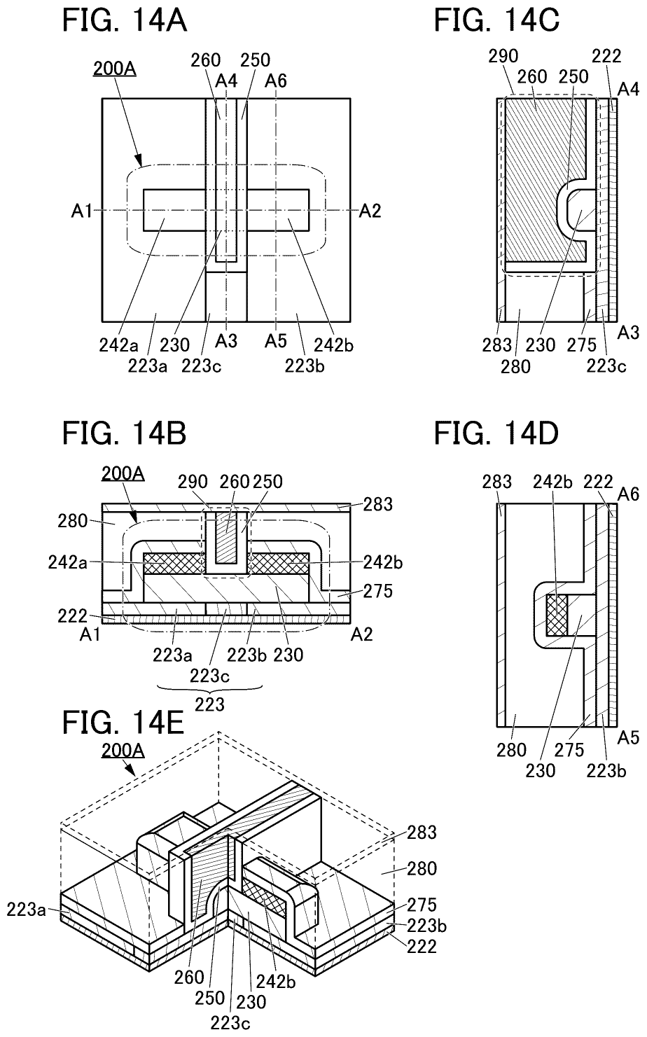

In this section, a semiconductor device having a structure different from that of the above-described semiconductor device described in <Structure example 1> is described with reference to FIG. 14A to FIG. 32D.

In the semiconductor devices illustrated in FIG. 14A to FIG. 32D, components having the same functions as the components included in the semiconductor device described in <Structure example 1> are denoted by the same reference numerals. Note that the materials described in detail in <Structure example 1> can be used as materials for the semiconductor device also in this section.

In <Structure example 1> described above, the channel formation region, the source region, and the drain region of the oxide semiconductor 230 are provided over the insulator 223. That is, the channel formation region, the source region, and the drain region of the oxide semiconductor 230 are provided over the same insulator. In other words, an insulator provided below the channel formation region, an insulator provided below the source region, and an insulator provided below the drain region are formed using the same insulating material.

As described in <Structure example 1> above, a transistor including an oxide semiconductor in a semiconductor layer preferably has a structure in which oxygen is supplied to a channel formation region and oxygen is not excessively supplied to a source region and a drain region. As long as such a structure can be employed, the insulator provided below the channel formation region may be different from the insulator provided below the source region and the insulator provided below the drain region. In other words, the insulator provided below the channel formation region may be formed using an insulating material different from that of the insulator provided below the source region and the insulator provided below the drain region.

### Structure Example 2-1

Another example of the structure of the semiconductor device is described with reference to FIG. 14A to FIG. 14D. FIG. 14A to FIG. 14D are a top view and cross-sectional views of the semiconductor device including a transistor 200A. The semiconductor device illustrated in FIG. 14A to FIG. 14D is different from the semiconductor device illustrated in FIG. 1A to FIG. 1D mainly in the structure of the insulator 223. Points different from the above description in <Structure example 1> are mainly described below; the description of the same portions is omitted in some cases and the description of <Structure example 1> is referred to.

As illustrated in FIG. 14A to FIG. 14D, the insulator 223 includes an insulator 223a, an insulator 223b, and an insulator 223c positioned between the insulator 223a and the insulator 223b. That is, the transistor 200A includes the insulator 223a, the insulator 223b, and the insulator 223c positioned between the insulator 223a and the insulator 223b over the insulator 222. The transistor 200A includes the oxide semiconductor 230 over the insulator 223a, the insulator 223b, and the insulator 223c. The insulator 223a to the insulator 223c are each provided to extend in the channel width direction (A3-A4 direction) of the transistor 200A. The insulator 223a includes a region overlapping with the conductor 242a, the insulator 223b includes a region overlapping with the conductor 242b, and the insulator 223c includes a region overlapping with the insulator 250 and the conductor 260. The top surfaces of the insulator 223a to the insulator 223c are level with each other. In other words, the thicknesses of the insulator 223a to the insulator 223c are equal to each other.

FIG. 14E is a schematic perspective view of the semiconductor device. In FIG. 14E, the insulator 222, the insulator 223, the oxide semiconductor 230, the conductor 242b, the insulator 250, the conductor 260, the insulator 275, and parts of their periphery are cut for easy viewing. In FIG. 14E, only outlines of some components (e.g., the insulator 280 and the insulator 283) are indicated by dashed lines.

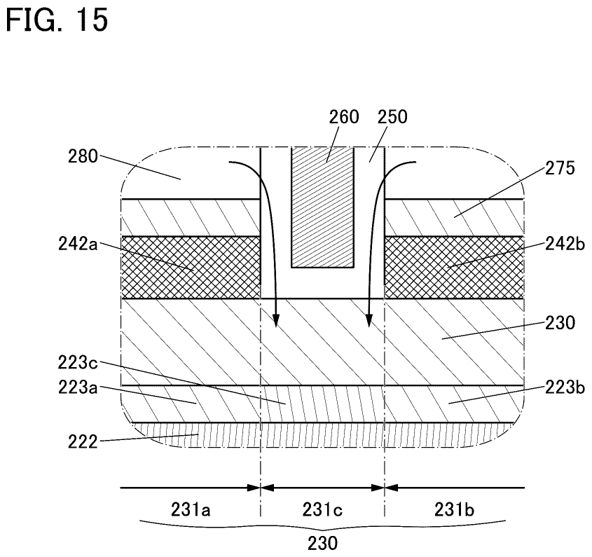

Here, FIG. 15 is an enlarged view of the channel formation region and the vicinity thereof in FIG. 14B. The arrows illustrated in FIG. 15 visualize a state where oxygen contained in the insulator 280 diffuses into the region 231c through the insulator 250.

As illustrated in FIG. 15, the oxide semiconductor 230 includes the region 231a overlapping with the conductor 242a, the region 231b overlapping with the conductor 242b, and the region 231c positioned between the region 231a and the region 231b. The region 231a includes a region overlapping with the insulator 223a, the region 231b includes a region overlapping with the insulator 223b, and the region 231c includes a region overlapping with the insulator 223c.

In the structure illustrated in FIG. 14A to FIG. 14D, the region 231a is surrounded by the insulator 223a and the insulator 275, and the region 231b is surrounded by the insulator 223b and the insulator 275. The region 231a is in contact with the insulator 223a and the insulator 275, and the region 231b is in contact with the insulator 223b and the insulator 275.

As illustrated in FIG. 14C, the insulator 250 is in contact with part of the top surface of the insulator 223c. In that case, the region 231c is surrounded by the insulator 223c and the insulator 250. The region 231c is in contact with the insulator 223c and the insulator 250.

As the insulator 223a, the insulator 223b, and the insulator 275, a barrier insulator against oxygen in the above section [Insulator] is preferably used. For the insulator 223a, the insulator 223b, and the insulator 275, silicon nitride is preferably used, for example. In that case, each of the insulator 223a, the insulator 223b, and the insulator 275 contains at least silicon and nitrogen. With such a structure, the region 231a and the region 231b are supplied with a smaller amount of oxygen than the region 231c; thus, the carrier concentrations in the source region and the drain region can be prevented from being reduced.

Furthermore, it is preferable that the insulator 223a and the insulator 223b have compressive stress, and it is further preferable that the compressive stress of the insulator 223a and the insulator 223b be higher than that of the oxide semiconductor 230. For example, the silicon nitride applicable to the insulator 223a and the insulator 223b has higher compressive stress than the oxide semiconductor 230. The insulator 223a and the insulator 223b are formed using an insulator with compressive stress, particularly, an insulator with higher compressive stress than the oxide semiconductor 230, whereby the distortion extended in the tensile direction (hereinafter, such distortion is sometimes referred to as tensile distortion) can be formed in the region 231a and the region 231b. When VoH is stably formed by the tensile distortion, the region 231a and the region 231b can be stable n-type regions. The compressive stress of the insulator refers to stress for relaxing the compressive shape of the insulator that has a vector in a direction from a center portion to an end portion of the insulator.

Note that silicon nitride formed by an ALD method, particularly a PEALD method, is further preferably used for the insulator 223a, the insulator 223b, and the insulator 275. An ALD method provides excellent step coverage and excellent thickness uniformity and thus is suitable for forming a thin film or covering a surface with a high aspect ratio.

Since the insulator 223a and the insulator 223b preferably have at least a barrier property against oxygen, the thickness of each of the insulator 223a and the insulator 223b is preferably greater than or equal to 1.0 nm, further preferably greater than or equal to 1.4 nm. Although there is no particular limitation on the upper limit of the thicknesses of the insulator 223a and the insulator 223b, for miniaturization or high integration of the semiconductor device, increased productivity of the semiconductor device, and the like, the thickness of each of the insulator 223a and the insulator 223b is preferably less than or equal to 20 nm, less than or equal to 10 nm, or less than or equal to 5.0 nm. Thus, each of the insulator 223a and the insulator 223b preferably includes a region with a thickness greater than or equal to 1.0 nm and less than or equal to 10 nm, further preferably includes a region with a thickness greater than or equal to 1.0 nm and less than or equal to 5.0 nm. Each of the insulator 223a and the insulator 223b preferably includes a region with a thickness greater than or equal to 1.4 nm and less than or equal to 10 nm, further preferably includes a region with a thickness greater than or equal to 1.4 nm and less than or equal to 5.0 nm.

An insulator that can be used as the insulator 223a, the insulator 223b, and the insulator 275 is not limited to silicon nitride. For example, aluminum oxide or hafnium oxide may be used. The insulator 223a, the insulator 223b, and the insulator 275 may each have a stacked-layer structure.

For the insulator 223c, a material different from that for the insulator 223a and the insulator 223b may be used. That is, the barrier property against oxygen of the insulator 223c may be equivalent to the barrier property against oxygen of the insulator 223a and the insulator 223b, or may be higher or lower than that of the insulator 223a and the insulator 223b. For example, oxygen is preferably supplied to the region 231c with which the insulator 223c is in contact; thus, the insulator 223c preferably has a lower barrier property against oxygen than the insulator 223a and the insulator 223b. Note that as long as the insulator 223c has a barrier property against oxygen, the insulator 223c is not limited to an insulating material and may be formed with a semiconductor material.

Silicon nitride oxide, silicon oxynitride, or the like is preferably used for the insulator 223c, for example. For example, metal oxide such as hafnium oxide, gallium oxide, gallium zinc oxide, or indium gallium zinc oxide is preferably used for the insulator 223c. Such a structure enables oxygen to be supplied to the region 231c efficiently, resulting in formation of an i-type channel formation region.

For example, when an insulator containing more oxygen than nitride as compared with silicon nitride, such as silicon nitride oxide or silicon oxynitride, is used as the insulator 223c, the amount of nitrogen diffusing into the channel formation region can be reduced. Furthermore, the use of the above metal oxide for the insulator 223c can inhibit entry of nitrogen into the channel formation region.

The insulator 223a to the insulator 223c are preferably formed before the oxide semiconductor film to be the oxide semiconductor 230 is formed.

For example, in the case where the etching selectivity of the insulator 275 to the insulator 223c is high, the insulator 223c functions as an etching stopper film used in forming an opening portion by etching the insulator 275. At this time, the insulator 223c in a region overlapping with the opening portion formed in the insulator 275 and not overlapping with the oxide semiconductor 230 remains (see FIG. 14C). Thus, the insulator 223c is provided as a continuous insulator extending in the channel width direction (A3-A4 direction).

For example, in the case where the etching selectivity of the insulator 275 to the insulator 223c is low, the insulator 223c in a region overlapping with the oxide semiconductor 230 remains and the insulator 223c in a region not overlapping with the oxide semiconductor 230 is removed through etching the insulator 275 to form the opening portion. That is, an opening portion is formed in the insulator 223c. At this time, the insulator 250 is in contact with part of the top surface of the insulator 222 in the opening portion formed in the insulator 223c (see FIG. 16A to FIG. 16D).

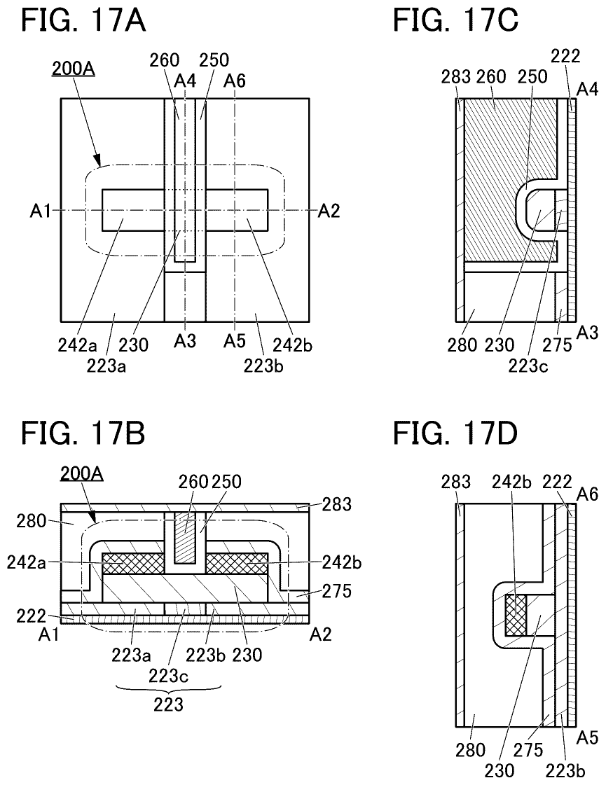

For another example, in the case where the etching selectivity of the oxide semiconductor 230 to the insulator 223c is low, the insulator 223c in a region overlapping with the oxide semiconductor 230 remains and the insulator 223c in a region not overlapping with the oxide semiconductor 230 is removed through processing the oxide semiconductor film to be the oxide semiconductor 230 to form the oxide semiconductor 230 into an island shape. Thus, the insulator 223c is formed into an island shape. At this time, the insulator 275 is in contact with part of the top surface of the insulator 222 in a region overlapping with neither the insulator 223a nor the insulator 223b (see FIG. 17A to FIG. 17D).

In any of the structure illustrated in FIG. 14A to FIG. 14D, the structure illustrated in FIG. 16A to FIG. 16D, and the structure illustrated in FIG. 17A to FIG. 17D, the region 231a is surrounded by the insulator 223a and the insulator 275, and the region 231b is surrounded by the insulator 223b and the insulator 275.

In the semiconductor device illustrated in FIG. 14A to FIG. 14D, the insulator 223c may be formed using an insulating material containing the same element as the insulator 222. At this time, the boundary between the insulator 222 and the insulator 223c cannot be clearly detected in some cases.

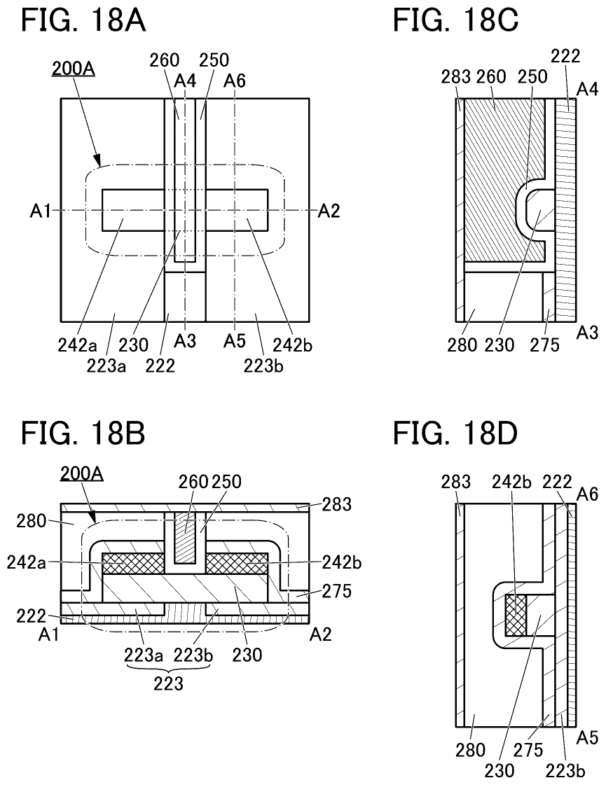

In the case where an insulating material containing the same element as the insulator 222 is used for the insulator 223c, the insulator 222 and the insulator 223c may be formed in different steps. Alternatively, the insulator 222 having a projecting shape may be formed by processing an insulating film to be the insulator 222 (see FIG. 18A to FIG. 18D). The projecting shape is preferably formed such that at least part of the insulator 222 overlaps with the conductor 260. In that case, the projecting region corresponds to the insulator 223c illustrated in FIG. 14A to FIG. 14D.

In the semiconductor device illustrated in FIG. 14A to FIG. 14D, the insulator 223c may be formed using a material containing the same element as the oxide semiconductor 230. At this time, the boundary between the insulator 223c and the oxide semiconductor 230 cannot be clearly detected in some cases.

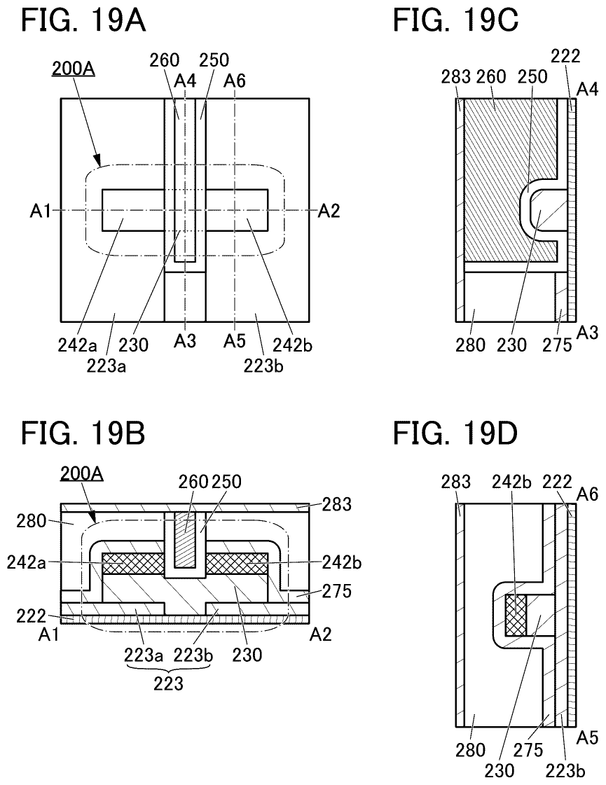

In the case where a material containing the same element as the oxide semiconductor 230 is used for the insulator 223c, the insulator 223c and the oxide semiconductor 230 may be formed in different steps. Alternatively, the oxide semiconductor 230 including a region projecting downward may be formed (see FIG. 19A to FIG. 19D) in such a manner that after the insulator 223a and the insulator 223b are formed, an oxide semiconductor film to be the oxide semiconductor 230 is formed and the oxide semiconductor film is processed. The region projecting downward is preferably formed to at least partly overlap with the conductor 260. In that case, the region projecting downward corresponds to the insulator 223c illustrated in FIG. 14A to FIG. 14D.

Note that in the case where the oxide semiconductor film to be the oxide semiconductor 230 is formed over the insulator 223a and the insulator 223b, the level of the top surface of a region of the oxide semiconductor film that overlaps with neither the insulator 223a nor the insulator 223b may be lower than the level of the top surface of a region of the oxide semiconductor film that overlaps with the insulator 223a or the insulator 223b. Thus, in the oxide semiconductor 230, the level of the top surface of the region overlapping with the conductor 260 is lower than the level of the top surface of the region overlapping with the conductor 242a or the conductor 242b in some cases.

Although the insulator 223a to the insulator 223c are provided to extend in the channel width direction of the transistor 200A in FIG. 14A to FIG. 14D, the present invention is not limited thereto. The insulator 223c may have an island shape.

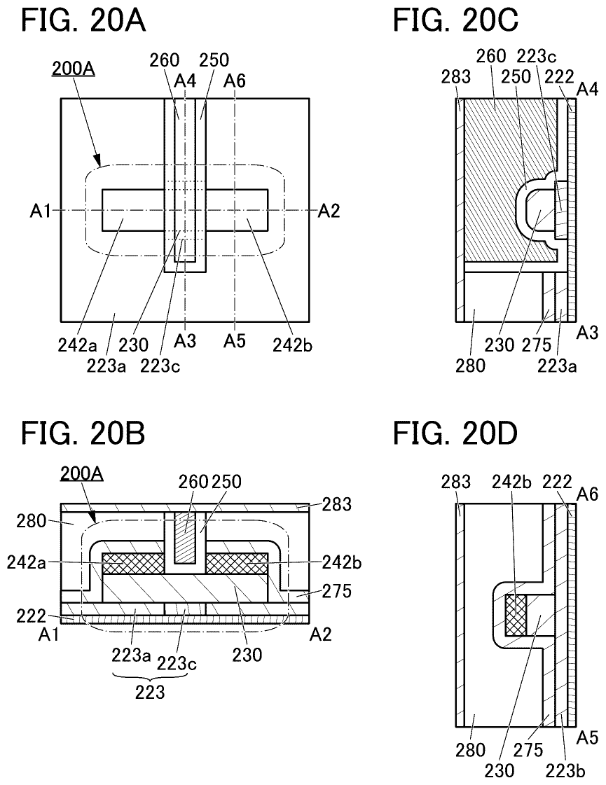

For example, in the semiconductor device illustrated in FIG. 20A to FIG. 20D, the insulator 223 includes the insulator 223c with an island shape and the insulator 223a provided around the insulator 223c in a plan view. At least part of the insulator 223c includes a region overlapping with the conductor 260 with the oxide semiconductor 230 therebetween. Also in such a structure, the region 231a is surrounded by the insulator 223a and the insulator 275, and the region 231b is surrounded by the insulator 223b and the insulator 275.

Although the side end portion of the insulator 223c is positioned outward from the side end portion of the oxide semiconductor 230 in FIG. 20C, the present invention is not limited thereto. For example, in the channel width direction of the transistor 200A, the side end portion of the insulator 223c may be aligned with the side end portion of the oxide semiconductor 230.

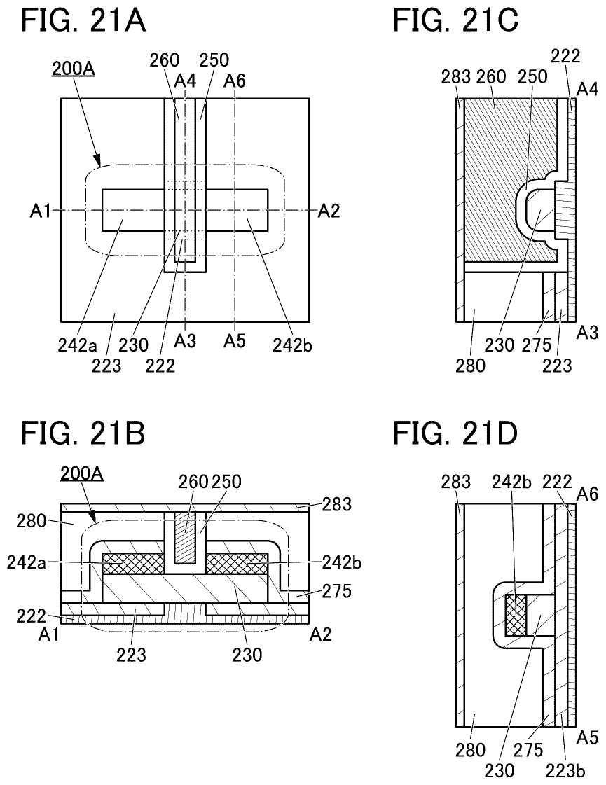

Note that like the structure illustrated in FIG. 18A to FIG. 18D, the semiconductor device illustrated in FIG. 20A to FIG. 20D may be provided with the insulator 222 having a projecting shape (see FIG. 21A to FIG. 21D). In that case, a projecting region corresponds to the insulator 223c.

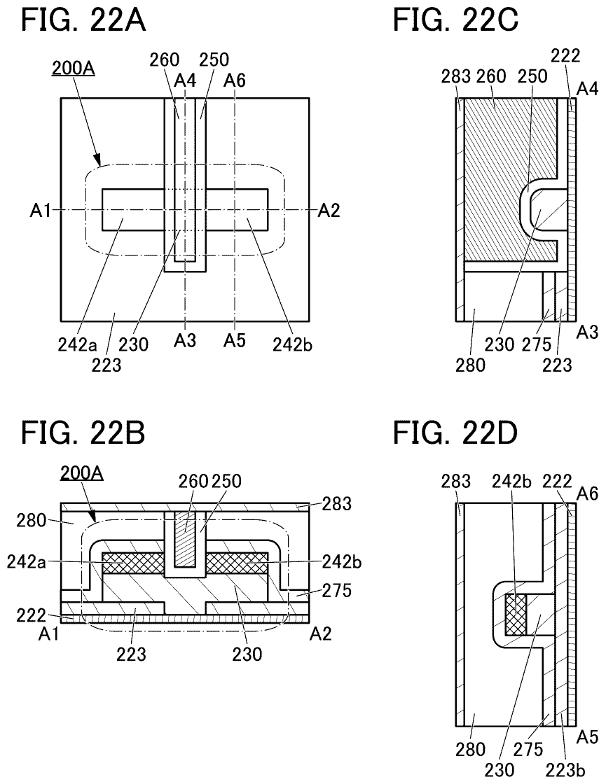

Like the structure illustrated in FIG. 19A to FIG. 19D, the semiconductor device illustrated in FIG. 20A to FIG. 20D may also be provided with the oxide semiconductor 230 including a region projecting downward (see FIG. 22A to FIG. 22D). In that case, the region projecting downward corresponds to the insulator 223c.

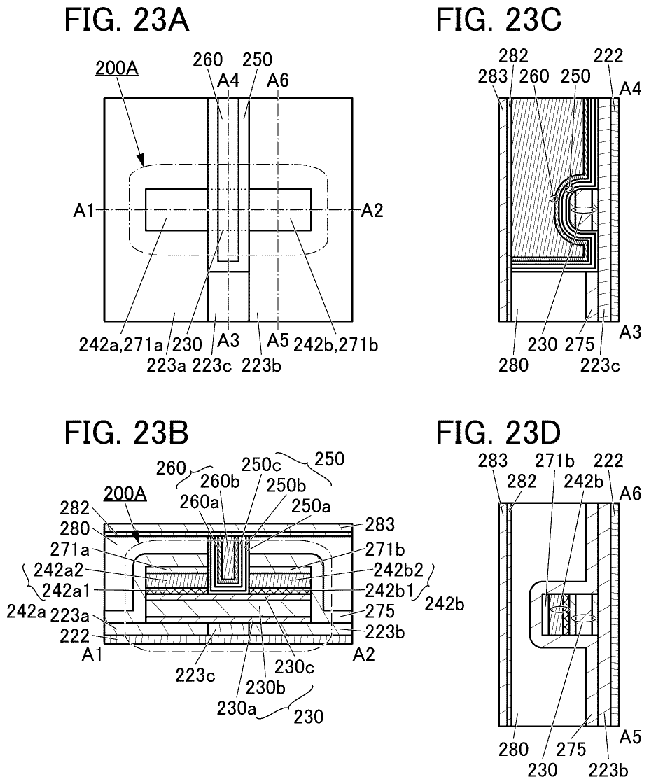

Although the oxide semiconductor 230 being a single layer is illustrated in FIG. 14B to FIG. 14D, the present invention is not limited thereto. The oxide semiconductor 230 may have a stacked-layer structure. For example, as illustrated in FIG. 23A to FIG. 23D, the oxide semiconductor 230 may have a stacked-layer structure of the oxide semiconductor 230a, the oxide semiconductor 230b over the oxide semiconductor 230a, and the oxide semiconductor 230c over the oxide semiconductor 230b.

Although the insulator 250 being a single layer is illustrated in FIG. 14B and FIG. 14C, the present invention is not limited thereto. The insulator 250 may have a stacked-layer structure. For example, as illustrated in FIG. 23A to FIG. 23D, the insulator 250 may have a stacked-layer structure of the insulator 250a, the insulator 250b over the insulator 250a, and the insulator 250c over the insulator 250b.

Although the conductor 260 being a single layer is illustrated in FIG. 14B and FIG. 14C, the present invention is not limited thereto. The conductor 260 may have a stacked-layer structure. For example, as illustrated in FIG. 23A to FIG. 23D, the conductor 260 may have a stacked-layer structure of the conductor 260a and the conductor 260b over the conductor 260a.

Although the conductor 242a and the conductor 242b each being a single layer are illustrated in FIG. 14B and FIG. 14D, the present invention is not limited thereto. Each of the conductor 242a and the conductor 242b may have a stacked-layer structure. For example, as illustrated in FIG. 23A to FIG. 23D, the conductor 242a may have a stacked-layer structure of the conductor 242a1 and the conductor 242a2 over the conductor 242a1, and the conductor 242b may have a stacked-layer structure of the conductor 242b1 and the conductor 242b2 over the conductor 242b1.

Although the insulator 275 is provided in contact with the top surface of the conductor 242a and the top surface of the conductor 242b in FIG. 14B and FIG. 14D, the present invention is not limited thereto. For example, as illustrated in FIG. 23A to FIG. 23D, an insulator 271a may be provided between the conductor 242a and the insulator 275, and an insulator 271b may be provided between the conductor 242b and the insulator 275.

Although the insulator 283 is provided in contact with the top surface of the insulator 280, the top surface of the insulator 250, and the top surface of the conductor 260 in FIG. 14B to FIG. 14D, the present invention is not limited thereto. For example, as illustrated in FIG. 23B to FIG. 23D, an insulator 282 may be provided between the insulator 283 and the insulator 280, the insulator 250, and the conductor 260.

### Structure Example 2-2

Although FIG. 14A to FIG. 14D illustrate the case where the transistor 200A has a single-gate structure, which includes one gate, the present invention is not limited to this structure. For example, the transistor 200A may include a back gate.

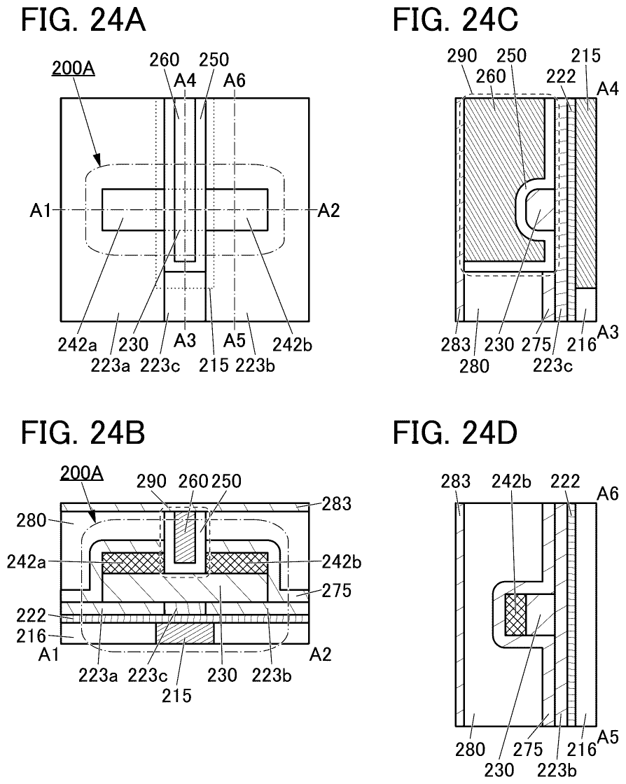

Another structure example of a semiconductor device is described with reference to FIG. 24A to FIG. 24D. FIG. 24A to FIG. 24D are a plan view and cross-sectional views of a semiconductor device. The semiconductor device illustrated in FIG. 24A to FIG. 24D is different from the semiconductor device illustrated in FIG. 14A to FIG. 14D mainly in including a conductor 215 and an insulator 216. Hereinafter, the description of [Structure example 2-1] is referred to for the same portions, and the description of the same portions is omitted.

The structures, materials, and the like of the conductor 215 illustrated in FIG. 24A to FIG. 24D are the same as those of the conductor 215 illustrated in FIG. 5A to FIG. 5D. The structures, materials, and the like of the insulator 216 illustrated in FIG. 24A to FIG. 24D are the same as those of the insulator 216 illustrated in FIG. 5A to FIG. 5D. Therefore, the above description in [Structure example 1-2] can be referred to for the structures, materials, and the like of the conductor 215 and the insulator 216.

### Structure Example 2-3

Although the side end portion of the conductor 242a and the side end portion of the oxide semiconductor 230 are aligned with each other and the side end portion of the conductor 242b and the side end portion of the oxide semiconductor 230 are aligned with each other in FIG. 24A to FIG. 24D, the present invention is not limited to this structure. For example, the conductor 242a and the conductor 242b may each include a region in contact with the side surface of the oxide semiconductor 230.

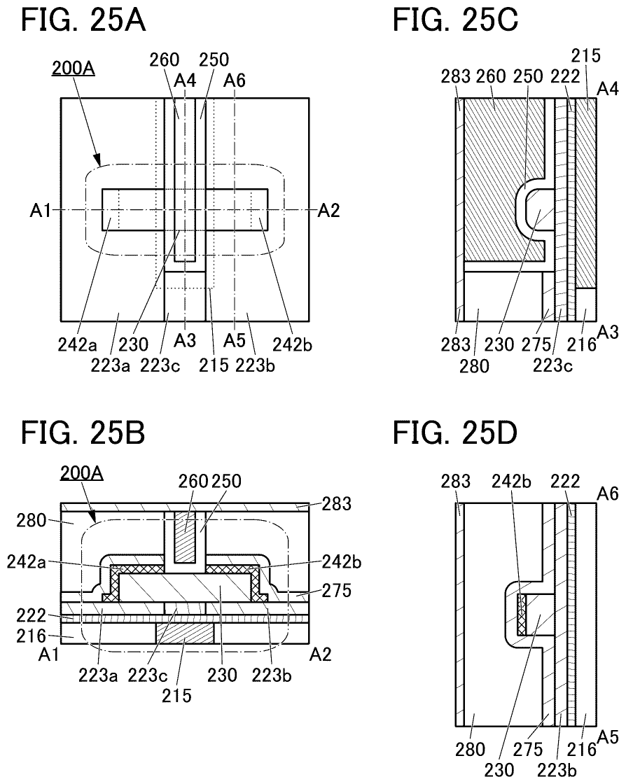

Another structure example of the semiconductor device is described with reference to FIG. 25A to FIG. 25D. FIG. 25A to FIG. 25D are a top view and cross-sectional views of the semiconductor device including the transistor 200A. The transistor 200A illustrated in FIG. 25A to FIG. 25D is different from the transistor 200A illustrated in FIG. 24A to FIG. 24D mainly in the shapes of the conductor 242a and the conductor 242b. Hereinafter, the description of [Structure example 2-1] and [Structure example 2-2] is referred to for the same portions, and the description of the same portions is omitted.

The structures, materials, and the like of the conductor 242a and the conductor 242b illustrated in FIG. 25A to FIG. 25D are the same as those of the conductor 242a and the conductor 242b illustrated in FIG. 6A to FIG. 6D. Therefore, the above description in [Structure example 1-3] can be referred to for the structures, materials, and the like of the conductor 242a and the conductor 242b.

### Structure Example 2-4

Although the insulator 250 is in contact with the side surface of the insulator 280, the side surface of the insulator 275, and the side surface of the insulator 223 in the opening portion 290 in FIG. 24A to FIG. 24D, the present invention is not limited to this structure. For example, in the opening portion 290, an insulator may be provided between the insulator 250 and the insulator 280, the insulator 275, and the insulator 223.

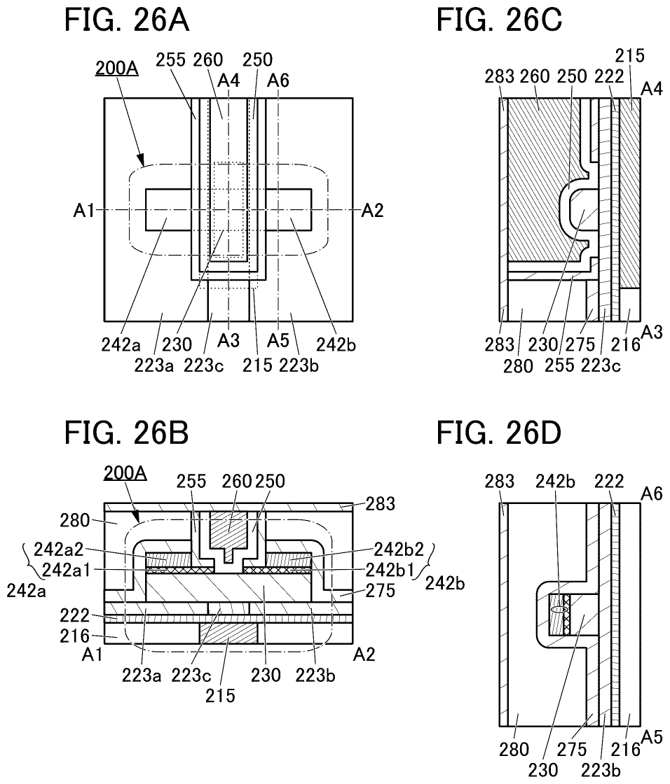

Another structure example of the semiconductor device is described with reference to FIG. 26A to FIG. 26D. FIG. 26A to FIG. 26D are a top view and cross-sectional views of the semiconductor device including the transistor 200A. The transistor 200A illustrated in FIG. 26A to FIG. 26D is different from the transistor 200A illustrated in FIG. 24A to FIG. 24D mainly in including an insulator 255. FIG. 26A to FIG. 26D illustrate a structure in which the conductor 242a and the conductor 242b each have a stacked-layer structure of two layers. Hereinafter, the description of [Structure example 2-1] and [Structure example 2-2] is referred to for the same portions, and the description of the same portions is omitted.

The structures, materials, and the like of the insulator 255 illustrated in FIG. 26A to FIG. 26D are the same as those of the insulator 255 illustrated in FIG. 7A to FIG. 7D. Therefore, the above description in [Structure example 1-4] can be referred to for the structures, materials, and the like of the insulator 255.

### Structure Example 2-5

Although the insulator 255 in FIG. 26A to FIG. 26D includes a region positioned between the insulator 250 and the oxide semiconductor 230, the present invention is not limited to this structure. For example, the insulator 255 does not necessarily include a region positioned between the insulator 250 and the oxide semiconductor 230.

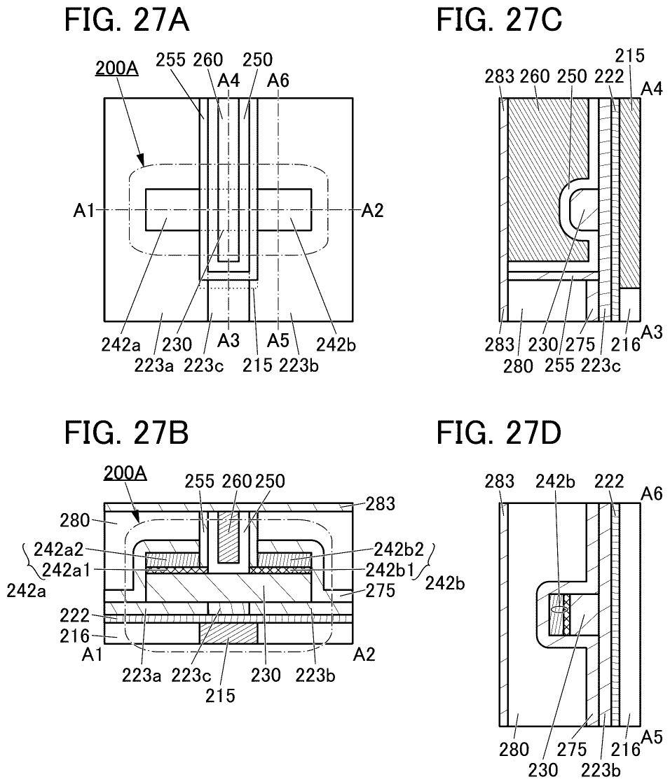

Another structure example of the semiconductor device is described with reference to FIG. 27A to FIG. 27D. FIG. 27A to FIG. 27D are a top view and cross-sectional views of the semiconductor device including the transistor 200A. The transistor 200A illustrated in FIG. 27A to FIG. 27D is different from the transistor 200A illustrated in FIG. 26A to FIG. 26D mainly in the shapes of the insulator 255, the insulator 250, and the conductor 260. Hereinafter, the description of [Structure example 2-4] and the like is referred to for the same portions, and the description of the same portions is omitted.

The structures, materials, and the like of the insulator 255 illustrated in FIG. 27A to FIG. 27D are the same as those of the insulator 255 illustrated in FIG. 8A to FIG. 8D. The structures, materials, and the like of the insulator 255 illustrated in FIG. 27A to FIG. 27D are the same as those of the insulator 255 illustrated in FIG. 8A to FIG. 8D. The structures, materials, and the like of the insulator 250 illustrated in FIG. 27A to FIG. 27D are the same as those of the insulator 250 illustrated in FIG. 8A to FIG. 8D. The structures, materials, and the like of the conductor 260 illustrated in FIG. 27A to FIG. 27D are the same as those of the conductor 260 illustrated in FIG. 8A to FIG. 8D. Therefore, the above description in [Structure example 1-5] can be referred to for the structures, materials, and the like of the insulator 255, the insulator 250, and the conductor 260.

### Structure Example 2-6

Although the oxide semiconductor 230 is provided over the insulator 223 in FIG. 14A to FIG. 14D, the present invention is not limited to this structure. For example, an insulator may be provided between the insulator 223 and the oxide semiconductor 230.

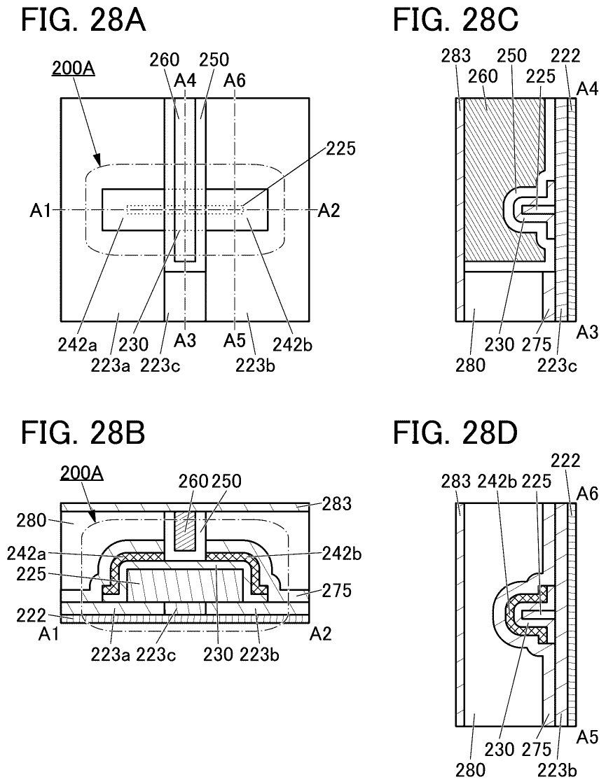

Another structure example of the semiconductor device is described with reference to FIG. 28A to FIG. 28D. FIG. 28A to FIG. 28D are a top view and cross-sectional views of the semiconductor device including the transistor 200A. The transistor 200A illustrated in FIG. 28A to FIG. 28D is different from the transistor 200A illustrated in FIG. 14A to FIG. 14D mainly in including an insulator 225. Hereinafter, the description of [Structure example 2-1] is referred to for the same portions, and the description of the same portions is omitted.

The structures, materials, and the like of the insulator 225 illustrated in FIG. 28A to FIG. 28D are the same as those of the insulator 225 illustrated in FIG. 9A to FIG. 9D. Therefore, the above description in [Structure example 1-6] can be referred to for the structures, materials, and the like of the insulator 225.

The transistor 200A illustrated in FIG. 28A to FIG. 28D includes the insulator 225 over the insulator 223a, the insulator 223b, and the insulator 223c. The transistor 200A further includes the oxide semiconductor 230 that is over the insulator 223a, the insulator 223b, and the insulator 223c and covers the top surface and the side surface of the insulator 225.

In the structure illustrated in FIG. 28A to FIG. 28D, one of the source region and the drain region is surrounded by the insulator 223a and the insulator 275 together with the insulator 225, and the other of the source region and the drain region is surrounded by the insulator 223b and the insulator 275 together with the insulator 225. One of the source region and the drain region is in contact with the insulator 223a, the insulator 225, and the insulator 275, and the other of the source region and the drain region is in contact with the insulator 223b, the insulator 225, and the insulator 275.

As illustrated in FIG. 28C, the insulator 250 is in contact with part of the top surface of the insulator 223c. In that case, the channel formation region is surrounded by the insulator 223c and the insulator 250 together with the insulator 225. The channel formation region is in contact with the insulator 223c, the insulator 225, and the insulator 250.

### Modification Example 2

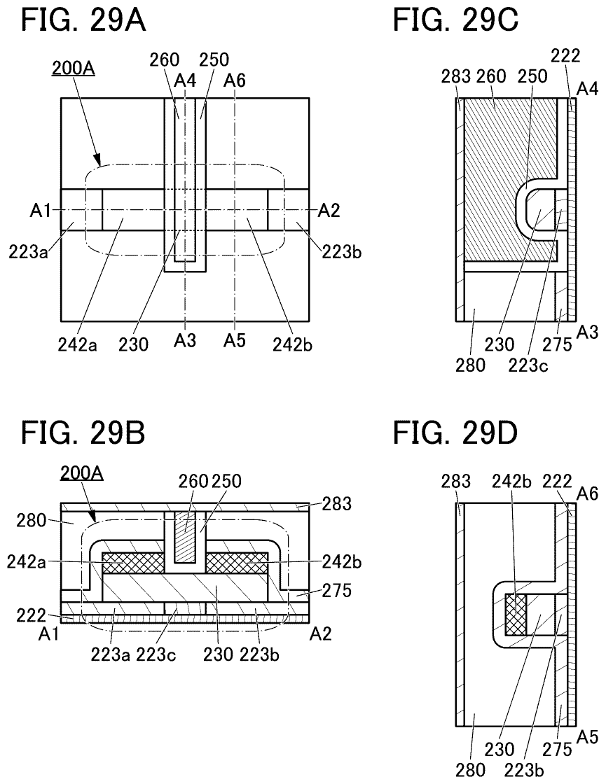

An example of the semiconductor device of one embodiment of the present invention is described below with reference to FIG. 29A to FIG. 32D.

The semiconductor devices illustrated in respective diagrams with reference to A to D among FIG. 29A to FIG. 32D are each different from the semiconductor device illustrated in FIG. 14A to FIG. 14D in the shape of the insulator 223.

Portions different from the above description of <Structure example 2> are mainly described below; description of the same portion is omitted in some cases and the description of <Structure example 2> is referred to.

In the semiconductor device illustrated in the respective diagrams with reference to A to D, components having the same functions as the components included in the semiconductor device described in <Structure example 2> are denoted by the same reference numerals. Note that the materials described in detail in <Structure example 2> can be used as materials for the semiconductor device also in this section.

### Modification Example 2-1

FIG. 29A to FIG. 29D illustrate a modification example of the semiconductor device illustrated in FIG. 14A to FIG. 14E. FIG. 29A to FIG. 29D are a plan view and cross-sectional views of the semiconductor device.

In the semiconductor device illustrated in FIG. 29A to FIG. 29D, the insulator 223a and the insulator 223b are each processed into a band-like shape and the insulator 223c is processed into an island shape. For example, as illustrated in FIG. 29A and FIG. 29B, the insulator 223a and the insulator 223b are each provided to extend in the channel length direction (A1-A2 direction).

As illustrated in FIG. 29A and FIG. 29D, side end portions of the insulator 223a, the insulator 223b, and the insulator 223c on the A5 side are aligned with the side end portion of the oxide semiconductor 230 on the A5 side. Side end portions of the insulator 223a, the insulator 223b, and the insulator 223c on the A6 side are aligned with the side end portion of the oxide semiconductor 230 on the A6 side.

In the above structure, as illustrated in FIG. 29B and FIG. 29D, the insulator 275 is provided in contact with the top surface of the insulator 222, the top surface and the side surface of the insulator 223a, the top surface and the side surface of the insulator 223b, the side surface of the oxide semiconductor 230, the side surface and the top surface of the conductor 242a, and the side surface and the top surface of the conductor 242b. Also in such a structure, the region 231a is surrounded by the insulator 223a and the insulator 275, and the region 231b is surrounded by the insulator 223b and the insulator 275.

Although FIG. 29A and FIG. 29D illustrate a structure in which the side end portion of each of the insulator 223a, the insulator 223b, and the insulator 223c is aligned with the side end portion of the oxide semiconductor 230 in a cross-sectional view in the channel width direction, the present invention is not limited thereto. For example, in a cross-sectional view in the channel width direction, the side end portion of each of the insulator 223a, the insulator 223b, and the insulator 223c may be positioned outward from the side end portion of the oxide semiconductor 230.

### Modification Example 2-2

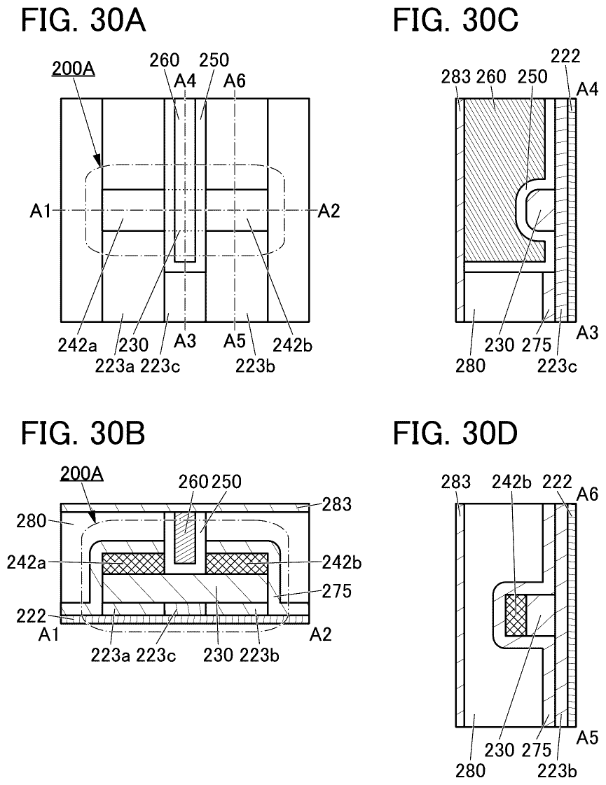

FIG. 30A to FIG. 30D illustrate a modification example of the semiconductor device illustrated in FIG. 14A to FIG. 14E. FIG. 30A to FIG. 30D are a plan view and cross-sectional views of the semiconductor device.

In the semiconductor device illustrated in FIG. 30A to FIG. 30D, the insulator 223a, the insulator 223b, and the insulator 223c are each processed into a band-like shape. For example, as illustrated in FIG. 30A and FIG. 30D, the insulator 223a, the insulator 223b, and the insulator 223c are each provided to extend in the channel width direction (A3-A4 direction). The insulator 223a, the insulator 223b, and the insulator 223c are each provided to extend in the direction in which the conductor 260 extends.

As illustrated in FIG. 30A and FIG. 30B, the side end portion of the insulator 223a on the A1 side is aligned with the side end portion of the oxide semiconductor 230 on the A1 side. A side end portion of the insulator 223b on the A2 side is aligned with a side end portion of the oxide semiconductor 230 on the A2 side.

In the above structure, as illustrated in FIG. 11B and FIG. 11D, the insulator 275 is provided in contact with the top surface of the insulator 222, the top surface and the side surface of the insulator 223a, the top surface and the side surface of the insulator 223b, the top surface of the insulator 223c, the side surface of the oxide semiconductor 230, the side surface and the top surface of the conductor 242a, and the side surface and the top surface of the conductor 242b. Also in such a structure, the region 231a is surrounded by the insulator 223a and the insulator 275, and the region 231b is surrounded by the insulator 223b and the insulator 275.

Although FIG. 30A and FIG. 30B illustrate a structure in which the side end portion of each of the insulator 223a and the insulator 223b is aligned with the side end portion of the oxide semiconductor 230 in a cross-sectional view in the channel length direction, the present invention is not limited thereto. For example, in a cross-sectional view in the channel length direction, the side end portion of each of the insulator 223a and the insulator 223b may be positioned outward from the side end portion of the oxide semiconductor 230.

### Modification Example 2-3

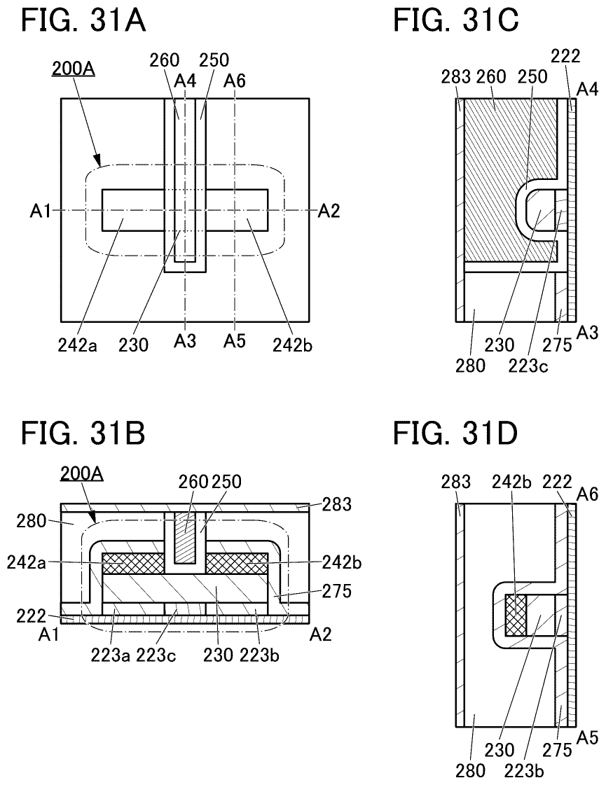

FIG. 31A to FIG. 31D illustrate a modification example of the semiconductor device illustrated in FIG. 14A to FIG. 14E. FIG. 31A to FIG. 31D are a plan view and cross-sectional views of the semiconductor device.

In the semiconductor device illustrated in FIG. 31A to FIG. 31D, the insulator 223a, the insulator 223b, and the insulator 223c are each processed into an island shape. As illustrated in FIG. 31A to FIG. 31D, side end portions of the insulator 223a, the insulator 223b, and the insulator 223c are aligned with the side end portion of the oxide semiconductor 230.

In the above structure, as illustrated in FIG. 31B to FIG. 31D, the insulator 275 is provided in contact with the top surface of the insulator 222, the side surface of the insulator 223a, the side surface of the insulator 223b, the side surface of the oxide semiconductor 230, the side surface and the top surface of the conductor 242a, and the side surface and the top surface of the conductor 242b. Also in such a structure, the region 231a is surrounded by the insulator 223a and the insulator 275, and the region 231b is surrounded by the insulator 223b and the insulator 275.

Although FIG. 31A and FIG. 31B illustrate a structure in which the side end portion of each of the insulator 223a and the insulator 223b is aligned with the side end portion of the oxide semiconductor 230, the present invention is not limited thereto. For example, in a cross-sectional view in the channel length direction, the side end portion of each of the insulator 223a and the insulator 223b may be positioned outward from the side end portion of the oxide semiconductor 230. In a cross-sectional view in the channel width direction, the side end portion of each of the insulator 223a and the insulator 223b may be positioned outward from the side end portion of the oxide semiconductor 230.

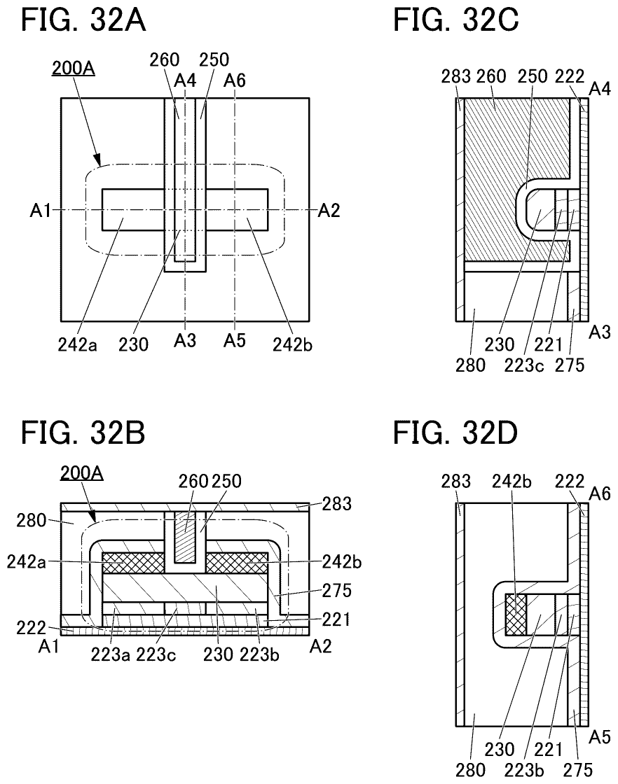

Note that as described in [Modification example 1-3], for example, an insulator may be provided between the insulator 222 and the insulator 223. For example, as illustrated in FIG. 32A to FIG. 32D, the island-shaped insulator 221 may be provided between the insulator 222 and the insulator 223.

The structures, materials, and the like of the insulator 221 illustrated in FIG. 32A to FIG. 32D are the same as those of the insulator 221 illustrated in FIG. 13A to FIG. 13D. Therefore, the above description in [Modification example 1-3] can be referred to for the structures, materials, and the like of the insulator 221.

The structure body over the insulator 222 and the insulator 223 in the semiconductor device illustrated in the respective diagrams with reference to A to D among FIG. 29A to FIG. 32D has the same structure as the structure body over the insulator 222 and the insulator 223 in the semiconductor device illustrated in FIG. 14A to FIG. 14D; however, the present invention is not limited thereto. The structure body over the insulator 222 and the insulator 223 in the semiconductor device illustrated in the respective diagrams with reference to A to D may have the same structure as the structure body over the insulator 222 and the insulator 223 in the semiconductor device illustrated in any of FIG. 23A to FIG. 28D.

Like the semiconductor device illustrated in FIG. 24A to FIG. 24D, the semiconductor device illustrated in the respective diagrams with reference to A to D may include the conductor 215 and the insulator 216 below the insulator 222.

With one embodiment of the present invention, a semiconductor device including a transistor with a small variation in electrical characteristics can be provided. Alternatively, a semiconductor device including a transistor with a high on-state current can be provided. Alternatively, a semiconductor device having excellent electrical characteristics can be provided. Alternatively, a highly reliable semiconductor device can be provided. Alternatively, a novel semiconductor device can be provided.

This embodiment can be combined with the other embodiments as appropriate. In this specification, in the case where a plurality of structure examples are shown in one embodiment, the structure examples can be combined as appropriate.

### Embodiment 2

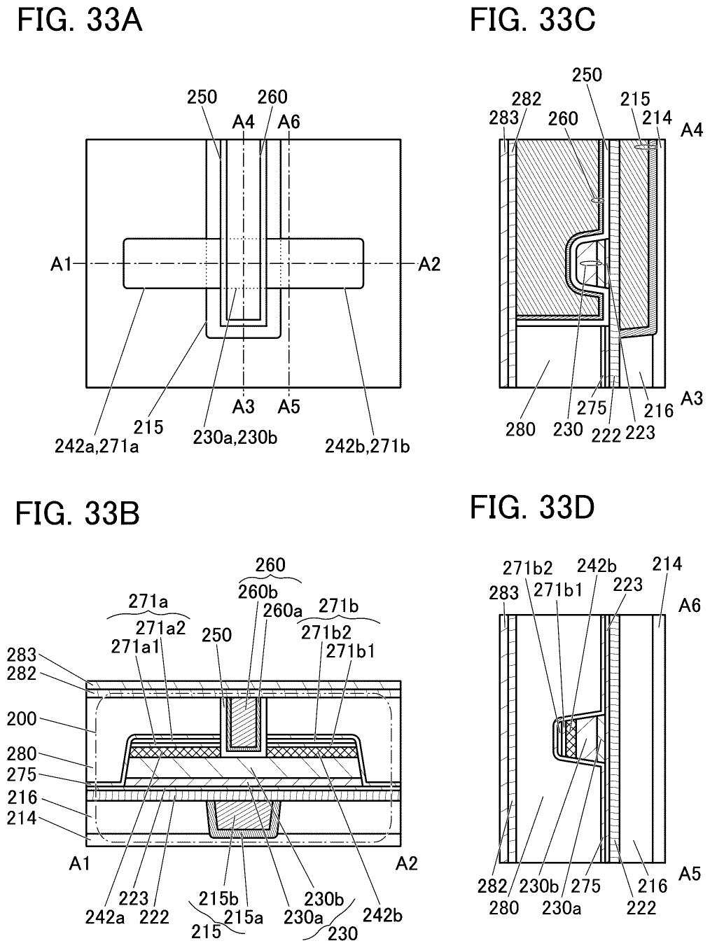

In this embodiment, structure examples of a semiconductor device of one embodiment of the present invention will be described with reference to FIG. 33A to FIG. 50D. The semiconductor device of one embodiment of the present invention includes a transistor.

In the semiconductor devices illustrated in FIG. 33A to FIG. 50D, components having the same functions as the components included in the semiconductor device described in Embodiment 1 are denoted by the same reference numerals. Note that the materials described in detail in Embodiment 1 can be used as materials for the semiconductor device also in this embodiment.

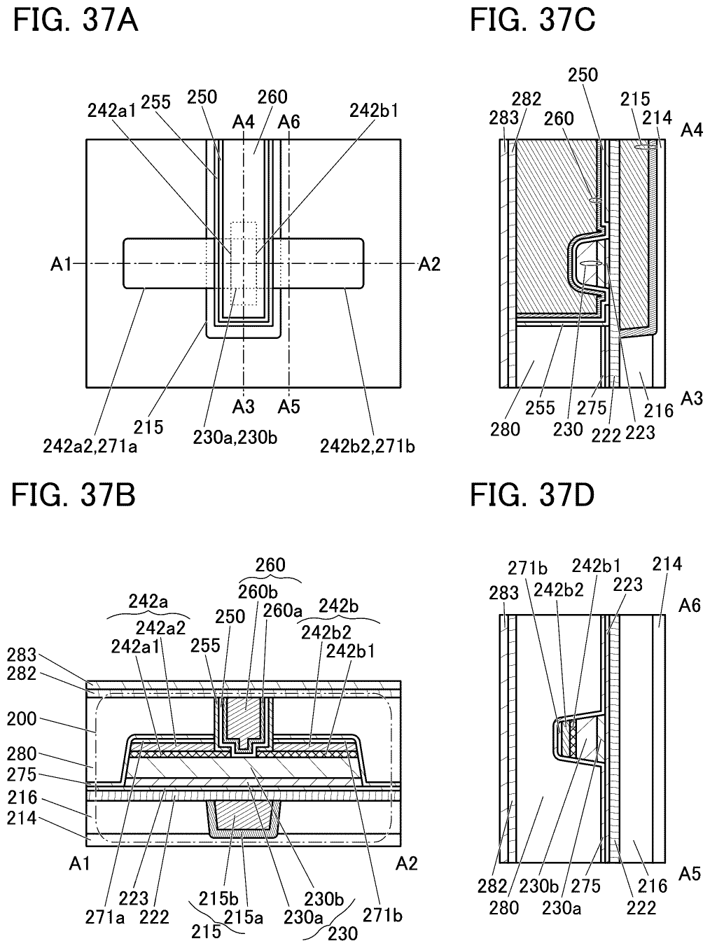

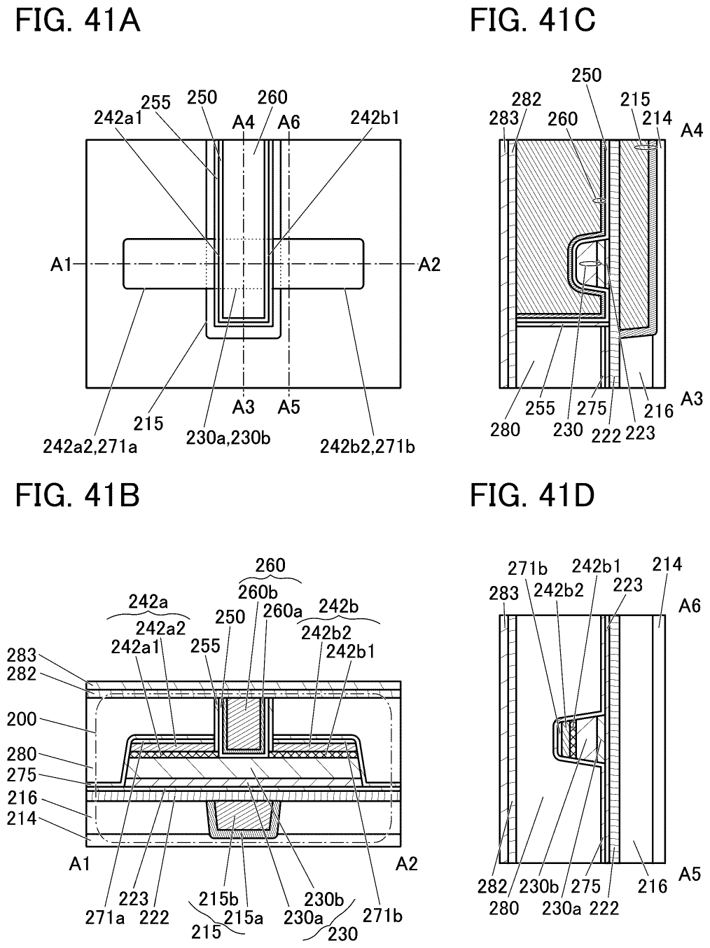

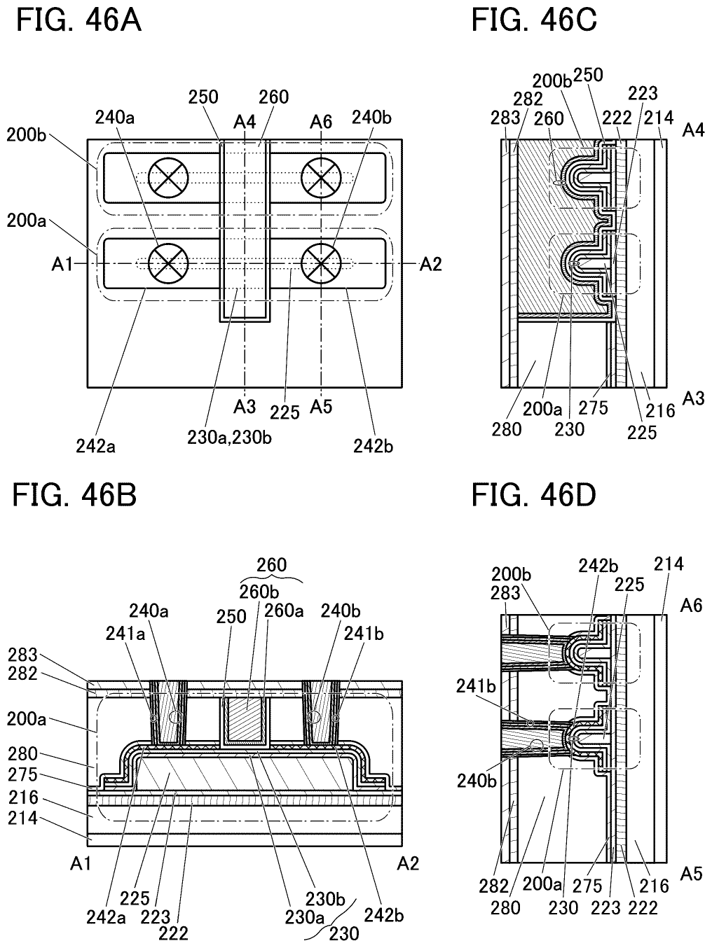

In FIG. 33A to FIG. 33D, FIG. 37A to FIG. 37D, FIG. 41A to FIG. 41D, and FIG. 46A to FIG. 46D, A of each drawing is a plan view of a semiconductor device. Moreover, B of each drawing is a cross-sectional view corresponding to a portion indicated by the dashed-dotted line A1-A2 in A of each drawing, and is also a cross-sectional view in the channel length direction of a transistor. Furthermore, C of each drawing is a cross-sectional view corresponding to a portion indicated by the dashed-dotted line A3-A4 in A of each drawing, and is also a cross-sectional view in the channel width direction of the transistor. Furthermore, D of each drawing is a cross-sectional view corresponding to a portion indicated by the dashed-dotted line A5-A6 in A of each drawing. The dashed-dotted line A1-A2 is orthogonal to the dashed-dotted line A3-A4 and the dashed-dotted line A5-A6, and the dashed-dotted line A3-A4 is parallel to the dashed-dotted line A5-A6. For clarity of the drawings, some components are omitted in the plan view of A of each drawing.

### Structure Example 1 of Semiconductor Device

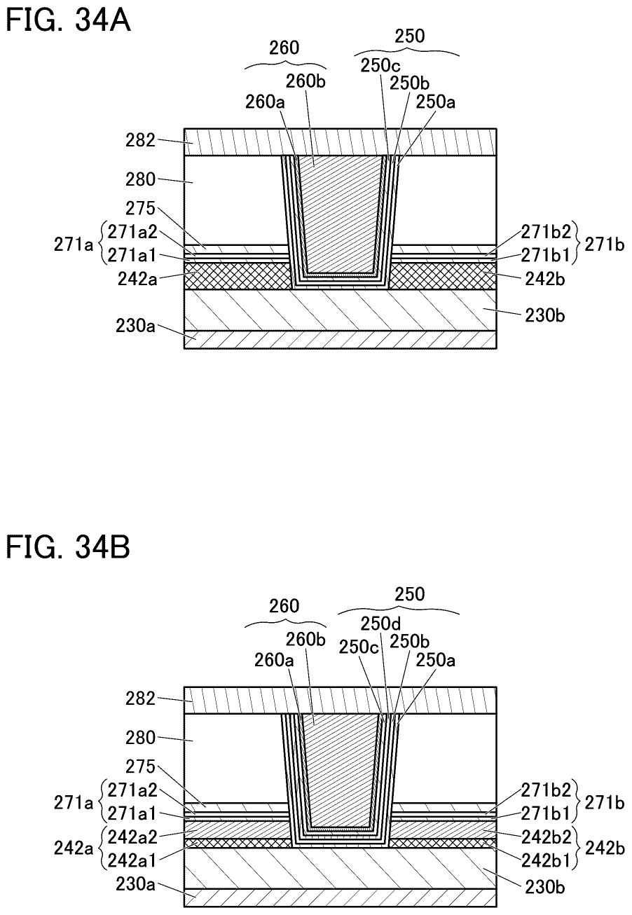

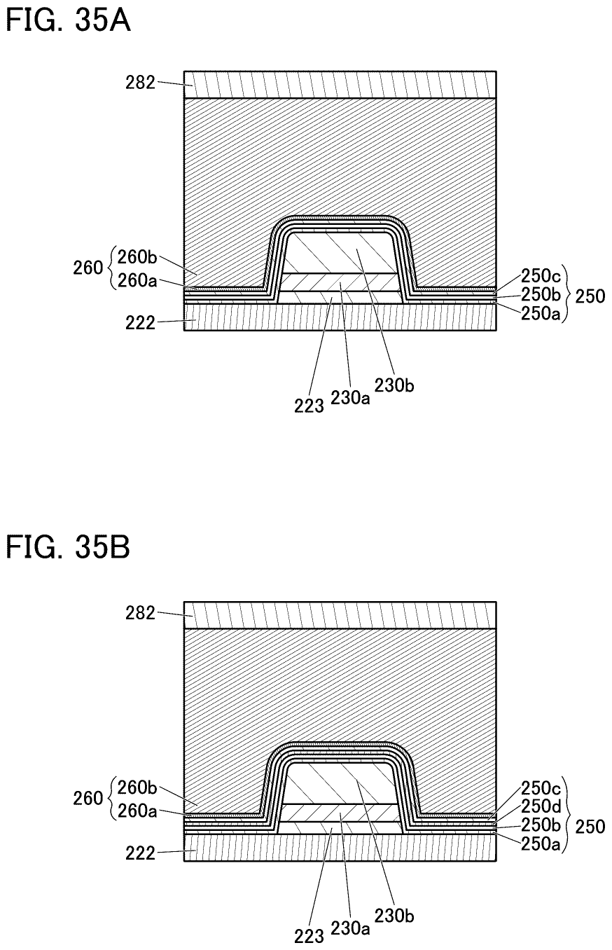

An example of the structure of a semiconductor device is described with reference to FIG. 33A to FIG. 35B. FIG. 33A to FIG. 33D are a plan view and cross-sectional views of a semiconductor device including the transistor 200. FIG. 34A and FIG. 34B are enlarged cross-sectional views of the transistor 200 in the channel length direction, and FIG. 35A and FIG. 35B are enlarged cross-sectional views of the transistor 200 in the channel width direction.

The structure of the semiconductor device illustrated in FIG. 33A to FIG. 33D is also a detailed structure of the semiconductor device described in [Structure example 1-2] in Embodiment 1. Portions different from the above description of [Structure example 1-2] in Embodiment 1 are mainly described below; description of the same portion is omitted in some cases and the description of [Structure example 1-2] is referred to. For example, the description in Embodiment 1 can be referred to for materials, structures, and the like used for components (e.g., an insulator, an oxide semiconductor, and a conductor) of the semiconductor device.

The transistor 200 includes the insulator 216 over the insulator 214, the conductor 215 provided to be embedded in the insulator 216, the insulator 222 over the insulator 216 and the conductor 215, the insulator 223 over the insulator 222, the oxide semiconductor 230 over the insulator 223, the conductor 242a and the conductor 242b over the oxide semiconductor 230, the insulator 271a over the conductor 242a, the insulator 271b over the conductor 242b, the insulator 250 over the oxide semiconductor 230, and the conductor 260 over the insulator 250.

The insulator 275 is provided over the insulator 271a and the insulator 271b, and the insulator 280 is provided over the insulator 275. The insulator 250 and the conductor 260 fill the opening portion provided in the insulator 280 and the insulator 275. The insulator 282 is provided over the insulator 280, the insulator 250, and the conductor 260. The insulator 283 is provided over the insulator 282.

The oxide semiconductor 230 includes a region functioning as a channel formation region of the transistor 200. The conductor 260 includes a region functioning as a first gate electrode (an upper gate electrode) of the transistor 200. The insulator 250 includes a region functioning as a first gate insulator of the transistor 200. The conductor 215 includes a region functioning as a second gate electrode (a lower gate electrode) of the transistor 200. The insulator 223 and the insulator 222 each include a region functioning as a second gate insulator of the transistor 200. The conductor 242a includes a region functioning as one of a source electrode and a drain electrode of the transistor 200. The conductor 242b includes a region functioning as the other of the source electrode and the drain electrode of the transistor 200.

As illustrated in FIG. 33B, it is preferable that one side end portion of the conductor 242a be aligned with one side end portion of the oxide semiconductor 230 and one side end portion of the conductor 242b be aligned with the other side end portion of the oxide semiconductor 230 in the cross-sectional view of the transistor 200. In order to obtain such a structure, the oxide semiconductor 230 and a conductive layer to be the conductor 242a and the conductor 242b are preferably processed into an island shape at a time. Accordingly, the semiconductor device of one embodiment of the present invention can be manufactured with favorable productivity. In the case of performing processing in the above manner, the side end portions of the oxide semiconductor 230, the conductor 242a, and the conductor 242b are substantially aligned with each other as described above.

The insulator 271a and the insulator 271b function as etching stoppers for protecting the conductor 242a and the conductor 242b, respectively, in the processing into an island shape. Accordingly, as illustrated in FIG. 33A and FIG. 33B, it is preferable that the side end portion of the insulator 271a be aligned with the side end portion of the conductor 242a and the side end portion of the insulator 271b be aligned with the side end portion of the conductor 242b in the cross-sectional view of the transistor 200.

The oxide semiconductor 230 preferably includes the oxide semiconductor 230a over the insulator 223 and the oxide semiconductor 230b over the oxide semiconductor 230a. When the oxide semiconductor 230a is provided below the oxide semiconductor 230b, impurities can be inhibited from being diffused into the oxide semiconductor 230b from the structures formed below the oxide semiconductor 230a.

Although an example in which the oxide semiconductor 230 has a two-layer structure of the oxide semiconductor 230a and the oxide semiconductor 230b is described in this embodiment, one embodiment of the present invention is not limited thereto. The oxide semiconductor 230 may have a single-layer structure of the oxide semiconductor 230b or a stacked-layer structure of three or more layers, for example.

The oxide semiconductor 230b includes the channel formation region of the transistor 200 and a source region and a drain region provided to sandwich the channel formation region. At least part of the channel formation region overlaps with the conductor 260. The source region overlaps with the conductor 242a, and the drain region overlaps with the conductor 242b. Note that the source region and the drain region can be interchanged with each other.

Note that the channel formation region, the source region, and the drain region may each be formed not only in the oxide semiconductor 230b but also in the oxide semiconductor 230a.

In the oxide semiconductor 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of impurity elements such as hydrogen and nitrogen.

The insulator 250 preferably has a function of capturing and fixing hydrogen. Thus, the hydrogen concentration in the channel formation region of the oxide semiconductor 230b can be reduced. Accordingly, VoH in the channel formation region can be reduced, so that the channel formation region can be an i-type or substantially i-type region.

Here, as illustrated in FIG. 34A and FIG. 35A, the insulator 250 preferably has a stacked-layer structure of an insulator 250a in contact with the oxide semiconductor 230, an insulator 250b over the insulator 250a, and an insulator 250c over the insulator 250b. In this case, the insulator 250a preferably has a function of capturing and fixing hydrogen.

A high dielectric constant (high-k) material is preferably used for the insulator 250a. With the use of the high-k material for the insulator 250a, a gate potential applied during the operation of the transistor can be reduced while the physical thickness of the gate insulator is maintained. In addition, the equivalent oxide thickness (EOT) of the insulator functioning as the gate insulator can be reduced.

An insulator having a thermally stable structure, such as silicon oxide or silicon oxynitride, is preferably used for the insulator 250b.

As illustrated in FIG. 34B and FIG. 35B, an insulator 250d may be provided between the insulator 250b and the insulator 250c. In that case, as the insulator 250d, an insulator that can be used as the insulator 250a can be provided. For example, an insulator having a function of capturing and fixing hydrogen can be used as the insulator 250d. Accordingly, hydrogen contained in the insulator 250b or the like can be captured and fixed more effectively. For example, a high dielectric constant (high-k) material can be used for the insulator 250d. Accordingly, a gate potential applied during the operation of the transistor can be reduced while the physical thickness of the gate insulator is maintained. In addition, the equivalent oxide thickness (EOT) of the insulator functioning as the gate insulator can be reduced.

The insulator 250d corresponds to the insulator provided between the insulator 250b and the insulator 250c, which is described in Embodiment 1. Thus, for the materials, structures, and the like used for the insulator 250d, the description of the insulator provided between the insulator 250b and the insulator 250c described in Embodiment 1 can be referred to.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 250a, the insulator 250d, the insulator 250c, and the insulator 275, for example. Examples of insulators provided in the vicinity of the conductor 242a, the conductor 242b, and the conductor 260 in the semiconductor device described in this embodiment include the insulator 250a, the insulator 250c, the insulator 250d, and the insulator 275.

The insulator 250a preferably has a barrier property against oxygen. It is preferable that oxygen be less likely to pass through the insulator 250a than at least the insulator 280. With such a structure, oxidation of the side surfaces of the conductor 242a and the conductor 242b and formation of oxide films along the side surfaces can be inhibited. Accordingly, a decrease in the on-state current or field-effect mobility of the transistor 200 can be inhibited.

With the above structure, release of oxygen from the channel formation region of the oxide semiconductor 230b at the time of heat treatment or the like can be inhibited. This can inhibit formation of oxygen vacancies in the oxide semiconductor 230b.

With the above structure, even when an excess amount of oxygen is contained in the insulator 280, the oxygen can be inhibited from being excessively supplied to the oxide semiconductor 230b, so that an appropriate amount of oxygen can be supplied to the oxide semiconductor 230b. Thus, it is possible to inhibit excessive oxidation of the source region and the drain region and a decrease in the on-state current or field-effect mobility of the transistor 200.

The insulator 250c preferably has a barrier property against oxygen. This can inhibit diffusion of oxygen contained in the channel formation region of the oxide semiconductor 230 into the conductor 260 and formation of oxygen vacancies in the channel formation region. Moreover, oxygen contained in the oxide semiconductor 230 and oxygen contained in the insulator 280 can be inhibited from diffusing into the conductor 260 and oxidizing the conductor 260.

The insulator 250c preferably has a barrier property against hydrogen. Accordingly, diffusion of impurities contained in the conductor 260, such as hydrogen, into the oxide semiconductor 230b can be prevented.

The insulator 275 preferably has a barrier property against oxygen. With this structure, oxygen contained in the insulator 280 can be prevented from diffusing into the conductor 242a and the conductor 242b. Thus, the conductor 242a and the conductor 242b can be inhibited from being oxidized by oxygen contained in the insulator 280, so that an increase in resistivity and a reduction in on-state current can be inhibited.

In order to inhibit a reduction in hydrogen concentration in the source region and the drain region in the oxide semiconductor 230, a barrier insulator against hydrogen is preferably provided in the vicinity of each of the source region and the drain region. An example of the insulator provided in the vicinity of each of the source region and the drain region in the semiconductor device described in this embodiment includes the insulator 275.

The insulator 275 preferably has a barrier property against hydrogen. Accordingly, diffusion of hydrogen contained in the source region and the drain region of the oxide semiconductor 230 to the outside can be inhibited, and a reduction in hydrogen concentration in the source region and the drain region can be inhibited. Thus, the source region and the drain region can be n-type regions.

With the above structure, the channel formation region can be an i-type or substantially i-type region, and the source region and the drain region can be n-type regions. Thus, a semiconductor device with favorable electrical characteristics can be provided. The semiconductor device with the above structure can have favorable electrical characteristics even when miniaturized or highly integrated. Miniaturization of the transistor 200 can improve the high-frequency characteristics. Specifically, the cutoff frequency can be improved.

The insulator 250a to the insulator 250d function as part of the first gate insulator. The insulator 250a to the insulator 250d are provided in the opening portion formed in the insulator 280 and the like, together with the conductor 260. The thicknesses of the insulator 250a to the insulator 250d are preferably small for miniaturization of the transistor 200. The thickness of each of the insulator 250a to the insulator 250d is preferably larger than or equal to 0.1 nm and smaller than or equal to 10 nm, further preferably larger than or equal to 0.1 nm and smaller than or equal to 5.0 nm, still further preferably larger than or equal to 0.5 nm and smaller than or equal to 5.0 nm, yet further preferably larger than or equal to 1.0 nm and smaller than 5.0 nm, yet still further preferably larger than or equal to 1.0 nm and smaller than or equal to 3.0 nm. Note that at least part of each of the insulator 250a to the insulator 250c includes a region having the above-described thickness.

To form the insulator 250a to the insulator 250d each having a small thickness as described above, an ALD method is preferably used for film formation.

Although the case where the insulator 250 has a three-layer structure of the insulator 250a to the insulator 250c or a four-layer structure of the insulator 250a to the insulator 250d is described above, the present invention is not limited thereto. The insulator 250 can have a structure including at least one of the insulator 250a to the insulator 250d. When the insulator 250 is formed of one, two, or three layer(s) of the insulator 250a to the insulator 250d, the manufacturing process of the semiconductor device can be simplified and the productivity can be increased.

In addition to the above structure, the semiconductor device of this embodiment preferably has a structure that inhibits entry of hydrogen into the transistor 200 and the like. For example, an insulator having a function of inhibiting diffusion of hydrogen is preferably provided to cover one or both of the upper portion and the lower portion of the transistor 200 and the like. In the semiconductor device described in this embodiment, the insulator corresponds to the insulator 214, the insulator 282, and the insulator 283, for example. The insulator 214 provided below the transistor 200 may have a structure similar to the structure of one or both of the insulator 282 and the insulator 283. In such a case, the insulator 214 may have a stacked-layer structure of the insulator 282 and the insulator 283; the insulator 282 may be the lower layer and the insulator 283 may be the upper layer, or the insulator 282 may be the upper layer and the insulator 283 may be the lower layer.

One or more of the insulator 214, the insulator 282, and the insulator 283 preferably function as a barrier insulator that inhibits diffusion of impurities such as water or hydrogen into the transistor 200 and the like from the substrate side or from above the transistor 200 and the like. Thus, one or more of the insulator 214, the insulator 282, and the insulator 283 preferably contain an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), or a copper atom (i.e., the insulating material through which the impurities are less likely to pass). Alternatively, it is preferable to contain an insulating material having a function of inhibiting diffusion of oxygen (e.g., at least one of an oxygen atom, an oxygen molecule, and the like) (i.e., the insulating material through which the oxygen is less likely to pass).

The insulator 214, the insulator 282, and the insulator 283 are each preferably formed using an insulator having a function of inhibiting diffusion of oxygen and impurities such as water and hydrogen. For example, the insulator 283 preferably has a high barrier property against hydrogen. For example, the insulator 282 preferably has a function of capturing and fixing hydrogen well. Thus, impurities such as water and hydrogen can be inhibited from diffusing into the transistor 200 and the like from an interlayer insulating film and the like that are provided above the insulator 283. Hydrogen contained in the insulator 280, the insulator 250, and the like can be captured and fixed in the insulator 282. Moreover, oxygen contained in the insulator 280 and the like can be inhibited from diffusing to above the transistor 200 and the like. When the insulator 214 has a structure similar to that of one or both of the insulator 282 and the insulator 283, it is possible to inhibit diffusion of impurities such as water and hydrogen into the transistor 200 and the like from the substrate side. Oxygen contained in the oxide semiconductor 230 and the like can be prevented from diffusing to the components under the transistor 200 or the like. With such a structure where the transistor 200 and the like are surrounded by upper and lower insulators having a function of inhibiting diffusion of oxygen and impurities such as water and hydrogen, an excess amount of oxygen and hydrogen can be prevented from diffusing into the oxide semiconductor. Thus, the semiconductor device can have improved electrical characteristics and reliability.

The conductor 215 is placed to overlap with the oxide semiconductor 230 and the conductor 260. Here, the conductor 215 is preferably provided to be embedded in an opening portion formed in the insulator 216. Moreover, the conductor 215 is preferably provided to extend in the channel width direction as illustrated in FIG. 33A and FIG. 33C. With such a structure, the conductor 215 functions as a wiring when a plurality of transistors are provided.

The conductor 215 may have a single-layer structure or a stacked-layer structure. In FIG. 33B or the like, the conductor 215 includes the conductor 215a and the conductor 215b. The conductor 215a is provided in contact with the bottom surface and the sidewall of the opening portion. The conductor 215b is provided to fill a depressed portion that is defined by the conductor 215a and formed along the opening portion. Here, the top surface of the conductor 215 is level with the top surface of the insulator 216.

As the insulator 222, a barrier insulator against hydrogen is preferably used. As the insulator 222, a barrier insulator against oxygen is preferably used. For example, the insulator 222 preferably has a function of inhibiting diffusion of one or both of hydrogen and oxygen more than the insulator 216.

In the case where the insulator 222 is formed using such a material, the insulator 222 functions as a layer that inhibits release of oxygen from the oxide semiconductor 230 to the substrate side and diffusion of impurities such as hydrogen from the periphery of the transistor 200 into the oxide semiconductor 230. Thus, providing the insulator 222 can inhibit diffusion of impurities such as hydrogen into the transistor 200 and inhibit generation of oxygen vacancies in the oxide semiconductor 230. Moreover, the conductor 215 can be inhibited from reacting with oxygen contained in the oxide semiconductor 230.

The insulator 222 may have a single-layer structure or a stacked-layer structure of an insulator containing a high-k material. As miniaturization and high integration of transistors progress, a problem such as a leakage current may arise because of a thinner gate insulator. When a high-k material is used for the insulator functioning as a gate insulator, the gate potential at the time of the operation of the transistor can be reduced while the physical thickness is maintained.

Each of the conductor 242a and the conductor 242b may have a single-layer structure or a stacked-layer structure. The conductor 260 may have a single-layer structure or a stacked-layer structure.

For example, as illustrated in FIG. 34B, each of the conductor 242a and the conductor 242b may have a two-layer structure. In that case, the conductor 242a is a stacked film of the conductor 242a1 and the conductor 242a2 over the conductor 242a1, and the conductor 242b is a stacked film of the conductor 242b1 and the conductor 242b2 over the conductor 242b1. In this case, a conductive material that is less likely to be oxidized, such as metal nitride, or a conductive material having a function of inhibiting diffusion of oxygen is preferably used for the layer (the conductor 242a1 and the conductor 242b1) in contact with the oxide semiconductor 230b. Thus, the conductor 242a and the conductor 242b can be prevented from being oxidized excessively by oxygen contained in the oxide semiconductor 230b. Accordingly, a reduction in the conductivity of the conductor 242a and the conductor 242b can be inhibited.

The conductor 242a2 and the conductor 242b2 are preferably conductors having higher conductivity than the conductor 242a1 and the conductor 242b1, such as a metal layer. For example, the thicknesses of the conductor 242a2 and the conductor 242b2 are preferably larger than the thicknesses of the conductor 242a1 and the conductor 242b1. As the conductor 242a2 and the conductor 242b2, a conductor that can be used for the conductor 215b is used. Accordingly, the conductor 242a and the conductor 242b can each function as a wiring or an electrode with high conductivity. In this manner, a semiconductor device in which the conductor 242a and the conductor 242b which function as a wiring or an electrode are provided in contact with the top surface of the oxide semiconductor 230 functioning as an active layer can be provided.

The insulator 271a and the insulator 271b are inorganic insulators for protecting the conductor 242a and the conductor 242b, respectively. Since the insulator 271a and the insulator 271b are respectively in contact with the conductor 242a and the conductor 242b, the insulator 271a and the insulator 271b are preferably inorganic insulators that are less likely to oxidize the conductor 242a and the conductor 242b. Thus, the insulator 271a preferably has a stacked-layer structure of the insulator 271a1 and the insulator 271a2 over the insulator 271a1, and the insulator 271b preferably has a stacked-layer structure of the insulator 271b1 and the insulator 271b2 over the insulator 271b1. Here, the insulator 271a1 and the insulator 271b1 are each preferably formed using the nitride insulator that can be used for the insulator 250c, so as not to easily oxidize the conductor 242a and the conductor 242b. An oxide insulator that can be used for the insulator 250b is preferably used for the insulator 271a2 and the insulator 271b2.

Here, the insulator 271a1 is in contact with the top surface of the conductor 242a and a part of the insulator 275, and the insulator 271b1 is in contact with the top surface of the conductor 242b and another part of the insulator 275. The insulator 271a2 is in contact with the top surface of the insulator 271a1 and the bottom surface of the insulator 275, and the insulator 271b2 is in contact with the top surface of the insulator 271b1 and the bottom surface of the insulator 275. For example, silicon nitride can be used for the insulator 271a1 and the insulator 271b1, and silicon oxide can be used for the insulator 271a2 and the insulator 271b2.

An insulating layer to be the insulator 271a and the insulator 271b functions as a mask for a conductive layer to be the conductor 242a and the conductor 242b, and thus the conductive layer does not have a curved surface between the side surface and the top surface. Thus, end portions at the intersections of the side surfaces and the top surfaces of the conductor 242a and the conductor 242b are angular. The cross-sectional area of each of the conductor 242a and the conductor 242b is larger in the case where the end portion at the intersection of the side surface and the top surface of each of the conductor 242a and the conductor 242b is angular than in the case where the end portion has a curved surface. Furthermore, when a nitride insulator that is less likely to oxidize a metal is used for the insulator 271a1 and the insulator 271b1, excessive oxidation of the conductor 242a and the conductor 242b can be prevented. Accordingly, the resistance of the conductor 242a and the conductor 242b is reduced, so that the on-state current of the transistor can be increased.

As illustrated in FIG. 34A and FIG. 35A, the conductor 260 is placed in the opening portion formed in the insulator 280, the insulator 275, and the insulator 223. The conductor 260 is provided in the opening portion to cover the top surface of the insulator 222, the side surface of the insulator 223, the side surface of the oxide semiconductor 230a, the side surface of the oxide semiconductor 230b, and the top surface of the oxide semiconductor 230b, with the insulator 250 therebetween. The top surface of the conductor 260 is level with each of the top surface of the insulator 250 and the top surface of the insulator 280.

The conductor 260 is preferably provided to extend in the channel width direction as illustrated in FIG. 33C, FIG. 35A, and FIG. 35B. With such a structure, the conductor 260 functions as a wiring when a plurality of transistors are provided.

In the case where the above-described structure is employed, a curved surface may be provided between the side surface of the oxide semiconductor 230b and the top surface of the oxide semiconductor 230b in the cross-sectional view of the transistor 200 in the channel width direction, as illustrated in FIG. 35A and FIG. 35B. That is, an end portion of the side surface and an end portion of the top surface may be curved (hereinafter also referred to as rounded).

The radius of curvature of the curved surface is preferably greater than 0 nm and less than the thickness of the oxide semiconductor 230b in a region overlapping with the conductor 242a or the conductor 242b, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide semiconductor 230b with the insulator 250 and the conductor 260.

FIG. 33B and the like illustrate the conductor 260 having a two-layer structure. Here, the conductor 260 preferably includes the conductor 260a and the conductor 260b placed over the conductor 260a. For example, the conductor 260a is preferably placed to cover the bottom surface and the side surface of the conductor 260b. In this case, a conductive material that is less likely to be oxidized or a conductive material having a function of inhibiting diffusion of oxygen is preferably used for the conductor 260a.

The insulator 216 and the insulator 280 each preferably have a lower dielectric constant than the insulator 214. When a material with a low dielectric constant is used for an interlayer film, parasitic capacitance generated between wirings can be reduced. The top surfaces of the insulator 216 and the insulator 280 may be planarized.

The concentration of impurities such as water or hydrogen in the insulator 280 is preferably reduced. For example, the insulator 280 preferably contains an oxide containing silicon such as silicon oxide or silicon oxynitride.

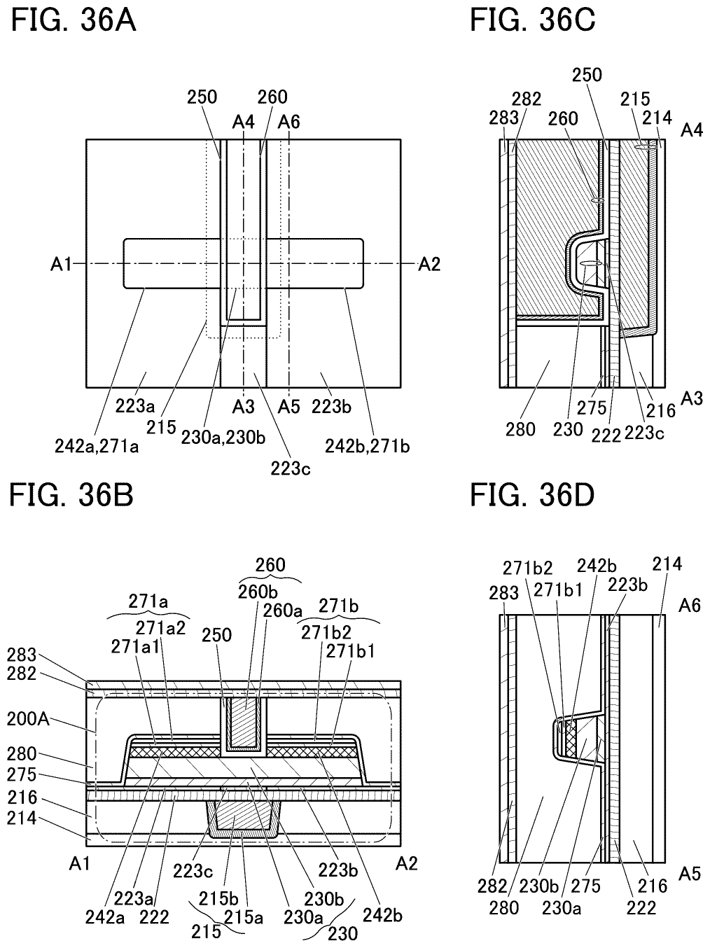

Although the structure of the insulator 223 in the semiconductor device illustrated in FIG. 33A to FIG. 33D is the same as the structure of the insulator 223 in the semiconductor device illustrated in FIG. 5A to FIG. 5D, the present invention is not limited thereto. The structure of the insulator 223 may be any of the structures of the insulator 223 described in Embodiment 1. For example, as illustrated in FIG. 36A to FIG. 36D, the insulator 223 may be the insulator 223 (the insulator 223a to the insulator 223c) illustrated in FIG. 24A to FIG. 24D.

### Structure Example 2 of Semiconductor Device

Although the insulator 250 is in contact with the side surface of the insulator 280, the side surface of the insulator 275, and the side surface of the insulator 223 in the opening portion provided in the insulator 280, the insulator 275, and the insulator 223 in FIG. 33A to FIG. 33D, the present invention is not limited to this structure. For example, an insulator may be provided between the insulator 250 and the insulator 280, the insulator 275, and the insulator 223 in the opening portion.

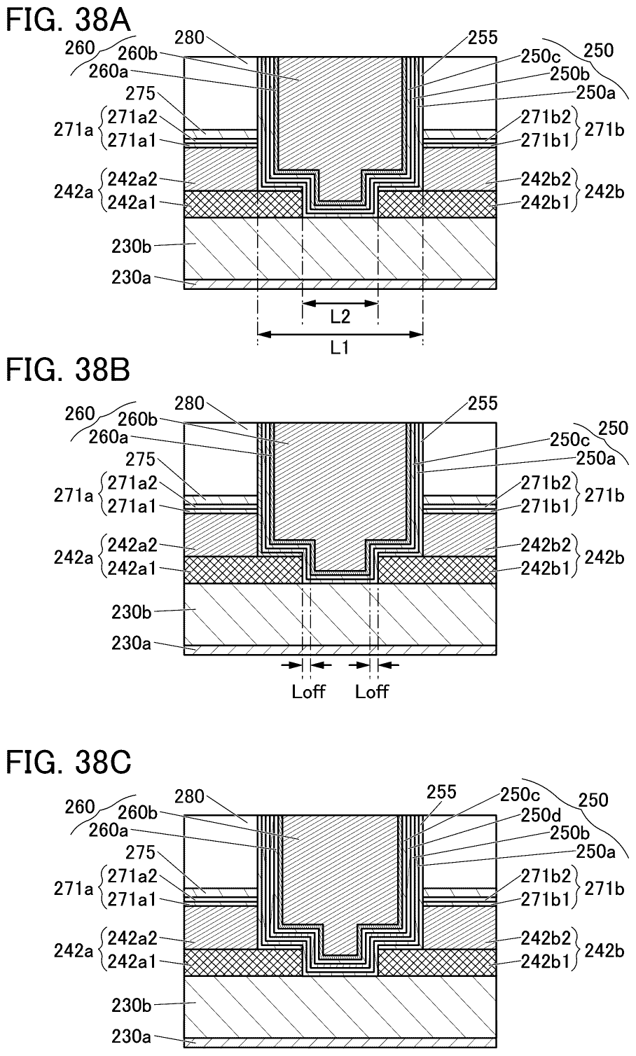

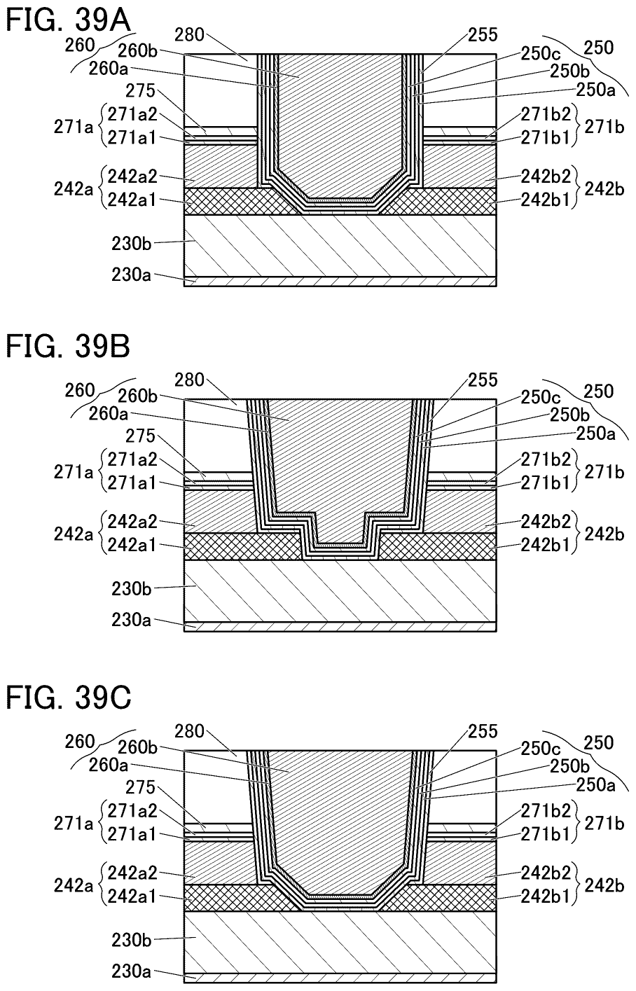

Another example of the structure of a semiconductor device is described with reference to FIG. 37A to FIG. 39C. FIG. 37A to FIG. 37D are a plan view and cross-sectional views of a semiconductor device including the transistor 200. FIG. 38A to FIG. 39C are enlarged cross-sectional views of the transistor 200 in the channel length direction.

The structure of the semiconductor device illustrated in FIG. 37A to FIG. 37D is also a detailed structure of the semiconductor device described in [Structure example 1-4] in Embodiment 1. Portions different from the above description of [Structure example 1-4] in Embodiment 1 are mainly described below; description of the same portion is omitted in some cases and the description of [Structure example 1-4] is referred to. For example, the description in Embodiment 1 can be referred to for materials, structures, and the like used for components (e.g., an insulator, an oxide semiconductor, and a conductor) of the semiconductor device.

The transistor 200 illustrated in FIGS. 37A to 37D is also a modification example of the transistor 200 illustrated in FIGS. 33A to 33D. Specifically, the transistor 200 illustrated in FIGS. 37A to 37D is different from the transistor 200 illustrated in FIGS. 33A to 33D mainly in including the insulator 255. Portions different from the above description of <Structure example 1 of semiconductor device> are mainly described below; the description of the same portions is omitted in some cases and the description of <Structure example 1 of semiconductor device> is referred to for.

The transistor 200 includes the insulator 216 over the insulator 214, the conductor 215 provided to be embedded in the insulator 216, the insulator 222 over the insulator 216 and the conductor 215, the insulator 223 over the insulator 222, the oxide semiconductor 230 over the insulator 223, the conductor 242a and the conductor 242b over the oxide semiconductor 230, the insulator 271a over the conductor 242a, the insulator 271b over the conductor 242b, the insulator 250 over the oxide semiconductor 230, and the conductor 260 over the insulator 250. The insulator 255 is provided between the insulator 250 and the conductor 242a, the conductor 242b, the insulator 271a, the insulator 271b, the insulator 275, and the insulator 280.

The insulator 255, the insulator 250, and the conductor 260 are placed in an opening portion provided in the insulator 280 and the insulator 275. An insulator 282 is provided over the insulator 280, the insulator 255, the insulator 250, and the conductor 260.

The conductor 242a has a stacked structure of the conductor 242a1 and the conductor 242a2 over the conductor 242a1, and the conductor 242b has a stacked structure of the conductor 242b1 and the conductor 242b2 over the conductor 242b1. The conductor 242a1 and the conductor 242b1 in contact with the oxide semiconductor 230b are preferably conductors that are not easily oxidized. The conductor 242a2 and the conductor 242b2 are preferably conductors having higher conductivity than the conductor 242a1 and the conductor 242b1, such as a metal layer.

As illustrated in FIG. 38A, in the cross-sectional view of the transistor 200 in the channel length direction, a distance L2 between the conductor 242a1 and the conductor 242b1 is smaller than a distance L1 between the conductor 242a2 and the conductor 242b2. With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operating speed.

The opening portion formed in the insulator 280 and the insulator 275 overlaps with a region between the conductor 242a2 and the conductor 242b2. The conductor 242a1 and the conductor 242b1 are formed to partly extend toward the inside of the opening portion. Thus, in the opening portion, the insulator 255 is in contact with the top surface of the conductor 242a1, the top surface of the conductor 242b1, the side surface of the conductor 242a2, and the side surface of the conductor 242b2. The insulator 250 is in contact with the top surface of the oxide semiconductor 230 in a region between the conductor 242a1 and the conductor 242b1.

Here, as illustrated in FIG. 38A, the insulator 250 preferably has a stacked-layer structure of the insulator 250a in contact with the oxide semiconductor 230, the insulator 250b over the insulator 250a, and the insulator 250c over the insulator 250b. In this case, the insulator 250a preferably has a function of capturing and fixing hydrogen.

As illustrated in FIG. 38C, the insulator 250d may be provided between the insulator 250b and the insulator 250c. In that case, as the insulator 250d, an insulator that can be used as the insulator 250a can be provided.

The insulator 250a and the insulator 255 each preferably have a barrier property against oxygen. It is preferable that oxygen be less likely to pass through the insulator 250a and the insulator 255 than at least the insulator 280. The insulator 250a includes a region in contact with a side surface of the conductor 242a1 and a region in contact with a side surface of the conductor 242b1. The insulator 255 includes a region in contact with the top surface of the conductor 242a1, the top surface of the conductor 242b1, the side surface of the conductor 242a2, and the side surface of the conductor 242b2. The insulator 250a is in contact with the top surface and the side surface of the insulator 255. When the insulator 250a and the insulator 255 each have a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 200 can be inhibited.

With the above structure, even when an excess amount of oxygen is contained in the insulator 280, the oxygen can be inhibited from being excessively supplied to the oxide semiconductor 230b, so that an appropriate amount of oxygen can be supplied to the oxide semiconductor 230b. Thus, it is possible to inhibit excessive oxidation of the source region and the drain region and a decrease in the on-state current or field-effect mobility of the transistor 200.

Although the case where the insulator 250 has a three-layer structure of the insulator 250a to the insulator 250c or a four-layer structure of the insulator 250a to the insulator 250d is described above, the present invention is not limited thereto. The insulator 250 can have a structure including at least one of the insulator 250a to the insulator 250d. When the insulator 250 is formed of one, two, or three layer(s) of the insulator 250a to the insulator 250d, the manufacturing process of the semiconductor device can be simplified and the productivity can be increased.

For example, as illustrated in FIG. 38B, the insulator 250 may have a two-layer structure. In that case, the insulator 250 preferably has a stacked-layer structure of the insulator 250a and the insulator 250c over the insulator 250a. A high-k material can be used for at least one of the insulator 250a and the insulator 250c. Thus, the equivalent oxide thicknesses (EOT) of the insulator 250a and the insulator 250c can be reduced while the thicknesses thereof are kept large enough to inhibit a leakage current.

Note that, in the transistor 200 of this embodiment as illustrated in FIG. 38B, the oxide semiconductor 230b is provided with a region overlapping with the insulator 250 in contact with the side surface of the conductor 242a1 and a region overlapping with the insulator 250 in contact with the side surface of the conductor 242b1 (the regions are hereinafter referred to as Loff regions). The Loff regions overlap with neither the conductor 242a1 nor the conductor 242b1 and do not overlap with the conductor 260 with the insulator 250 therebetween; thus they function like a resistor.

In the transistor 200 illustrated in FIG. 38B, the insulator 250 is formed of only the insulator 250a and the insulator 250c, and each of the insulator 250a and the insulator 250c can be formed to have a small thickness as described above. For example, the insulator 250a is formed using aluminum oxide to have a thickness of 2.0 nm, and the insulator 250c is formed using silicon nitride to have a thickness of 1.5 nm, whereby the thickness of the insulator 250 can be 3.5 nm. Making the thickness of the insulator 250 small in this manner enables the width of each Loff region to be narrowed. Accordingly, the frequency characteristics of the transistor 200 can be improved, and the operation speed of the semiconductor device of one embodiment of the present invention can be improved.

In this embodiment, the insulator 255 is provided between the insulator 250 and the conductor 242a and between the insulator 250 and the conductor 242b. Accordingly, the distance between the conductor 260 and the conductor 242a and the distance between the conductor 260 and the conductor 242b can be increased by the thickness of the insulator 255. Thus, while the parasitic capacitance between the conductor 260 and each of the conductor 242a and the conductor 242b is reduced, the thickness of the insulator 250 can be reduced, so that the Loff regions can be small.

As illustrated in FIG. 37B and FIG. 37C, the insulator 255 is provided in the opening portion formed in the insulator 280 and the like, and in contact with the side surface of the insulator 280, the side surface of the insulator 275, a side surface of the insulator 271a, a side surface of the insulator 271b, the side surface of the conductor 242a2, the side surface of the conductor 242b2, the side surface of the conductor 242a1, the side surface of the conductor 242b1, and the top surface of the insulator 222 in the opening portion. In other words, the insulator 255 may be formed to have an opening portion that exposes the island-shaped oxide semiconductor 230 therein. In a region of the opening portion formed in the insulator 255, the insulator 250 is in contact with the oxide semiconductor 230 and the insulator 222. Although the insulator 255 has an opening only in the vicinity of the oxide semiconductor 230 in FIG. 37C, the present invention is not limited thereto. The insulator 255 may have an opening at least in a region of the oxide semiconductor 230b that is sandwiched between the conductor 242a1 and the conductor 242b1. Thus, for example, the insulator 255 may be formed in a sidewall shape in an opening portion formed in the insulator 280 and the like and rarely include a region in contact with the insulator 222.

The insulator 255 is formed in contact with the side surface of the conductor 242a2 and the side surface of the conductor 242b2, and is an inorganic insulator that protects the conductor 242a2 and the conductor 242b2. The insulator 255 is preferably an inorganic insulator that is less likely to be oxidized because it is exposed to an oxidation atmosphere. Since the insulator 255 is in contact with the conductor 242a2 and the conductor 242b2, the insulator 255 is preferably an inorganic insulator that is less likely to oxidize the conductor 242a2 and the conductor 242b2. Thus, for the insulator 255, an insulating material that can be used for the insulator 250c having a barrier property against oxygen is preferably used. The insulator 255 can be formed using silicon nitride, for example.

With the use of the insulator 255 described above, even when heat treatment is performed in an atmosphere containing oxygen after the separation into the conductor 242a2 and the conductor 242b2 and before the formation of the insulator 250, the conductor 242a2 and the conductor 242b2 can be prevented from being excessively oxidized.

The thickness of the insulator 255 is preferably larger than that of any one of the insulator 250a to the insulator 250d. The thickness of the insulator 255 is preferably greater than or equal to 1 nm and less than or equal to 20 nm, further preferably greater than or equal to 1 nm and less than or equal to 15 nm, still further preferably greater than or equal to 3 nm and less than or equal to 10 nm, and for example, can be approximately 5 nm. When the insulating layer 255 has the above thickness, the distance between the conductor 260 and the conductor 242a or the conductor 242b can be increased, so that the parasitic capacitance can be reduced. In this case, at least part of the insulator 255 has a region with the above-described thickness. Since the insulator 255 is provided in the opening formed in the insulator 280, the insulator 255 is preferably formed by a method capable of depositing a film with good coverage, such as an ALD method.

The insulator 255 functions as part of a mask at the time of dividing the conductor into the conductor 242a1 and the conductor 242b1. Accordingly, as illustrated in FIG. 37B, it is preferable that the side end portion of the insulator 255 be aligned with the side end portion of the conductor 242a1 and a side end portion of the conductor 242b1 in the cross-sectional view of the transistor 200.

Here, part of the conductor 242a1 having a top surface on which the insulator 255 is formed, is formed to extend beyond the conductor 242a2 toward the conductor 260 side. Similarly, part of the conductor 242b1 having a top surface on which the insulator 255 is formed is formed to extend from the conductor 242b2 toward the conductor 260 side. As illustrated in FIG. 38A, in the cross-sectional view of the transistor 200 in the channel length direction, the distance L2 between the conductor 242a1 and the conductor 242b1 is smaller than the distance L1 between the conductor 242a2 and the conductor 242b2.

The distance L2 between the conductor 242a1 and the conductor 242b1 is preferably short because the distance L2 reflects the channel length of the transistor 200. For example, the distance L2 is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm. For example, the distance L2 is preferably greater than or equal to 2 nm and less than or equal to 20 nm. With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operation speed.

In the transistor 200 illustrated in FIG. 38A, the side surfaces of the conductor 242a1 and the conductor 242b1 that face each other are substantially perpendicular to the top surface of the oxide semiconductor 230b; however, the present invention is not limited thereto. For example, as illustrated in FIG. 39A, the side surfaces of the conductor 242a1 and the conductor 242b1 that face each other may have tapered shapes. With such shapes, the distance between the conductor 260 and the oxide semiconductor 230b is shortened in the vicinity of side end portions of the conductor 242a1 and the conductor 242b1, which reduces the influence of the Loff regions.

As illustrated in FIG. 39B, the side surfaces of the conductor 242a1 and the conductor 242b1 which face each other and the side surfaces of the conductor 242a2 and the conductor 242b2 which face each other may have tapered shapes.

As illustrated in FIG. 39C, the taper angle of the conductor 242a1 may be formed to be more acute than the taper angle of the conductor 242a2. Moreover, the taper angle of the conductor 242b1 may be formed to be more acute than the taper angle of the conductor 242b2. With such shapes, the distance between the conductor 260 and the oxide semiconductor 230b is further shortened in the vicinity of side end portions of the conductor 242a1 and the conductor 242b1, which reduces the influence of the Loff regions.

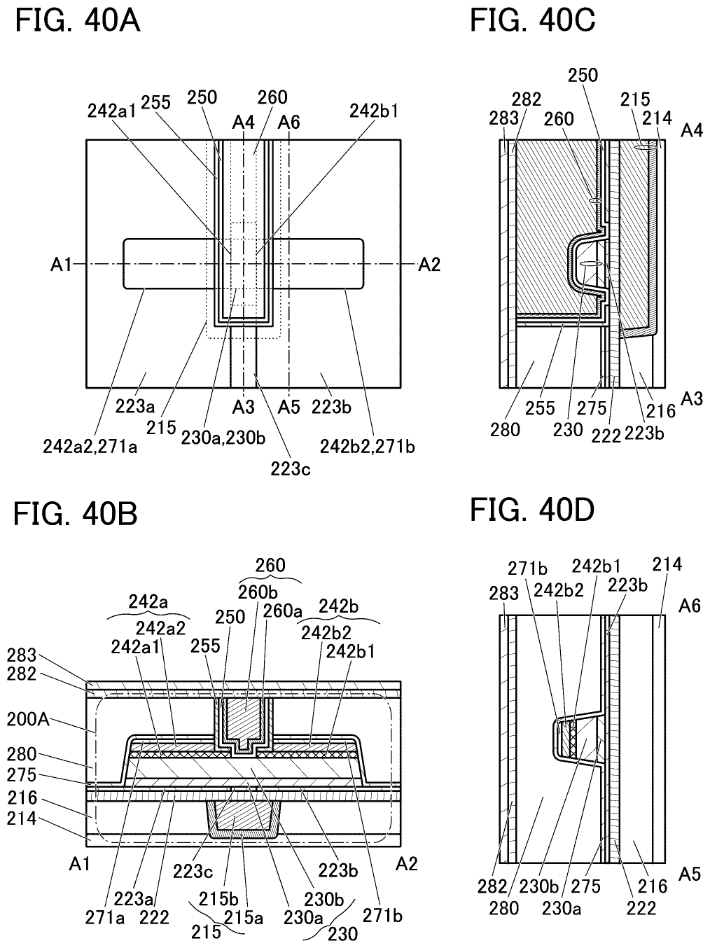

Although the structure of the insulator 223 in the semiconductor device illustrated in FIG. 37A to FIG. 37D is the same as the structure of the insulator 223 in the semiconductor device illustrated in FIG. 7A to FIG. 7D, the present invention is not limited thereto. The structure of the insulator 223 may be any of the structures of the insulator 223 described in Embodiment 1. For example, as illustrated in FIG. 40A to FIG. 40D, the insulator 223 may be the insulator 223 (the insulator 223a to the insulator 223c) illustrated in FIG. 26A to FIG. 26D.

### Structure Example 3 of Semiconductor Device

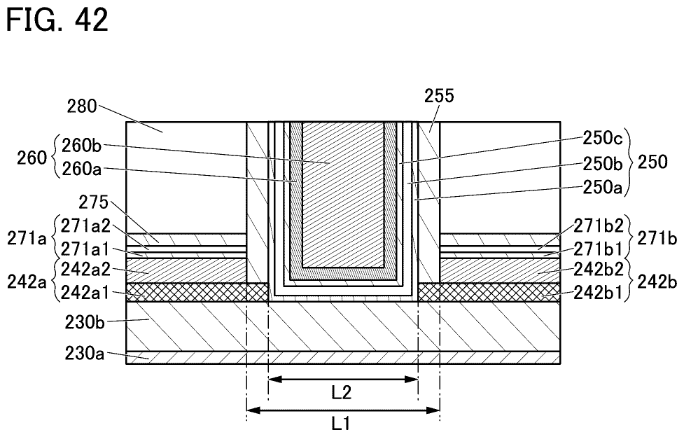

Another example of the structure of a semiconductor device is described with reference to FIG. 41A to FIG. 44C. FIG. 41A to FIG. 41D are a plan view and cross-sectional views of a semiconductor device including the transistor 200. FIG. 42 to FIG. 44C are enlarged cross-sectional views of the transistor 200 in the channel length direction.

The structure of the semiconductor device illustrated in FIG. 41A to FIG. 41D is also a detailed structure of the semiconductor device described in [Structure example 1-5] in Embodiment 1. Portions different from the above description of [Structure example 1-5] in Embodiment 1 are mainly described below; description of the same portion is omitted in some cases and the description of [Structure example 1-5] is referred to. For example, the description in Embodiment 1 can be referred to for materials, structures, and the like used for components (e.g., an insulator, an oxide semiconductor, and a conductor) of the semiconductor device.

The transistor 200 illustrated in FIGS. 41A to 41D is also a modification example of the transistor 200 illustrated in FIGS. 37A to 37D. Specifically, the transistor 200 illustrated in FIG. 41A to FIG. 41D is different from the transistor 200 illustrated in FIG. 37A to FIG. 37D mainly in the shape of the insulator 255. Portions different from the above description of <Structure example 2 of semiconductor device> are mainly described below; the description of the same portions is omitted in some cases and the description of <Structure example 2 of semiconductor device> is referred to for.

As illustrated in FIG. 42, in the cross-sectional view of the transistor 200 in the channel length direction, the distance L2 between the conductor 242a1 and the conductor 242b1 is smaller than the distance L1 between the conductor 242a2 and the conductor 242b2. Specifically, the difference between the distance L1 and the distance L2 is equal to twice the thickness of the insulator 255. In other words, the distance L1 is equal to the sum of the distance L2 and twice the thickness of the insulator 255. Here, the thickness of the insulator 255 corresponds to the thickness in the A1-A2 direction of at least part of the insulator 255. With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operating speed.

The opening portion formed in the insulator 280 and the insulator 275 overlaps with the region between the conductor 242a2 and the conductor 242b2. In a top view, a side surface of the insulator 280 in the opening portion is aligned with the side surface of the conductor 242a2 and the side surface of the conductor 242b2. The conductor 242a1 and the conductor 242b1 are formed to partly extend toward the inside of the opening portion. Here, a part of a top surface of the conductor 242a1 is in contact with the conductor 242a2, and a part of a top surface of the conductor 242b1 is in contact with the conductor 242b2. Thus, in the opening portion, the insulator 255 is in contact with another part of the top surface of the conductor 242a1, another part of the top surface of the conductor 242b1, the side surface of the conductor 242a2, and the side surface of the conductor 242b2. The insulator 250 is in contact with the top surface of the oxide semiconductor 230, the side surface of the conductor 242a1, the side surface of the conductor 242b1, and the side surface of the insulator 255.

By anisotropic etching, the insulator 255 is formed in a sidewall shape to be in contact with the sidewall of the opening portion formed in the insulator 280 and the like (here, the sidewall of the opening portion corresponds to, for example, the side surface of the insulator 280 or the like in the opening portion). The insulator 255 is formed in contact with the side surface of the conductor 242a2 and the side surface of the conductor 242b2 and has a function of protecting the conductor 242a2 and the conductor 242b2.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device illustrated in FIG. 42, the insulator corresponds to the insulator 250a, the insulator 250c, the insulator 255, and the insulator 275, for example. For example, each of the insulator 250a, the insulator 250c, the insulator 255, and the insulator 275 preferably has a single-layer structure or a stacked-layer structure of the barrier insulator against oxygen.

The insulator 250a and the insulator 255 each preferably have a barrier property against oxygen. It is preferable that oxygen be less likely to pass through the insulator 250a and the insulator 255 than at least the insulator 280. The insulator 250a includes a region in contact with a side surface of the conductor 242a1 and a region in contact with a side surface of the conductor 242b1. The insulator 255 includes a region in contact with the top surface of the conductor 242a1, the top surface of the conductor 242b1, the side surface of the conductor 242a2, and the side surface of the conductor 242b2. The insulator 250a is in contact with the side surface of the insulator 255. When the insulator 250a and the insulator 255 each have a barrier property against oxygen, oxidation of the side surfaces of the conductor 242a and the conductor 242b and formation of oxide films on the side surfaces can be inhibited. Accordingly, a decrease in the on-state current or field-effect mobility of the transistor 200 can be inhibited.

Here, it is preferable that a region of the insulator 275 not overlapping with the oxide semiconductor 230 be in contact with the insulator 223, a side end portion of the insulator 275 be in contact with the insulator 255, and an upper end portion of the insulator 255 and upper end portions of the insulator 250a to the insulator 250c be in contact with the insulator 282. With the above structure, in a region sandwiched between the insulator 283 and the insulator 222, the insulator 280 is separated from the oxide semiconductor 230 by the insulator 275, the insulator 280 is separated from the insulator 250b by the insulator 255 and the insulator 250a, the conductor 260 is separated from the insulator 250b by the insulator 250c, and the conductor 242a2 and the conductor 242b2 are separated from the insulator 250b by the insulator 255 and the insulator 250a.

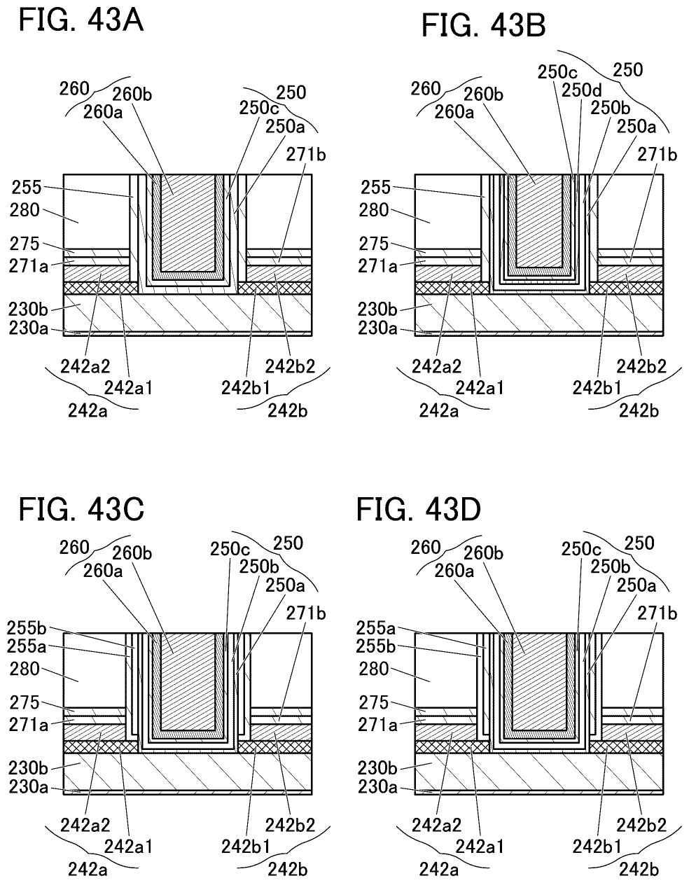

Although the structure in which the insulator 250 has a three-layer structure of the insulator 250a to the insulator 250c is described with reference to FIG. 42, the present invention is not limited thereto. The insulator 250 can have a structure including at least one of the insulator 250a to the insulator 250d. For example, as in the structure illustrated in FIG. 38B, the insulator 250 may have a two-layer structure. In that case, the insulator 250 preferably has a stacked-layer structure of the insulator 250a and the insulator 250c over the insulator 250a (see FIG. 43A). For another example, as in the structure illustrated in FIG. 38C, the insulator 250 may have a four-layer structure. In that case, the insulator 250 preferably has a stacked-layer structure of the insulator 250a, the insulator 250b over the insulator 250a, the insulator 250d over the insulator 250b, and the insulator 250c over the insulator 250d (see FIG. 43B).

As illustrated in FIG. 41B and FIG. 41C, the insulator 255 is provided in the opening portion formed in the insulator 280 and the like, and in contact with the side surface of the insulator 280, the side surface of the insulator 275, the side surface of the insulator 271a, the side surface of the insulator 271b, the side surface of the conductor 242a2, the side surface of the conductor 242b2, the top surface of the conductor 242a1, the top surface of the conductor 242b1, and the top surface of the insulator 222. In other words, the insulator 255 is formed in a sidewall shape to be in contact with a sidewall of the opening formed in the insulator 280 and the like.

The thickness of the insulator 255 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 255 has a thickness in the above range, excessive oxidation of the conductor 242a2 and the conductor 242b2 can be prevented. In this case, at least part of the insulator 255 has a region with the above-described thickness. Since the insulator 255 is provided in contact with the sidewall of the opening formed in the insulator 280 and the like, the insulator 255 is preferably formed by a method capable of depositing a film with good coverage, such as an ALD method. When the thickness of the insulator 255 is set excessively large, the time for forming the insulator 255 by an ALD method is long, which decreases the productivity; for this reason, the thickness of the insulator 255 is preferably in the above range.

Furthermore, the insulator 255 may have a stacked-layer structure of two or more layers. In that case, at least one of the stacked layers is the above-described inorganic insulator that is less likely to be oxidized. For example, as illustrated in FIG. 43C, the insulator 255 may have a stacked-layer structure of an insulator 255a and an insulator 255b over the insulator 255a. The insulator 255b can be regarded as being provided on the inner side of the insulator 255a. Here, a bottom surface of the insulator 255b is in contact with the insulator 255a in some cases. The inorganic insulator that is less likely to be oxidized may be used for the insulator 255b, and an insulator that can be used for the insulator 250b (e.g., silicon oxide) may be used for the insulator 255a. The dielectric constant of the insulator 255a is preferably lower than that of the insulator 255b. When the insulator 255 has a two-layer structure to have a large thickness in the above manner, the distance between the conductor 260 and the conductor 242a or the conductor 242b can be increased, whereby the parasitic capacitance can be reduced.

Although FIG. 43C illustrates a structure in which the insulator 255a is positioned on the outer side and the insulator 255b is positioned on the inner side, the present invention is not limited thereto. For example, as illustrated in FIG. 43D, the insulator 255b may be positioned on the outer side and the insulator 255a may be positioned on the inner side. Here, a bottom surface of the insulator 255a is in contact with the insulator 255b in some cases.

The insulator 255 functions as a mask at the time of dividing the conductor into the conductor 242a1 and the conductor 242b1. Accordingly, as illustrated in FIG. 41B and the like, it is preferable that the side end portion of the insulator 255 be aligned with the side end portion of the conductor 242a1 and a side end portion of the conductor 242b1 in the cross-sectional view of the transistor 200.

Here, part of the conductor 242a1 having a top surface on which the insulator 255 is formed, is formed to extend beyond the conductor 242a2 toward the conductor 260 side. Similarly, part of the conductor 242b1 having a top surface on which the insulator 255 is formed is formed to extend from the conductor 242b2 toward the conductor 260 side. As illustrated in FIG. 42, in the cross-sectional view of the transistor 200 in the channel length direction, the distance L2 between the conductor 242a1 and the conductor 242b1 is smaller than the distance L1 between the conductor 242a2 and the conductor 242b2. Specifically, the difference between the distance L1 and the distance L2 is equal to twice the thickness of the insulator 255. In other words, the distance L1 is equal to the sum of the distance L2 and twice the thickness of the insulator 255.

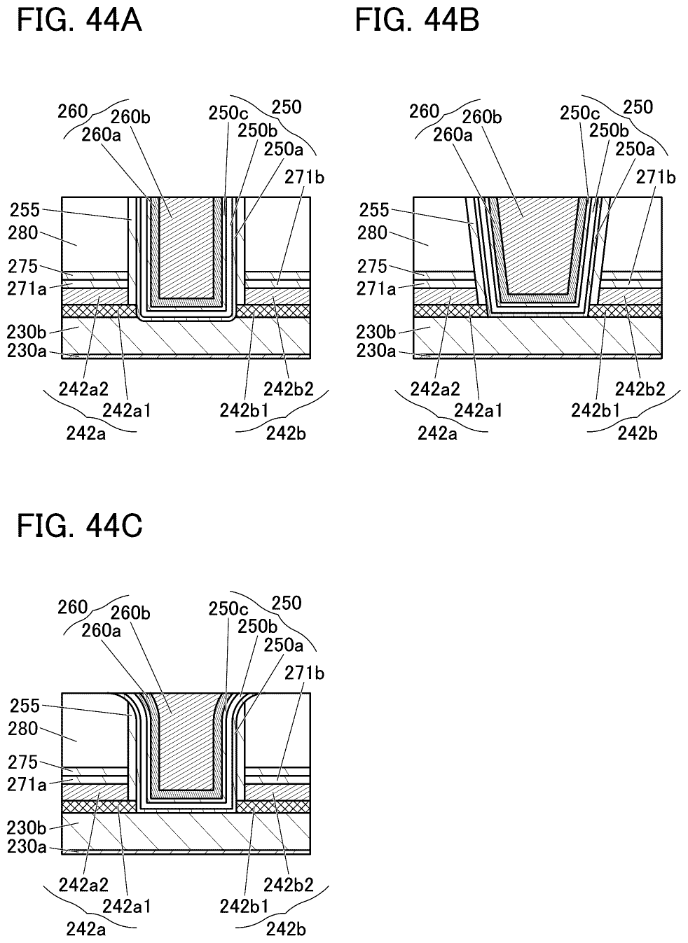

As illustrated in FIG. 44A, a depressed portion is sometimes formed in a portion of the oxide semiconductor 230b that is exposed from the conductor 242a1 and the conductor 242b1. In other words, in the top surface of the oxide semiconductor 230b, the level of a region sandwiched between the conductor 242a1 and the conductor 242b1 is lower than the level of a region overlapping with the conductor 242a1 and the level of a region overlapping with the conductor 242b1 in some cases.

In the transistor 200 illustrated in FIG. 44A, the side surfaces of the conductor 242a1 and the conductor 242b1 which face each other and the side surfaces of the conductor 242a2 and the conductor 242b2 which face each other are perpendicular or substantially perpendicular to the top surface of the oxide semiconductor 230b; however, the present invention is not limited thereto. As illustrated in FIG. 44B, for example, the side surfaces of the conductor 242a1 and the conductor 242b1 which face each other and the side surfaces of the conductor 242a2 and the conductor 242b2 which face each other may have tapered shapes. In that case, the side surfaces of the conductor 242a2, the conductor 242b2, the insulator 271a, the insulator 271b, the insulator 275, and the insulator 280 have tapered shapes in some cases.

Moreover, the taper angles of the conductor 242a1 and the conductor 242b1 may be formed to be more acute than the taper angles of the conductor 242a2 and the conductor 242b2.

As illustrated in FIG. 44C, an upper portion of the side surface of the insulator 255 has a tapered shape in some cases. Furthermore, as illustrated in FIG. 44C, an upper portion of the insulator 280 has a tapered shape that continues or roughly continues to the tapered shape of the side surface of the insulator 255 in some cases. As illustrated in FIG. 44C, an upper portion of the insulator 255 and an upper portion of the insulator 280 have curved surfaces in some cases. Here, the insulator 250a is sometimes in contact with the tapered shapes of the upper portions of the insulator 255 and the insulator 280. In that case, when the upper portions of the insulator 255 and the insulator 280 have curved surfaces, the insulator 250a can be formed with good coverage.

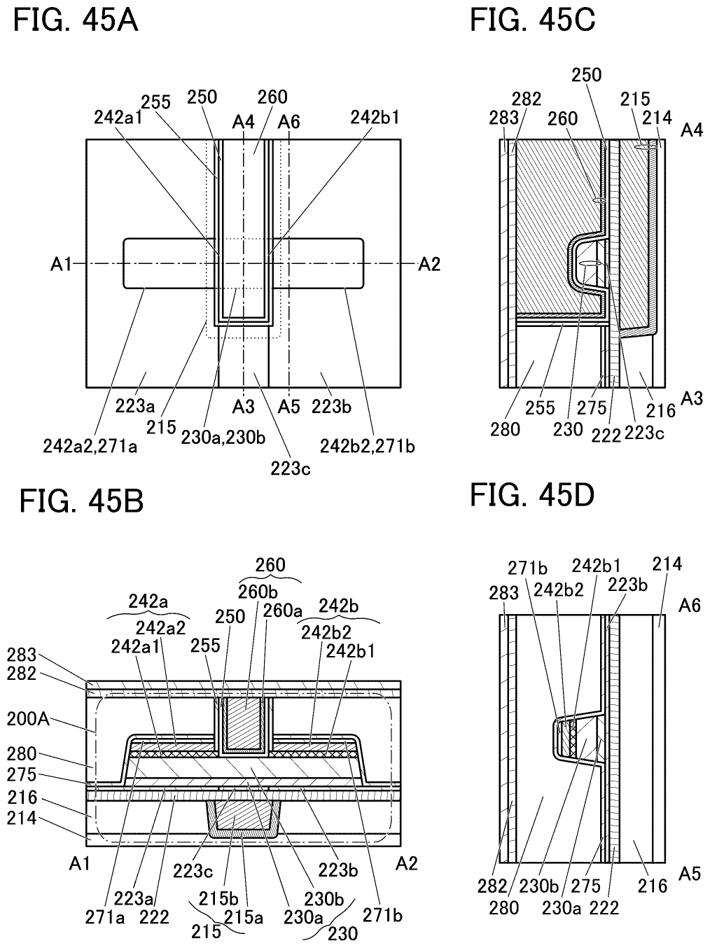

Although the structure of the insulator 223 in the semiconductor device illustrated in FIG. 41A to FIG. 41D is the same as the structure of the insulator 223 in the semiconductor device illustrated in FIG. 8A to FIG. 8D, the present invention is not limited thereto. The structure of the insulator 223 may be any of the structures of the insulator 223 described in Embodiment 1. For example, as illustrated in FIG. 45A to FIG. 45D, the insulator 223 may be the insulator 223 (the insulator 223a to the insulator 223c) illustrated in FIG. 27A to FIG. 27D.

### Structure Example 4 of Semiconductor Device

A structure example of the semiconductor device is described with reference to FIG. 46A to FIG. 49C. FIG. 46A to FIG. 46D are a plan view and cross-sectional views of a semiconductor device including a transistor 200a and a transistor 200b. Since the transistor 200b has a structure similar to that of the transistor 200a, the components are shown with the same hatching pattern as those of the transistor 200a and are not especially denoted by reference numerals. In the following description, the transistor 200a and the transistor 200b are collectively referred to as the transistor 200, in some cases. Note that when a capacitor electrically connected to the transistor 200a and a capacitor electrically connected to the transistor 200b are provided in the semiconductor device described in this embodiment, the semiconductor device can function as two memory cells of 1T (transistor) 1C (capacitor) type and can also be used in a storage device.

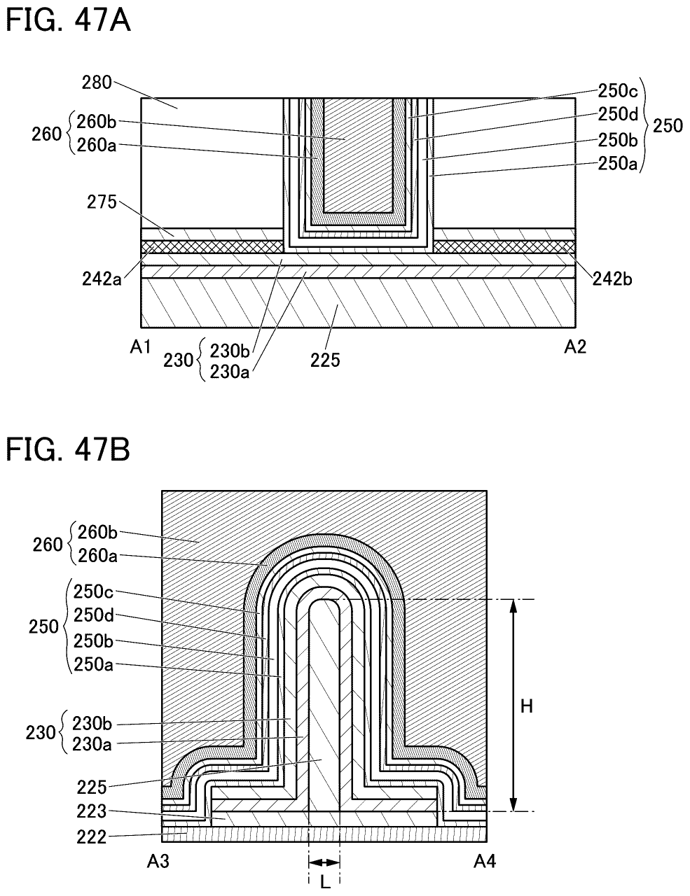

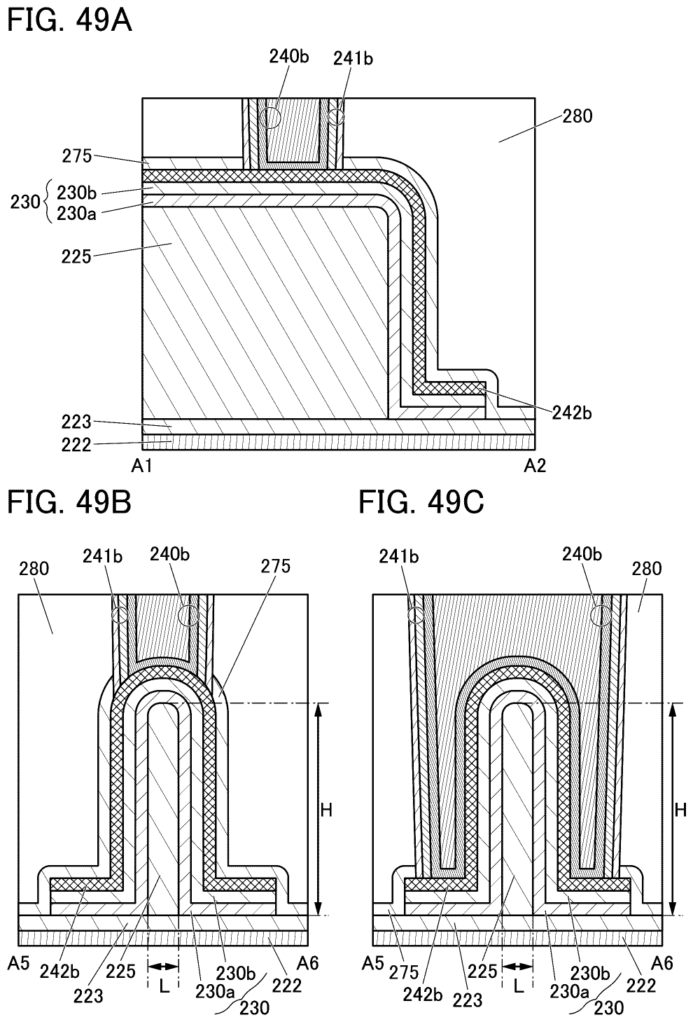

FIG. 47A is an enlarged view of the vicinity of the conductor 260 in FIG. 46B. FIG. 47B is an enlarged view of the vicinity of the insulator 225 in FIG. 46C. FIG. 49A is an enlarged view of the vicinity of the conductor 242a in FIG. 46B. FIG. 49B is an enlarged view of the vicinity of the insulator 225 in FIG. 46D.

The structure of the semiconductor device illustrated in FIG. 46A to FIG. 46D is also a detailed structure of the semiconductor device described in [Structure example 1-6] in Embodiment 1. Portions different from the above description of [Structure example 1-6] in Embodiment 1 are mainly described below; description of the same portion is omitted in some cases and the description of [Structure example 1-6] is referred to. For example, the description in Embodiment 1 can be referred to for materials, structures, and the like used for components (e.g., an insulator, an oxide semiconductor, and a conductor) of the semiconductor device.

The transistor 200 illustrated in FIGS. 46A to 46D is also a modification example of the transistor 200 illustrated in FIGS. 33A to 33D. Specifically, the transistor 200 illustrated in FIG. 46A to FIG. 46D is different from the transistor 200 illustrated in FIG. 33A to FIG. 33D mainly in including the insulator 225 and not including the conductor 215, the insulator 271a, and the insulator 271b. The transistor 200 illustrated in FIG. 46A to FIG. 46D is different from the transistor 200 illustrated in FIG. 33A to FIG. 33D mainly in the shapes of the oxide semiconductor 230, the conductor 242a, and the conductor 242b. Portions different from the above description of <Structure example 1 of semiconductor device> are mainly described below; the description of the same portions is omitted in some cases and the description of <Structure example 1 of semiconductor device> is referred to for.

The transistor 200 includes the insulator 216 over the insulator 214, the insulator 222 over the insulator 216, the insulator 223 over the insulator 222, the insulator 225 over the insulator 223, the oxide semiconductor 230 over the insulator 225 and the insulator 223, the conductor 242a and the conductor 242b over the oxide semiconductor 230, the insulator 250 over the oxide semiconductor 230, and the conductor 260 over the insulator 250.

The insulator 275 is provided over the conductor 242a and the conductor 242b, and the insulator 280 is provided over the insulator 275. The insulator 250 and the conductor 260 are placed in the opening portion provided in the insulator 280 and the insulator 275. The insulator 282 is provided over the insulator 280, the insulator 250, and the conductor 260. The insulator 283 is provided over the insulator 282.

An insulator 241a is provided in contact with an inner wall of an opening portion in the insulator 280 and the like, and the conductor 240a is provided in contact with a side surface of the insulator 241a. A bottom surface of the conductor 240a is in contact with the top surface of the conductor 242a. An insulator 241b is provided in contact with an inner wall of an opening portion in the insulator 280 and the like, and a conductor 240b is provided in contact with the side surface of the insulator 241b. A bottom surface of the conductor 240b is in contact with a top surface of the conductor 242b.

The oxide semiconductor 230 includes a region functioning as a channel formation region of the transistor 200. The conductor 260 includes a region functioning as the gate electrode of the transistor 200. The insulator 250 includes a region functioning as the gate insulator of the transistor 200. The conductor 242a includes a region functioning as one of a source electrode and a drain electrode of the transistor 200. The conductor 242b includes a region functioning as the other of the source electrode and the drain electrode of the transistor 200. The conductor 240a and the conductor 240b function as a plug connected to the conductor 242a and a plug connected to the conductor 242b, respectively.

The oxide semiconductor 230 preferably includes the oxide semiconductor 230a covering the insulator 225 and the oxide semiconductor 230b over the oxide semiconductor 230a. Here, the oxide semiconductor 230a is in contact with the top surface and the side surface of the insulator 225 and the top surface of the insulator 223. The oxide semiconductor 230a and the oxide semiconductor 230b are provided to cover the insulator 225 having a high aspect ratio, as illustrated in FIG. 47B and the like. Thus, the oxide semiconductor 230a and the oxide semiconductor 230b are preferably formed by a film formation method that offers excellent coverage, such as an ALD method. Here, as illustrated in FIG. 47B, in the cross section in the channel width direction, the oxide semiconductor 230a and the oxide semiconductor 230b are formed to be folded in half with the insulator 225 therebetween. With such a structure, the channel formation region of the transistor 200 can be formed in the upper portion, the side surface on the A3 side, and the side surface on the A4 side of the insulator 225; thus, the channel width per unit area can be increased.

Although an example in which the oxide semiconductor 230 has a two-layer structure of the oxide semiconductor 230a and the oxide semiconductor 230b is described in this embodiment, one embodiment of the present invention is not limited thereto. The oxide semiconductor 230 may have a single-layer structure of the oxide semiconductor 230b or a stacked-layer structure of three or more layers, for example.

As illustrated in FIG. 47A and FIG. 47B, the insulator 250 has a stacked-layer structure of the insulator 250a in contact with the oxide semiconductor 230, the insulator 250b over the insulator 250a, the insulator 250d over the insulator 250b, and the insulator 250c over the insulator 250d.

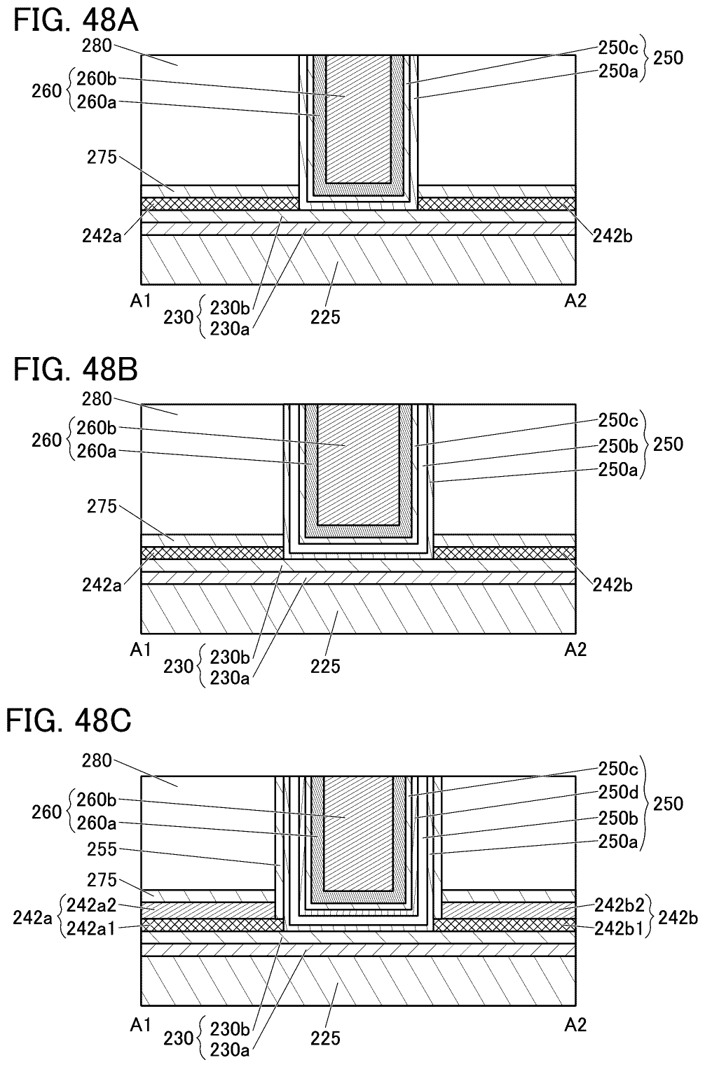

For example, as illustrated in FIG. 48A, the insulator 250 may have a two-layer structure. In that case, the insulator 250 preferably has a stacked-layer structure of the insulator 250a and the insulator 250c over the insulator 250a. A high-k material can be used for at least one of the insulator 250a and the insulator 250c. Thus, the equivalent oxide thicknesses (EOT) of the insulator 250a and the insulator 250c can be reduced while the thicknesses thereof are kept large enough to inhibit a leakage current.

For example, as illustrated in FIG. 48B, the insulator 250 may have a three-layer structure. In that case, the insulator 250 preferably has a stacked-layer structure of the insulator 250a, the insulator 250b over the insulator 250a, and the insulator 250c over the insulator 250b.

The insulator 225 is formed over and in contact with the insulator 223. As illustrated in FIG. 47B and FIG. 49B, the insulator 225 has a shape with a high aspect ratio in the cross-sectional view in the channel width direction. Here, the aspect ratio of the insulator 225 in the cross-sectional view in the channel width direction refers to the ratio between a length L of the insulator 225 in the A3-A4 direction (also referred to as a width L of the insulator 225) and a length H of the insulator 225 in a direction perpendicular to the formation surface (e.g., the insulator 222) of the insulator 225 (also referred to as a height H of the insulator 225). In the insulator 225, the height H of the insulator 225 is at least larger than the width L of the insulator 225. The height H of the insulator 225 is more than one, preferably more than or equal to two, further preferably more than or equal to five, still further preferably more than or equal to ten times the width L of the insulator 225. The height H of the insulator 225 is preferably less than or equal to twenty times the width L of the insulator 225.

The oxide semiconductor 230, the conductor 242a, and the conductor 242b are provided to cover the insulator 225 having such a high aspect ratio. In the transistor 200, as illustrated in FIG. 47B, the oxide semiconductor 230 is provided to be folded in half to sandwich the insulator 225, and the insulator 250 and the conductor 260 are provided to cover the oxide semiconductor 230. Thus, in the cross-sectional view in the channel width direction, the oxide semiconductor 230 and the conductor 260 are provided to face each other with the insulator 250 therebetween along the portion above the insulator 225 and the side surface on the A3 side and the side surface on the A4 side of the insulator 225. That is, the upper portion, the side surface on the A3 side, and the side surface on the A4 side of the insulator 225 function as a channel formation region. Thus, the channel width of the transistor 200 is larger by the side surface on the A3 side and the side surface on the A4 side of the insulator 225 than that in the case where the insulator 225 is not provided.

The transistor 200 can have a favorable on-state current, field-effect mobility, frequency characteristics, and the like when the channel width is increased as described above. Hence, a semiconductor device that can operate at high speed can be provided. In addition, the operation speed of a storage device including the semiconductor device can be increased. In the above structure, provision of the insulator 225 enables the channel width to be increased without an increase in the area occupied by the transistor 200. In that case, miniaturization and high integration of the semiconductor device can be achieved. It is also possible to increase the storage capacity of a storage device including the semiconductor device.

For the insulator 225, an insulating material that can be used for the insulator 222, the insulator 223, the insulator 280, the insulator 250, or the like is used. Since the insulator 225 has a shape with a high aspect ratio, the insulator 225 is preferably formed in a sidewall shape along the side surface of a sacrificial layer. Accordingly, the insulator 225 is preferably formed by an ALD method that offers favorable coverage. For example, silicon nitride or hafnium oxide deposited by an ALD method can be used for the insulator 225.

When the insulator 225 is formed in a sidewall shape in contact with the side surface of the sacrificial layer in this manner, the insulator 225 of the transistor 200a and the insulator 225 of the transistor 200b can be formed at the same time as illustrated in FIG. 46A or the like. When the two insulators 225 are formed in this manner, the distance between the two insulators 225 can be set in accordance with the size of the sacrificial layer. Thus, the distance between the insulators 225 can be shortened, and the area occupied by the transistor 200a and the transistor 200b can be reduced, leading to high integration of the semiconductor device.

Note that the insulator 225 is not limited to only an insulating material in a strict sense. For example, a metal oxide with a relatively high insulating property can also be used. For example, a metal oxide that can be used as the oxide semiconductor 230a may be used.

The upper portion of the insulator 225 may have a curved shape. Having such a curved shape can prevent formation of defects such as a void in the oxide semiconductor 230a, the oxide semiconductor 230b, the conductor 242a, and the conductor 242b in the vicinity of the upper portion of the insulator 225. Although a symmetrical structure in which the insulator 225 has a curved shape on the A3 side (A5 side) and the A4 side (A6 side) of the upper portion is employed in FIG. 47B, FIG. 49B, and the like, the present invention is not limited thereto. For example, an asymmetrical structure in which the insulator 225 has a curved shape only on the A3 side (A5 side) of the upper portion is employed in some cases.

The conductor 242a and the conductor 242b are placed apart from each other and over and in contact with the oxide semiconductor 230b. As illustrated in FIG. 49A, FIG. 49B, and the like, the conductor 242a and the conductor 242b are provided to cover the insulator 225 having a high aspect ratio. Thus, the conductor 242a and the conductor 242b are preferably formed by a film formation method that offers favorable coverage, such as an ALD method or a CVD method.

The oxide semiconductor 230 and the conductor 242b are provided to be folded in half to sandwich the insulator 225 in the vicinity of a source or a drain of the transistor 200a as illustrated in FIG. 49B. Accordingly, the conductor 242b is in contact with the oxide semiconductor 230b along the upper portion, the side surface on the A5 side, and the side surface on the A6 side of the insulator 225 in the cross-sectional view in the channel width direction. Thus, the contact area between the conductor 242b and the oxide semiconductor 230b is larger than that of the case where the insulator 225 is not provided by the side surface on the A5 side and the side surface on the A6 side of the insulator 225. Although FIG. 49B illustrates the conductor 242b and its vicinity, the same applies to the conductor 242a. That is, the contact area between the conductor 242a and the oxide semiconductor 230b increases like that between the conductor 242b and the oxide semiconductor 230b.

The increase in the contact area between the conductor 242a or the conductor 242b and the oxide semiconductor 230b enables the transistor 200 to have a high on-state current, excellent frequency characteristics, and the like without an increase in the area occupied by the transistor 200. Hence, a semiconductor device that can operate at high speed can be provided. In addition, the operation speed of a storage device including the semiconductor device can be increased. In that case, miniaturization and high integration of the semiconductor device can be achieved. It is also possible to increase the storage capacity of a storage device including the semiconductor device.

A conductive material that is less likely to be oxidized or a conductive material having a function of inhibiting diffusion of oxygen is preferably used for each of the conductor 242a and the conductor 242b since the conductor 242a and the conductor 242b are in contact with the oxide semiconductor 230b. Thus, a decrease in the conductivity of the conductor 242a and the conductor 242b can be inhibited. Oxygen can be inhibited from being extracted from the oxide semiconductor 230b, that is, an excessive amount of oxygen vacancies can be inhibited from being formed. For the conductor 242a and the conductor 242b, a material that is likely to absorb (extract) hydrogen is preferably used, in which case the hydrogen concentration in the oxide semiconductor 230 can be reduced.

As illustrated in FIG. 48C, the conductor 242a and the conductor 242b may each have a two-layer structure. The conductor 242a can be a stacked-layer film of a conductor 242a1 and a conductor 242a2 over the conductor 242a1, and the conductor 242b can be a stacked-layer film of a conductor 242b1 and a conductor 242b2 over the conductor 242b1.

Furthermore, as illustrated in FIG. 48C, an insulator 255 is preferably provided between the insulator 250 and the conductor 242a2, the conductor 242b2, the insulator 275, and the insulator 280. The insulator 255 is provided in the opening portion formed in the insulator 280 and the like, and in contact with the side surface of the insulator 280, a side surface of the insulator 275, a side surface of the conductor 242a2, a side surface of the conductor 242b2, the top surface of the conductor 242a1, and the top surface of the conductor 242b1. In other words, the insulator 255 is formed in contact with the sidewall of the opening portion formed in the insulator 280 and the like. That is, the insulator 255 can also be referred to as a sidewall insulating film.

The insulator 255 is formed in contact with the side surface of the conductor 242a2 and the side surface of the conductor 242b2, and is an inorganic insulator that protects the conductor 242a2 and the conductor 242b2. The insulator 255 is preferably an inorganic insulator that is less likely to be oxidized because it is exposed to an oxidation atmosphere. Since the insulator 255 is in contact with the conductor 242a2 and the conductor 242b2, the insulator 255 is preferably an inorganic insulator that is less likely to oxidize the conductor 242a2 and the conductor 242b2.

With the use of the insulator 255 described above, even when heat treatment is performed in an atmosphere containing oxygen after the separation into the conductor 242a1 and the conductor 242b1 and before the formation of the insulator 250, the conductor 242a2 and the conductor 242b2 can be prevented from being excessively oxidized.

Although FIG. 48C illustrates the structure in which the upper end of the insulator 255, the top surface of the insulator 280, the upper end of the insulator 250, and the upper end of the conductor 260 are aligned with each other, this embodiment is not limited thereto. The insulator 255 have a structure covering the side surface of the conductor 242a2 and the side surface of the conductor 242b2. For example, the structure in which the level of the upper end of the insulator 255 is lower than that of the top surface of the insulator 280 and higher than that of the top surface of the insulator 275 may be employed.

As illustrated in FIG. 48C, in the cross-sectional view of the transistor 200 in the channel length direction, a distance (a first distance) between the conductor 242a1 and the conductor 242b1 is smaller than a distance (a second distance) between the conductor 242a2 and the conductor 242b2. Specifically, the difference between the first distance and the second disntance is equal to twice the thickness of the insulator 255. In other words, the first distance is equal to the sum of the second distance and twice the thickness of the insulator 255. Here, the thickness of the insulator 255 corresponds to the thickness in the A1-A2 direction of at least part of the insulator 255. With such a structure, the distance between the source and the drain can be shortened, and the channel length can be accordingly shortened. Thus, the frequency characteristics of the transistor 200 can be improved. In this manner, miniaturization of the semiconductor device enables the semiconductor device to have a higher operating speed.

The conductor 240a and the conductor 240b are provided in the opening portion in the insulator 275, the insulator 280, the insulator 282, and the insulator 283. The bottom surface of the conductor 240a is in contact with the top surface of the conductor 242a, and the bottom surface of the conductor 240b is in contact with the top surface of the conductor 242b. Here, the level of the top surface of the conductor 240a and the level of the top surface of the conductor 240b are substantially the same as the level of the top surface of the insulator 283.

For the conductor 240a and the conductor 240b, a conductive material containing tungsten, copper, or aluminum as its main component is preferably used. The conductor 240a may have a stacked-layer structure in which a first conductor is provided in contact with the side surface of the insulator 241a and a second conductor is provided on the inner side of the first conductor. In that case, the above-described material can be used for the second conductor. The same applies to the conductor 240b.

In the case where the conductor 240a has a stacked-layer structure, a conductive material having a function of inhibiting passage of impurities such as water and hydrogen is preferably used for a first conductor placed in the vicinity of the insulator 283, the insulator 282, the insulator 280, and the insulator 275. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. With such a structure, impurities such as water and hydrogen contained in a layer above the insulator 283 can be inhibited from entering the oxide semiconductor 230 through the conductor 240a. The same applies to the conductor 240b.

The insulator 241a and the insulator 241b are formed in contact with the inner wall of the opening portion in the insulator 275, the insulator 280, the insulator 282, and the insulator 283. The inner side surface of the insulator 241a is in contact with the conductor 240a, and the inner side surface of the insulator 241b is in contact with the conductor 240b.

For the insulator 241a and the insulator 241b, a barrier insulating film that can be used for the insulator 275 or the like may be used. For the insulator 241a and the insulator 241b, for example, an insulator such as silicon nitride, aluminum oxide, or silicon nitride oxide may be used. With the provision of the insulator 241a and the insulator 241b, impurities such as water and hydrogen contained in the insulator 280 or the like can be inhibited from entering the oxide semiconductor 230 through the conductor 240a and the conductor 240b. In particular, silicon nitride is suitable because of its high blocking property against hydrogen. Furthermore, oxygen contained in the insulator 280 can be prevented from being absorbed by the conductor 240a and the conductor 240b.

When the insulator 241a and the insulator 241b have a stacked-layer structure illustrated in FIG. 46B, a first insulator in contact with an inner wall of the opening portion formed in the insulator 280 and the like and a second insulator on the inner side of the first insulator are preferably formed using a combination of a barrier insulating film against oxygen and a barrier insulating film against hydrogen. For example, aluminum oxide deposited by a thermal ALD method is used for the first insulator and silicon nitride deposited by a PEALD method is used for the second insulator. With this structure, oxidation of the conductor 240a and the conductor 240b can be inhibited, and hydrogen can be inhibited from entering the conductor 240a and the conductor 240b.

Although the structure in which the insulator 241a and the insulator 241b each have a stacked-layer structure of two layers is described above, the present invention is not limited thereto. For example, the insulator 241a and insulator 241b may have a single-layer structure or a stacked-layer structure of three or more layers. Although the structure in which the conductor 240a and the conductor 240b each have a stacked-layer structure of two layers is described above, the present invention is not limited thereto. For example, the conductor 240a and the conductor 240b may have a single-layer structure or a stacked-layer structure of three or more layers.

Although FIG. 49B and the like illustrate the structure in which the conductor 240b is in contact with the conductor 242b only above the upper end portion of the insulator 225, the present invention is not limited thereto. For example, as illustrated in FIG. 49C, the conductor 240b may cover the insulator 225 and the oxide semiconductor 230 and the conductor 242b that are folded in half to sandwich the insulator 225. Thus, in the cross-sectional view in the channel width direction, the conductor 240b and the conductor 242b are in contact with each other in the upper portion, the side surface on the A5 side, and the side surface on the A6 side of the insulator 225. Thus, the contact area between the conductor 240b and the conductor 242b is larger than that of the case where the insulator 225 is not provided by the side surface on the A5 side and the side surface on the A6 side of the insulator 225. Although FIG. 49C illustrates the vicinity of the conductor 240b and the conductor 242b, the same applies to the conductor 240a and the conductor 242a. That is, the contact area between the conductor 240a and the conductor 242a increases like that between the conductor 240b and the conductor 242b.

The increase in the contact area between the conductor 240a and the conductor 242a and the contact area between the conductor 240b and the conductor 242b enables the transistor 200 to have a high on-state current, excellent frequency characteristics, and the like without an increase in the area occupied by the transistor 200. Hence, a semiconductor device that can operate at high speed can be provided. In addition, the operation speed of a storage device including the semiconductor device can be increased. In that case, miniaturization and high integration of the semiconductor device can be achieved. It is also possible to increase the storage capacity of a storage device including the semiconductor device.

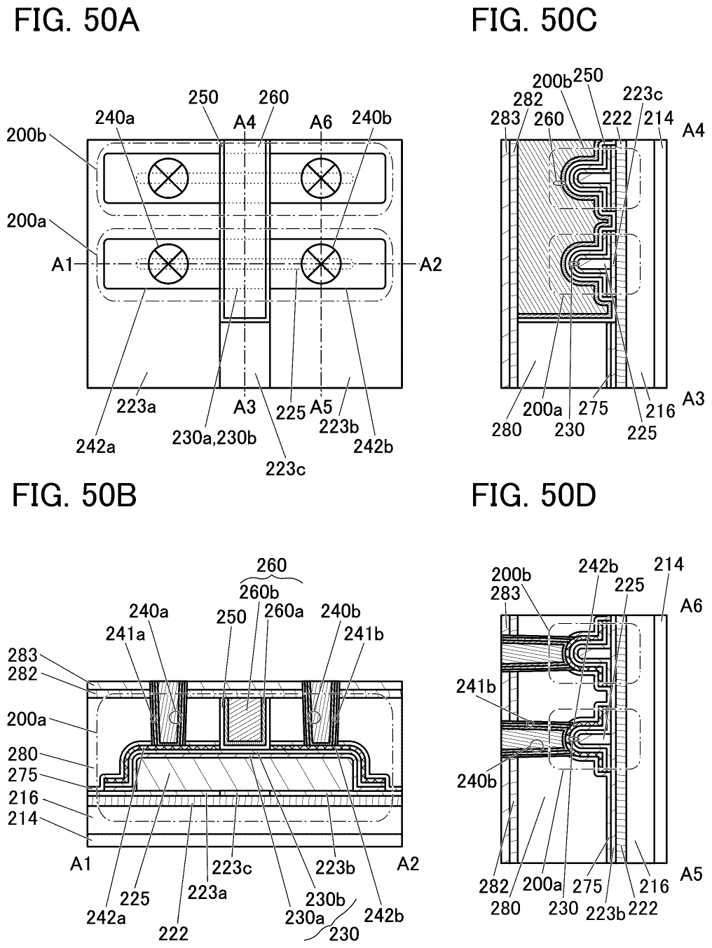

Although the structure of the insulator 223 in the semiconductor device illustrated in FIG. 46A to FIG. 46D is the same as the structure of the insulator 223 in the semiconductor device illustrated in FIG. 9A to FIG. 9D, the present invention is not limited thereto. The structure of the insulator 223 may be any of the structures of the insulator 223 described in Embodiment 1. For example, as illustrated in FIG. 50A to FIG. 50D, the insulator 223 may be the insulator 223 (the insulator 223a to the insulator 223c) illustrated in FIG. 28A to FIG. 28D.

The semiconductor device of this embodiment includes an OS transistor. Since the off-state current of the OS transistor is low, a semiconductor device or a storage device with low power consumption can be achieved. Since the OS transistors have excellent frequency characteristics, a semiconductor device or a storage device with high operating speed can be achieved. With use of the OS transistor, a semiconductor device having favorable electrical characteristics, a semiconductor device with a small variation in electrical characteristics of transistors, a semiconductor device with a high on-state current, or a highly reliable semiconductor device or storage device can be achieved.

This embodiment can be combined with the other embodiments as appropriate. In this specification, in the case where a plurality of structure examples are shown in one embodiment, the structure examples can be combined as appropriate.

### Embodiment 3

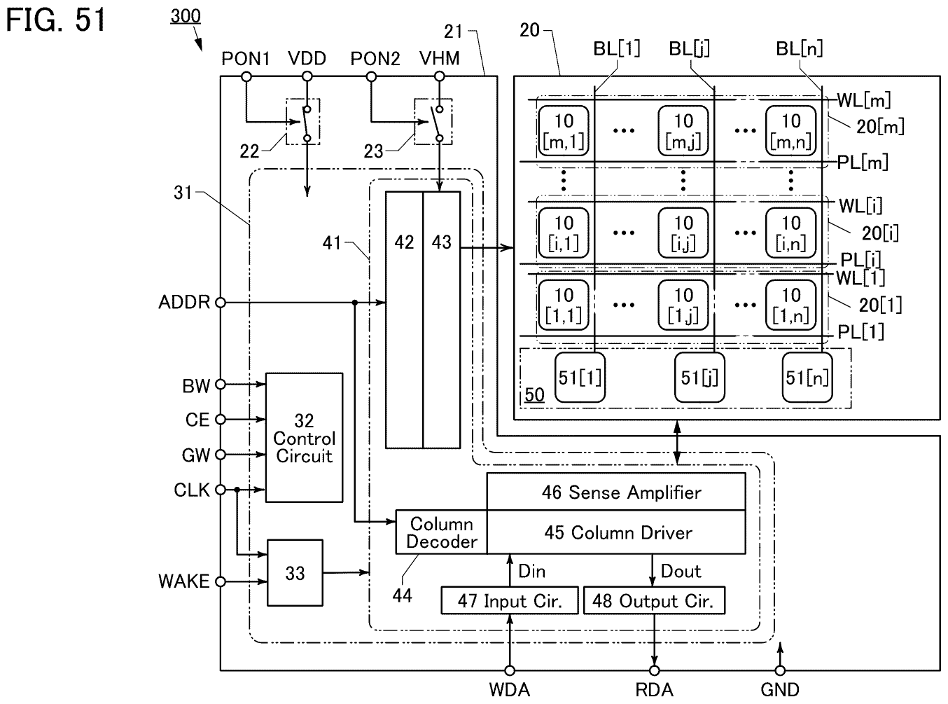

In this embodiment, a storage device using the transistor of one embodiment of the present invention will be described with reference to FIG. 51 to FIG. 57.

In this embodiment, a structure example of a storage device using a memory cell including the transistor described in the above embodiment will be described. In this embodiment, a structure example of a storage device provided with stacked layers including memory cells and a layer including a functional circuit having functions of amplifying and outputting a data potential retained in a memory cell will be described.

### Structure Example of Storage Device

FIG. 51 is a block diagram of the storage device of one embodiment of the present invention.

A storage device 300 illustrated in FIG. 51 includes a driver circuit 21 and a memory array 20. The memory array 20 includes a plurality of memory cells 10 and a functional layer 50 including a plurality of functional circuits 51.

FIG. 51 illustrates an example in which the memory array 20 includes the plurality of memory cells 10 arranged in a matrix of m rows and n columns (each of m and n is independently an integer greater than or equal to 2). In the example illustrated in FIG. 51, the functional circuit 51 is provided for each wiring BL functioning as a bit line, and the functional layer 50 includes the plurality of functional circuits 51 that are provided to correspond to n wirings BL.

In FIG. 51, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is denoted as a memory cell 10[i,j]. Note that in this embodiment and the like, “i+α” (α is a positive or negative integer) is not below 1 and does not exceed m. Similarly, “j+α” is not below 1 and does not exceed n.

The memory array 20 includes m wirings WL extending in the row direction, m wirings PL extending in the row direction, and the n wirings BL extending in the column direction. In this embodiment and the like, a first wiring WL (provided in the first row) is denoted as a wiring WL[1], and an m-th wiring WL (provided in the m-th row) is denoted as a wiring WL[m]. Similarly, a first wiring PL (provided in the first row) is denoted as a wiring PL[1], and an m-th wiring PL (provided in the m-th row) is denoted as a wiring PL[m]. Similarly, a first wiring BL (provided in the first column) is denoted as a wiring BL[1], and an n-th wiring BL (provided in the n-th column) is denoted as a wiring BL[n].

A plurality of the memory cells 10 provided in the i-th row are electrically connected to the wiring WL in the i-th row (wiring WL[i]) and the wiring PL in the i-th row (wiring PL[i]). A plurality of the memory cells 10 provided in the j-th column are electrically connected to the wiring BL in the j-th column (wiring BL[j]).

A DOSRAM (registered trademark) (Dynamic Oxide Semiconductor Random Access Memory) can be used for the memory array 20. A DOSRAM is a RAM including a 1T (transistor) 1C (capacitor) memory cell and refers to a memory in which an access transistor is an OS transistor. A current flowing between a source and a drain in an off state, that is, a leakage current, is extremely low in an OS transistor. A DOSRAM can retain charges corresponding to data stored in a capacitor for a long time by turning off an access transistor (by bringing the access transistor into a non-conducting state). For this reason, the refresh operation frequency of a DOSRAM can be lower than that of a DRAM formed with a transistor containing silicon in its channel formation region (a Si transistor). As a result, power consumption can be reduced. The OS transistor also has excellent frequency characteristics and thus enables high-speed reading and writing of the storage device. Hence, a storage device that can operate at high speed can be provided.

In the memory array 20 illustrated in FIG. 51, a plurality of memory arrays 20[1] to 20[m] can be stacked. When the memory arrays 20[1] to 20[m] included in the memory array 20 are placed in the direction perpendicular to the surface of a substrate provided with the driver circuit 21, the memory density of the memory cells 10 can be increased.

The wiring BL functions as a bit line for writing and reading data. The wiring WL functions as a word line for controlling the on and off states (conduction and non-conduction states) of the access transistor serving as a switch. The wiring PL has a function of a constant potential line connected to a capacitor and a function of supplying a back gate potential to a back gate of an OS transistor serving as the access transistor.

The memory cell 10 included in each of the memory arrays 20[1] to 20[m] is connected to the functional circuit 51 through the wiring BL. The wiring BL can be placed in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced; thus, power consumption and signal delays can be reduced. Moreover, even when the capacitance of the capacitors included in the memory cells 10 is reduced, the storage device can be made to operate.

The functional circuit 51 has functions of amplifying a data potential retained in the memory cell 10 and outputting the amplified data potential to a sense amplifier 46 included in the driver circuit 21 through a later-described wiring GBL (not illustrated). With this structure, a slight difference in the potential of the wiring BL can be amplified at the time of data reading. Like the wiring BL, the wiring GBL can be placed in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced; thus, power consumption and signal delays can be reduced.

Note that the wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductor provided in contact with the region functioning as the source or the drain in the semiconductor layer of the transistor included in the memory cell 10. That is, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, resistance and parasitic capacitance between the driver circuit 21 and the memory array 20 are reduced, so that power consumption and signal delays can be reduced. In addition, the storage device 300 can be downsized.

The functional circuit 51 can be placed at any desired position, e.g., over a circuit that is formed using Si transistors in a manner similar to that of the memory arrays 20[1] to 20[m] when being formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized; hence, the storage device 300 can be downsized.

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the storage device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 300. For example, the control circuit performs a logical operation on the signal CE, the signal GW, and the signal BW to determine an operation mode (e.g., a writing operation or a reading operation) of the storage device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for performing writing and reading of data to/from the memory cells 10. Moreover, the peripheral circuit 41 is a circuit that outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the storage device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 300, a high power supply voltage is VDD and a low power supply voltage is GND (a ground potential). In addition, VHM is a high power supply voltage used to set the word line at high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 51 but can be more than one. In such a case, a power switch is provided for each power domain.

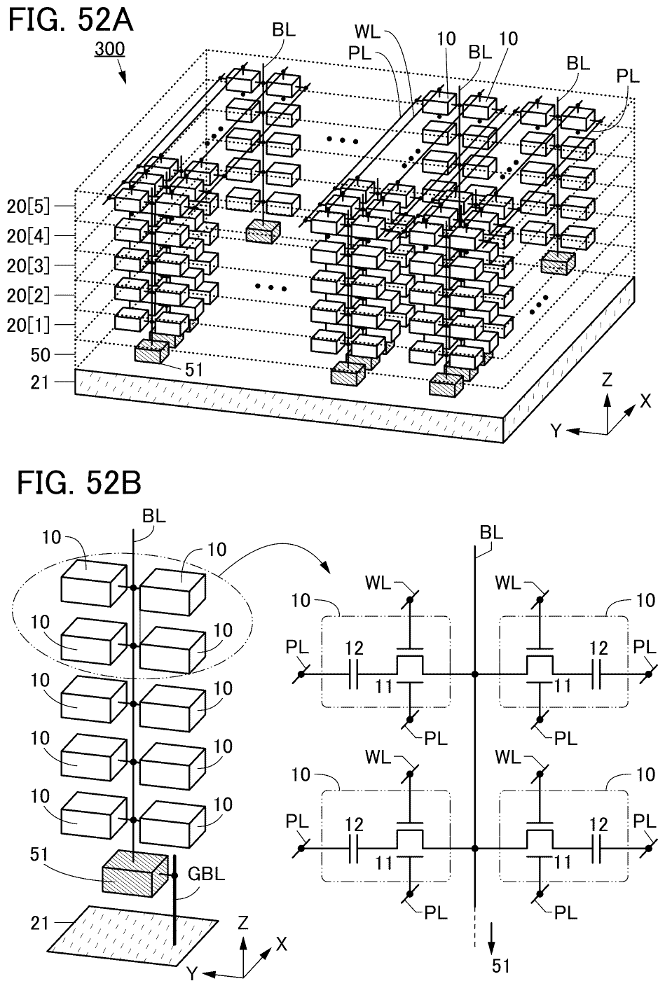

In the memory array 20 including the memory arrays 20[1] to 20[m] (m is an integer greater than or equal to 2) and the functional layer 50, the plurality of layers of memory arrays 20 can be stacked over the driver circuit 21. Stacking the plurality of layers of memory arrays 20 can increase the memory density of the memory cells 10. FIG. 52A is a perspective view of the storage device 300 that includes the functional layer 50 and five layers (m=5) of memory arrays 20[1] to 20[5], which overlap with each other, over the driver circuit 21.

In FIG. 52A, the memory array 20 provided in the first layer is denoted as a memory array 20[1], the memory array 20 provided in the second layer is denoted as a memory array 20[2], and the memory array 20 provided in the fifth layer is denoted as a memory array 20[5]. FIG. 52A also illustrates the wiring WL and the wiring PL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not illustrated.

FIG. 52B is a schematic view for describing a structure example of the functional circuit 51, which is connected to the wiring BL, and the memory cells 10 included in the memory arrays 20[1] to 20[5], which are connected to the wiring BL, illustrated in FIG. 52A. FIG. 52B illustrates the wiring GBL provided between the functional circuit 51 and the driver circuit 21. Note that a structure in which a plurality of memory cells (memory cells 10) are electrically connected to one wiring BL is also referred to as “memory string”. In the drawings, the wiring GBL is sometimes represented by a bold line for higher visibility.

FIG. 52B illustrates an example of a circuit structure of the memory cell 10 connected to the wiring BL. The memory cell 10 includes a transistor 11 and a capacitor 12. As for the transistor 11, the capacitor 12, and the wirings (e.g., the wiring BL and the wiring WL), for example, the wiring BL[1] and the wiring WL[1] are referred to as the wiring BL and the wiring WL in some cases. Here, the transistor 11 corresponds to the transistor 200 or the transistor 200A described above. Note that although the transistor 11 illustrated in FIG. 52B includes a back gate, the transistor 11 does not necessarily include the back gate in some cases.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL. A back gate of the transistor 11 is connected to the wiring PL.

The wiring PL is a wiring for supplying a constant potential for retaining the potential of the capacitor 12. The wiring PL can also be regarded as a wiring for supplying a constant potential for controlling the threshold voltage of the transistor 11. For example, when GND (a ground potential) is supplied to the wiring PL, the stacked memory cells 10 can be electrically insulated from each other. In addition, when the wiring PL serves also as the back gate electrode of the transistor 11, the off-state current can be sufficiently reduced.

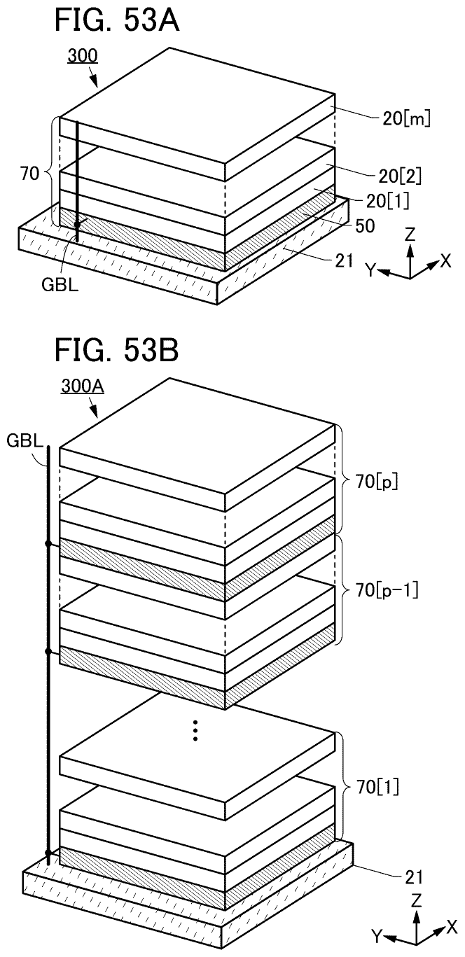

The wiring GBL illustrated in FIG. 52B is provided to electrically connect the driver circuit 21 and the functional layer 50. FIG. 53A is a schematic view of the storage device 300 in which the functional circuit 51 and the memory arrays 20[1] to 20[m] are regarded as a repeating unit 70. Although FIG. 53A illustrates one wiring GBL, the wiring GBL is provided as appropriate depending on the number of functional circuits 51 provided in the functional layer 50.

Note that the wiring GBL is provided in contact with a semiconductor layer of the transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. That is, the wiring GBL is a wiring for electrically connecting one of the source and the drain of the transistor included in the functional circuit 51 in the functional layer 50 to the driver circuit 21 in the perpendicular direction.

The repeating unit 70 including the functional circuit 51 and the memory arrays 20[1] to 20[m] may have a stacked-layer structure. A storage device 300A of one embodiment of the present invention can include repeating units 70[1] to 70[p] (p is an integer greater than or equal to 2) as illustrated in FIG. 53B. The wiring GBL is connected to the functional layers 50 included in the repeating units 70. The wiring GBL is provided as appropriate depending on the number of functional circuits 51.

In one embodiment of the present invention, OS transistors are provided in stacked layers and a wiring functioning as a bit line is placed in the direction perpendicular to the surface of the substrate provided with the driver circuit 21. Since the wiring that is provided to extend from the memory array 20 and functions as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the storage device 300 can be downsized. Moreover, even when the capacitance of the capacitors 12 included in the memory cells 10 is reduced, the storage device 300 can be made to operate.

Although the storage device including the memory arrays 20[1] to 20[m] is described above, the semiconductor device of the present invention can also be used for a single-layer storage device including only the memory array 20[1].

### Structure Example of Memory Array 20 and Functional Circuit 51

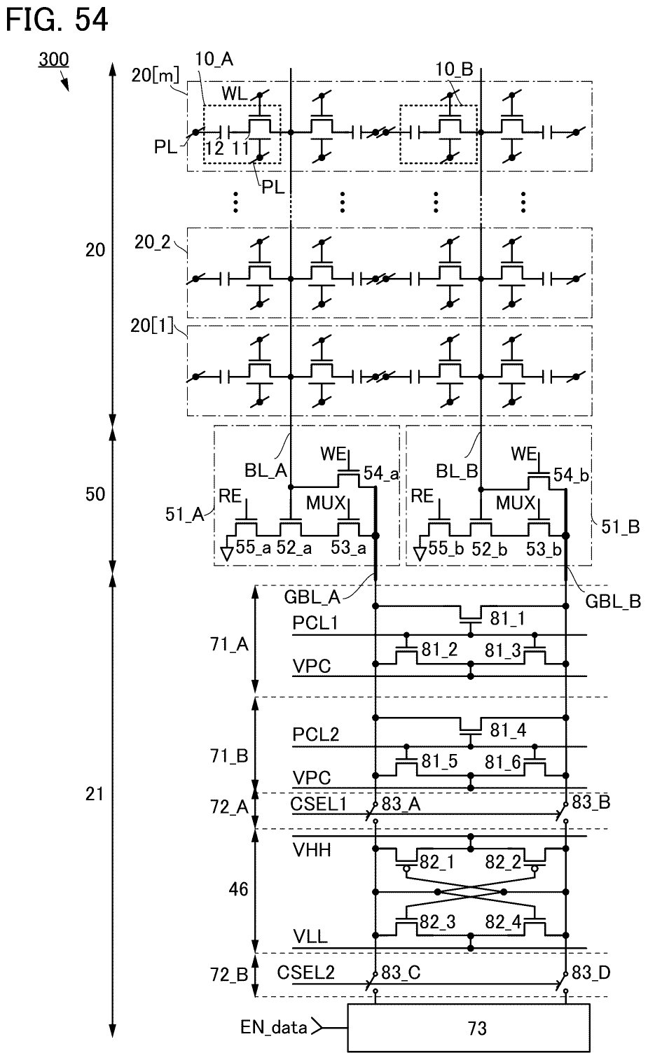

A structure example of the functional circuit 51 and structure examples of the memory array 20 and the sense amplifier 46 included in the driver circuit 21, which are described with reference to FIG. 51 to FIG. 53, are described with reference to FIG. 54. FIG. 54 illustrates the driver circuit 21 connected to the wirings GBL (a wiring GBL_A and a wiring GBL_B) connected to the functional circuits 51 (a functional circuit 51_A and a functional circuit 51_B) connected to the memory cells 10 (a memory cell 10_A and a memory cell 10_B) connected to different wirings BL (a wiring BL_A and a wiring BL_B). FIG. 54 also illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuits 51_A and 51_B, transistors 52_a, 52_b, 53_a, 53_b, 54_a, 54_b, 55_a, and 55_b are illustrated. The transistors 52_a, 52_b, 53_a, 53_b, 54_a, 54_b, 55_a, and 55_b illustrated in FIG. 54 are OS transistors like the transistor 11 included in the memory cell 10. The functional layer 50 including the functional circuits 51 can be provided in layers stacked like the memory arrays 20[1] to 20[m].

The wiring BL_A is connected to a gate of the transistor 52_a, and the wiring BL_B is connected to a gate of the transistor 52_b. One of a source and a drain of each of the transistors 53_a and 54_a is connected to the wiring GBL_A. One of a source and a drain of each of the transistors 53_b and 54_b is connected to the wiring GBL_B. The wirings GBL_A and GBL_B are provided in the perpendicular direction like the wirings BL_A and BL_B and connected to transistors included in the driver circuit 21. As illustrated in FIG. 54, a selection signal MUX, a control signal WE, or a control signal RE is supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 54 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to 81_3. The precharge circuit 71_A is a circuit for precharging the wiring BL_A and the wiring BL_B with an intermediate potential VPC corresponding to a potential VDD/2 between a high power supply potential (VDD) and a low power supply potential (VSS) in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistors 82_1 and 82_2 and the n-channel transistors 82_3 and 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged are changed by selecting the memory cells 10_A and 10_B, and the potentials of the wiring GBL_A and the wiring GBL_B are set to VDD or VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The on and off states of the switch circuit 72_A are switched under the control of a switch signal CSEL1. In the case where the switches 83_A and 83_B are n-channel transistors, the switches 83_A and 83_B are turned on and off when the switch signal CSEL1 is at high level and low level, respectively. The switch circuit 72_B is a circuit for controlling electrical continuity between the write/read circuit 73 and the bit line pair connected to the sense amplifier 46. The on and off states of the switch circuit 72_B are switched under the control of a switching signal CSEL2. The switches 83_C and 83_D may operate in a manner similar to those of the switches 83_A and 83_B.

As illustrated in FIG. 54, the storage device 300 can have a structure where the memory cell 10, the functional circuit 51, and the sense amplifier 46 are connected to each other in the shortest distance through the wiring BL and the wiring GBL provided in the perpendicular direction. Even with addition of the functional layer 50 including transistors included in the functional circuits 51, the loads of the wirings BL are reduced, whereby the writing time can be shortened and data reading can be facilitated.

As illustrated in FIG. 54, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can each function as a sense amplifier that consists of OS transistors. With this structure, a slight difference in the potential of the wiring BL can be amplified at the time of reading to drive the sense amplifier 46 formed using Si transistors.

### Structure Example of Memory Cell

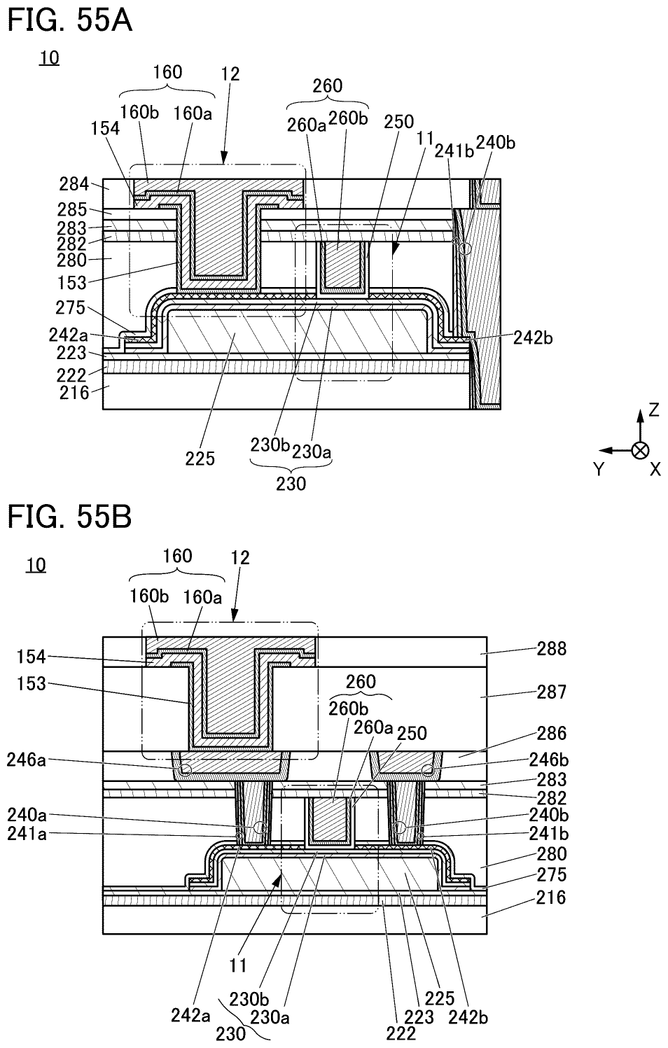

A structure example of the memory cell 10 used in the above-described storage device will be described with reference to FIG. 55A.

Note that in FIG. 55A, the X direction is parallel to the channel length direction of an illustrated transistor, the Y direction is perpendicular to the X direction, and the Z direction is perpendicular to the X direction and the Y direction.

As illustrated in FIG. 55A, the memory cell 10 includes the transistor 11 and the capacitor 12. An insulator 285 is provided over the transistor 11, and an insulator 284 is provided over the insulator 285. An insulator that can be used for the insulator 216 can be used for the insulator 285 and the insulator 284. Note that the transistor 11 has the same structure as the transistor 200 or the transistor 200A described in the above embodiment, and the same components are denoted by the same reference numerals. The above embodiment can be referred to for the details of the transistor 200 and the transistor 200A. The conductor 240b is provided in contact with one of the source electrode and the drain electrode of the transistor 11 (the conductor 242b). The conductor 240b is provided to extend in the Z direction and functions as the wiring BL.

The capacitor 12 includes a conductor 153 over the conductor 242a, an insulator 154 over the conductor 153, and a conductor 160 (a conductor 160a and a conductor 160b) over the insulator 154.

At least parts of the conductor 153, the insulator 154, and the conductor 160 are positioned in an opening portion provided in the insulator 275, the insulator 280, the insulator 282, the insulator 283, and the insulator 285. The end portions of the conductor 153, the insulator 154, and the conductor 160 are positioned at least over the insulator 282, and preferably positioned over the insulator 285. The insulator 154 is provided to cover the end portion of the conductor 153. This enables the conductor 153 and the conductor 160 to be electrically insulated from each other.

The deeper the opening portion provided in the insulator 275, the insulator 280, the insulator 282, the insulator 283, and the insulator 285 is (i.e., the larger the thickness of one or more of the insulator 275, the insulator 280, the insulator 282, the insulator 283, and the insulator 285 is), the larger the electrostatic capacitance of the capacitor 12 can be. Increasing the electrostatic capacitance per unit area of the capacitor 12 can achieve miniaturization or higher integration of the storage device.

The conductor 153 includes a region functioning as one electrode (a lower electrode) of the capacitor 12. The insulator 154 includes a region functioning as a dielectric of the capacitor 12. The conductor 160 includes a region functioning as the other electrode (an upper electrode) of the capacitor 12. An upper portion of the conductor 260 can be extended to function as the wiring PL illustrated in FIG. 52A and FIG. 52B. The capacitor 12 forms a MIM (Metal-Insulator-Metal) capacitor.

The conductor 242a provided to be over and overlap with the oxide semiconductor 230 functions as an electrode electrically connected to the conductor 153 of the capacitor 12.

Each of the conductor 153 and the conductor 160 included in the capacitor 12 can be formed using any of a variety of conductors that can be used for the conductor 215 and the conductor 260. The conductor 153 and the conductor 160 are each preferably formed by a film formation method that offers excellent coverage, such as an ALD method or a CVD method. For example, titanium nitride or tantalum nitride deposited by an ALD method or a CVD method can be used for the conductor 153.

The top surface of the conductor 242a is in contact with the bottom surface of the conductor 153. Here, the use of a conductive material with favorable conductivity for the conductor 242a can reduce the contact resistance between the conductor 153 and the conductor 242a.

Titanium nitride deposited by an ALD method or a CVD method can be used for the conductor 160a, and tungsten deposited by a CVD method can be used for the conductor 160b. Note that in the case where the adhesion of tungsten to the insulator 154 is sufficiently high, a single-layer structure of tungsten deposited by a CVD method may be used for the conductor 160.

The insulator 154 included in the capacitor 12 is preferably formed using a material with a high relative permittivity (high-k material) described in the above embodiment. Using such a high-k material allows the insulator 154 to be thick enough to inhibit a leakage current and the capacitor 12 to have sufficiently large capacitance. The insulator 154 is preferably formed by a film formation method that offers excellent coverage, such as an ALD method or a CVD method.

It is preferable to use stacked insulators formed of any of the above materials, and it is preferable to use a stacked-layer structure of a material with a high relative permittivity (a high-k material) and a material having higher dielectric strength than the material with high a relative permittivity (a high-k material). As the insulator 154, an insulator in which zirconium oxide, aluminum oxide, and zirconium oxide are stacked in this order can be used, for example. As another example, an insulator in which zirconium oxide, aluminum oxide, zirconium oxide, and aluminum oxide are stacked in this order can be used. Alternatively, an insulating film in which hafnium zirconium oxide, aluminum oxide, hafnium zirconium oxide, and aluminum oxide are stacked in this order can be used, for example. The stacking of such an insulator having relatively high dielectric strength, such as aluminum oxide, can increase the dielectric strength and inhibit electrostatic breakdown of the capacitor 12.

Alternatively, a material that can have ferroelectricity may be used for the insulator 154. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of the number of hafnium atoms to the number of atoms of the element J1 can be set as appropriate; the atomic ratio of the number of hafnium atoms to the number of atoms of the element J1 is, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of the number of zirconium atoms to the number of atoms of the element J2 can be set as appropriate; the atomic ratio of the number of zirconium atoms to the number of atoms of the element J2 is, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a κ-alumina-type structure, and the like.

Note that although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 154 can have a stacked-layer structure of a plurality of materials selected from the above-listed materials. Note that the crystal structures (properties) of the above-listed materials and the like can be changed depending on the processes as well as the film formation conditions; thus, a material that exhibits ferroelectricity is referred to not only as a ferroelectric but also as a material that can have ferroelectricity in this specification and the like.

The ferroelectric is an insulator having a property of causing internal polarization by application of an electric field from the outside and maintaining the polarization even after the electric field is made zero. Thus, with the use of a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 12, the storage device described in this embodiment functions as a ferroelectric memory.

The deeper the opening portion provided in the insulator 275, the insulator 280, the insulator 282, the insulator 283, and the insulator 285 is (i.e., the larger the thickness of one or more of the insulator 275, the insulator 280, the insulator 282, the insulator 283, and the insulator 285 is), the larger the electrostatic capacitance of the capacitor 12 can be. Here, since the insulator 275, the insulator 282, and the insulator 283 function as barrier insulators, their thicknesses are preferably set in accordance with a barrier property required for the semiconductor device. The thickness of the conductor 260 functioning as a gate electrode depends on the thickness of the insulator 280; thus, the thickness of the insulator 280 is preferably set in accordance with the thickness of the conductor 260 required for the semiconductor device.

Accordingly, the electrostatic capacitance of the capacitor 12 is preferably set by adjusting the thickness of the insulator 285. For example, the thickness of the insulator 285 is set within the range from 50 nm to 250 nm inclusive, and the depth of the opening portion is approximately greater than or equal to 150 nm and less than or equal to 350 nm. When the capacitor 12 is formed within the above range, the capacitor 12 can have adequate electrostatic capacitance, and the height of one layer can be prevented from being excessively large in a semiconductor device in which a plurality of memory cell layers are stacked. Note that capacitors provided in memory cells may have different electrostatic capacitances between the plurality of memory cell layers. In this structure, the thicknesses of the insulators 285 provided in the memory cell layers vary, for example.

Note that the sidewall of an opening portion in which the capacitor 12 is placed and which is provided in the insulator 285 and the like may be substantially perpendicular to the top surface of the insulator 222 or may be tapered. The tapered shape of the sidewall can improve the coverage with the conductor 153 and the like provided in the opening portion in the insulator 285 and the like; as a result, defects such as voids can be reduced.

The conductor 242b provided to be over and overlap with the oxide semiconductor 230 functions as a wiring electrically connected to the conductor 240b. In FIG. 55A, for example, the top surface and a side end portion of the conductor 242b are electrically connected to the conductor 240b extending in the Z direction. Specifically, in FIG. 55A, the top surface and the side end portion of the conductor 242b are in contact with the conductor 240b.

When the conductor 240b is in direct contact with at least one of the top surface and the side end portion of the conductor 242b, an electrode for connection does not need to be provided additionally, so that the area occupied by the memory arrays can be reduced. In addition, the integration degree of the memory cells is increased, and the storage capacity of the storage device can be increased. Note that the conductor 240b is preferably in contact with the side end portion and part of the top surface of the conductor 242b. When the conductor 240b is in contact with a plurality of surfaces of the conductor 242b, the contact resistance between the conductor 240b and the conductor 242b can be reduced.

The conductor 240b is provided in an opening formed in the insulator 216, the insulator 222, the insulator 223, the insulator 275, the insulator 280, the insulator 282, the insulator 283, the insulator 285, and the insulator 284.

As illustrated in FIG. 55A, the insulator 241b is preferably provided in contact with a side surface of the conductor 240b. Specifically, the insulator 241b is provided in contact with the inner wall of an opening portion in the insulator 216, the insulator 222, the insulator 223, the insulator 275, the insulator 280, the insulator 282, the insulator 283, the insulator 285, and the insulator 284. The insulator 241a and the insulator 241b is formed also along the side surface of the oxide semiconductor 230 that is formed to protrude in the opening portion. Here, at least part of the conductor 242b is exposed from the insulator 241b and is in contact with the conductor 240b. That is, the conductor 240b is provided to fill the opening portion with the insulator 241b therebetween.

As illustrated in FIG. 55A, the uppermost portion of the insulator 241b formed below the conductor 242b is preferably positioned below the top surface of the conductor 242b. With this structure, the conductor 240b can be in contact with at least part of the side end portion of the conductor 242b. Note that the insulator 241b formed below the conductor 242b preferably includes a region in contact with the side surface of the oxide semiconductor 230. With this structure, impurities such as water or hydrogen contained in the insulator 280 and the like can be inhibited from entering the oxide semiconductor 230 through the conductor 240b.

Note that the sidewall of the opening portion in which the conductor 240b and the insulator 241b are placed may be perpendicular or substantially perpendicular to the top surface of the insulator 222 or may have a tapered shape. The tapered sidewall can improve the coverage with the insulator 241b and the like provided in the opening portion.

Although the conductor 153 of the capacitor 12 is in contact with the conductor 242a of the transistor 11 in the memory cell 10 illustrated in FIG. 55A, the present invention is not limited thereto. For example, as illustrated in FIG. 55B, a structure may be employed in which the conductor 240a is provided in the transistor 11 and the capacitor 12 is provided thereover.

In the memory cell 10 illustrated in FIG. 55B, an insulator 286 can be provided over the insulator 283, an insulator 287 can be provided over the insulator 286, and an insulator 288 can be provided over the insulator 287. As the insulator 286, the insulator 287, and the insulator 288, the insulator that can be used as the insulator 284 can be used. A conductor 246a and a conductor 246b are provided to be embedded in the insulator 286. The conductor 246a and the conductor 246b function as wirings or electrodes and are formed using the conductor that can be used for the conductor 215. The capacitor 12 is provided to be embedded in the insulator 287 and the insulator 288. The capacitor 12 illustrated in FIG. 55B has a structure similar to that in FIG. 55A. Like the transistor 200 illustrated in FIG. 46B and the like, the transistor 11 illustrated in FIG. 55B includes the conductor 240a, the conductor 240b, the insulator 241a, and the insulator 241b that are embedded in the insulator 280 and the like.

As illustrated in FIG. 55B, the conductor 240a is in contact with the conductor 242a, the conductor 246a is in contact with the conductor 240a, and the conductor 153 is in contact with the conductor 246a. Thus, the conductor 153, which is the lower electrode of the capacitor 12, is electrically connected to the conductor 242a, which is one of the source and the drain of the transistor 11, through the conductor 246a and the conductor 240a.

As illustrated in FIG. 55B, the conductor 240b is in contact with the conductor 242b, and the conductor 246b is in contact with the conductor 240b. Here, when the conductor 246b is led in the same layer, the conductor 246b can function as the wiring BL. In this case, the memory cells 10 illustrated in FIG. 55B are provided in the same layer in a matrix to form a memory array. Without limitation to this, the conductor 246b may be provided to extend in the Z direction like the conductor 240b illustrated in FIG. 55A.

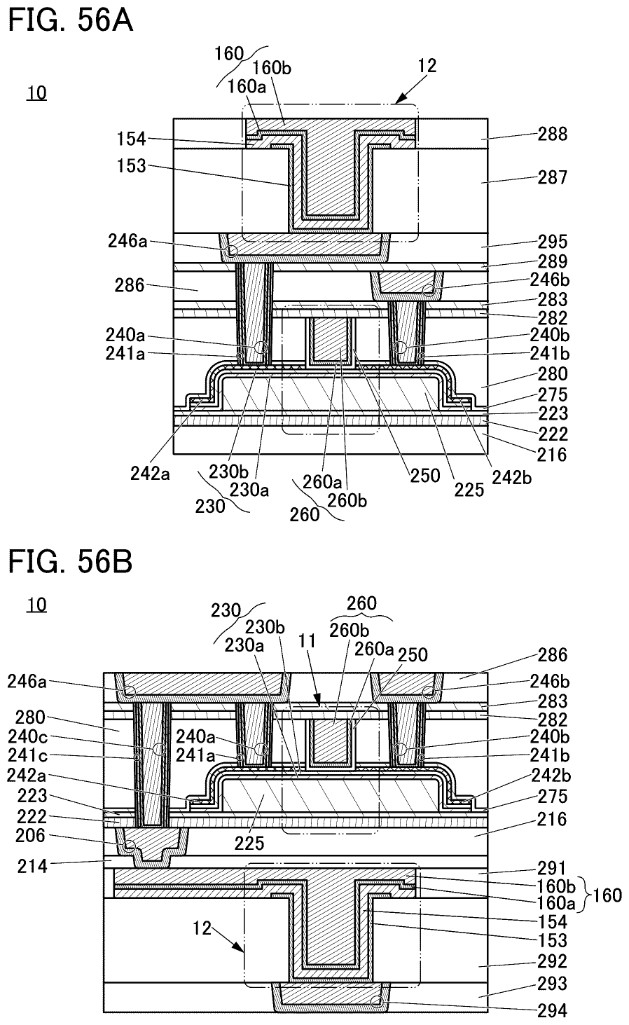

Although the conductor 246a and the conductor 246b are formed in the same layer in the memory cell 10 illustrated in FIG. 55B, the present invention is not limited thereto. For example, as illustrated in FIG. 56A, the conductor 246a may be provided in a layer above the conductor 246b.

In the memory cell 10 illustrated in FIG. 56A, an insulator 289 can be provided over the insulator 286, and an insulator 295 can be provided over the insulator 289. The insulator that can be used as the insulator 283 can be used as the insulator 289, and the insulator that can be used as the insulator 284 can be used as the insulator 295. The conductor 246a is provided to be embedded in the insulator 295.

With the above structure, the conductor 246a can be placed to be over and overlap with the transistor 11 without interference with the conductor 246b. Thus, the capacitor 12 provided over the conductor 246a can be placed to be over and overlap with the transistor 11. Here, at least part of the capacitor 12, for example, a portion where the conductor 153, the insulator 154, and the conductor 160 overlap with each other preferably overlaps with the oxide semiconductor 230 and the conductor 260. With such a structure, the memory cell 10 including the transistor 11 and the capacitor 12 can be provided without a significant increase in the occupation area. This results in an increase in the storage capacity per unit area of the storage device.

Note that the insulator 289 preferably functions as an etching stopper when the conductor 246a is formed. With such a structure, even when part of the conductor 246a overlaps with the conductor 246b, the part of the conductor 246a can be prevented from being in contact with the conductor 246b.

Although the capacitor 12 is provided over the transistor 11 in the memory cell 10 illustrated in FIG. 55A, the present invention is not limited thereto. For example, as illustrated in FIG. 56B, the capacitor 12 may be provided below the transistor 11.

In the memory cell 10 illustrated in FIG. 56B, the insulator 214 can be provided below the insulator 216 as in FIG. 46B, an insulator 291 can be provided below the insulator 214, an insulator 292 can be provided below the insulator 291, and an insulator 293 can be provided below the insulator 292. As the insulator 291, the insulator 292, and the insulator 293, the insulator that can be used for the insulator 284 can be used. A conductor 294 is provided to be embedded in the insulator 293. The conductor 294 functions as a wiring or an electrode and is formed using the conductor that can be used for the conductor 215. The capacitor 12 is provided to be embedded in the insulator 291 and the insulator 292. The capacitor 12 illustrated in FIG. 56B has a structure similar to that in FIG. 55A. In addition, a conductor 206 is provided so as to be embedded in the insulator 214 and the insulator 216. A conductor 240c and an insulator 241c are provided so as to be embedded in the insulator 222, the insulator 223, the insulator 275, the insulator 280, the insulator 282, and the insulator 283. The conductor 240c can be formed in the same step as the conductor 240a and the conductor 240b, and the insulator 241c can be formed in the same step as the insulator 241a and the insulator 241b.

As illustrated in FIG. 56B, the conductor 240a is in contact with the conductor 242a, the conductor 246a is in contact with the conductor 240a, the conductor 240c is in contact with the conductor 246a, the conductor 206 is in contact with the conductor 240c, and the conductor 160 is in contact with the conductor 206. Thus, the conductor 160, which is the upper electrode of the capacitor 12, is electrically connected to the conductor 242a, which is the one of the source and the drain of the transistor 11, through the conductor 206, the conductor 240c, the conductor 246a, and the conductor 240a.

As illustrated in FIG. 56B, the conductor 294 is in contact with the conductor 153. Here, the conductor 153 can function as the wiring PL.

With the above structure, the capacitor 12 can be placed to be below and overlap with the transistor 11 to overlap with the transistor 11. Here, at least part of the capacitor 12, for example, a portion where the conductor 153, the insulator 154, and the conductor 160 overlap with each other preferably overlaps with the oxide semiconductor 230 and the conductor 260. With such a structure, the memory cell 10 including the transistor 11 and the capacitor 12 can be provided without a significant increase in the occupation area. This results in an increase in the storage capacity per unit area of the storage device.

### Structure Example of Storage Device 300

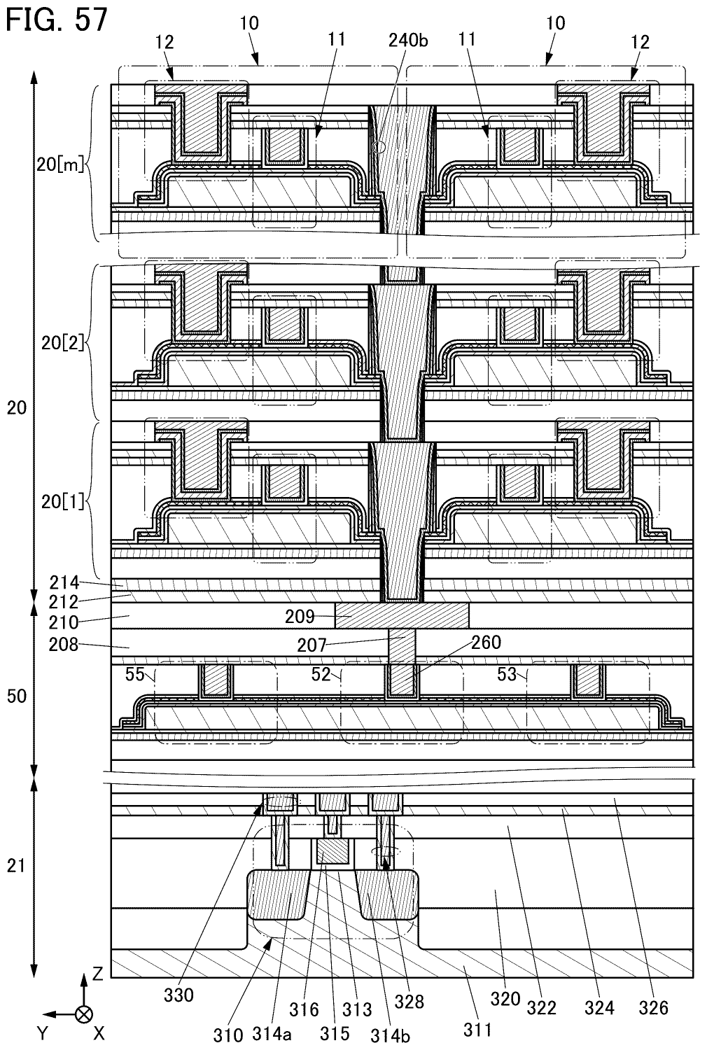

A structure example of the storage device 300 will be described with reference to FIG. 57.

The storage device 300 includes the driver circuit 21 that is a layer including a transistor 310 and the like, the functional layer 50 that is over the driver circuit 21 and is a layer including transistors 52, 53, 54, and 55 and the like, and the memory arrays 20[1] to 20[m] over the functional layer 50. Note that the transistor 52 corresponds to the transistors 52_a and 52_b, the transistor 53 corresponds to the transistors 53_a and 53_b, the transistor 54 corresponds to the transistors 54_a and 54_b, and the transistor 55 corresponds to the transistors 55_a and 55_b.

FIG. 57 illustrates the transistor 310 included in the driver circuit 21 as an example. The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 310 can be a p-channel transistor or an n-channel transistor. As the substrate 311, a single crystal silicon substrate can be used, for example.

Here, in the transistor 310 illustrated in FIG. 57, the semiconductor region 313 (part of the substrate 311) in which a channel is formed has a protruding shape. Furthermore, the conductor 316 is provided to cover the side surface and top surface of the semiconductor region 313 with the insulator 315 therebetween. Note that the conductor 316 may be formed using a material for adjusting the work function. The transistor 310 is also referred to as a FIN-type transistor because it utilizes a protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI (Silicon on Insulator) substrate.

Note that the transistor 310 illustrated in FIG. 57 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 310 as an interlayer film. A conductor 328 and the like are embedded in the insulator 320 and the insulator 322. A conductor 330 or the like is embedded in the insulator 324 and the insulator 326. Note that the conductor 328 and the conductor 330 function as a contact plug or a wiring.

The insulator functioning as an interlayer film may function as a planarization film that covers an uneven shape thereunder. For example, the top surface of the insulator 322 may be planarized by planarization treatment using a chemical mechanical polishing (CMP) method or the like to have improved planarity.

FIG. 57 illustrates the transistors 52, 53, and 55 included in the functional layer 50 as an example. Each of the transistors 52, 53, and 55 has the same structure as the transistor 11 included in the memory cell 10. Sources and drains of the transistors 52, 53, and 55 are connected in series.

An insulator 208 is provided over the transistors 52, 53, and 55, and a conductor 207 is provided in an opening formed in the insulator 208. Furthermore, an insulator 210 is provided over the insulator 208, and a conductor 209 is provided in an opening formed in the insulator 210. Moreover, an insulator 212 is provided over the insulator 210, and an insulator 214 is provided over the insulator 212. Part of the conductor 240b provided in the memory array 20[1] is embedded in an opening formed in the insulator 212 and the insulator 214. Here, for the insulator 208 and the insulator 210, the insulator that can be used for the insulator 216 can be used. For the insulator 212, the insulator that can be used for the insulator 283 can be used. For the insulator 214, the insulator that can be used for the insulator 282 can be used.

The bottom surface of the conductor 207 is provided in contact with the top surface of the conductor 260 of the transistor 52. The top surface of the conductor 207 is provided in contact with the bottom surface of the conductor 209. The top surface of the conductor 209 is provided in contact with the bottom surface of the conductor 240b provided in the memory array 20[1]. With such a structure, the conductor 240b corresponding to the wiring BL and the gate of the transistor 52 can be electrically connected to each other.

Each of the memory arrays 20[1] to 20[m] includes a plurality of the memory cells 10. The conductor 240b included in each the memory cell 10 is electrically connected to the conductor 240b in an upper layer and the conductor 240b in a lower layer.

As illustrated in FIG. 57, the conductor 240b is shared between the adjacent memory cells 10. In the adjacent memory cells 10, the components in the right memory cell and the components in the left memory cell are placed symmetrically about the conductor 240b.

In the above-described memory array 20, the plurality of memory arrays 20[1] to 20[m] can be provided to be stacked. When the memory arrays 20[1] to 20[m] included in the memory array 20 are placed in the direction perpendicular to the surface of a substrate provided with the driver circuit 21, the memory density of the memory cells 10 can be increased. Moreover, the memory array 20 can be formed by repeating the same manufacturing process in the perpendicular direction. The manufacturing cost of the memory array 20 in the storage device 300 can be reduced.

This embodiment can be combined with the other embodiments as appropriate.

### Embodiment 4

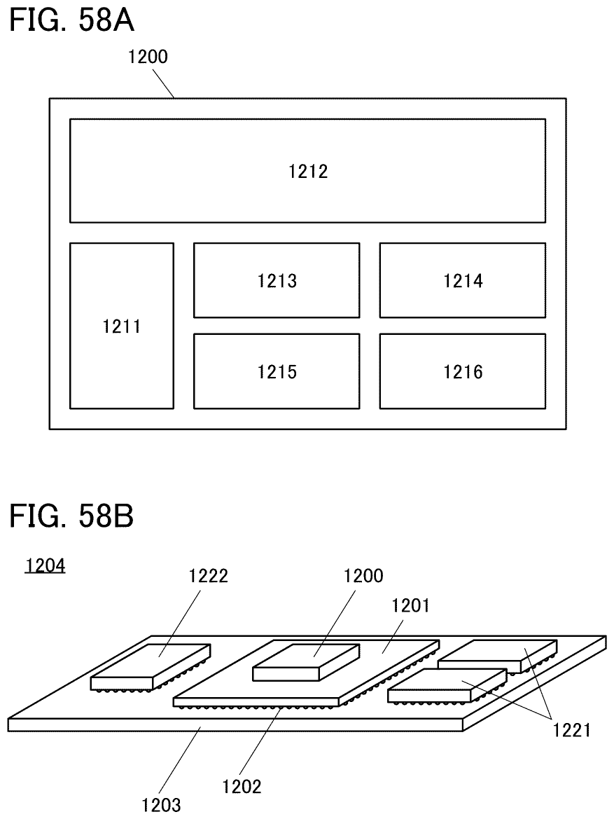

In this embodiment, an example of a chip on which the storage device of one embodiment of the present invention is mounted will be described with reference to FIG. 58A and FIG. 58B.

A plurality of circuits (systems) are mounted on a chip 1200 illustrated in FIG. 58A and FIG. 58B. A technique for integrating a plurality of circuits (systems) into one chip is referred to as system on chip (SoC) in some cases.

As illustrated in FIG. 58A, the chip 1200 includes a CPU 1211, a GPU 1212, one or a plurality of analog arithmetic units 1213, one or a plurality of memory controllers 1214, one or a plurality of interfaces 1215, one or a plurality of network circuits 1216, and the like.

The chip 1200 is provided with a bump (not illustrated) and is connected to a first surface of a package substrate 1201 as illustrated in FIG. 58B. A plurality of bumps 1202 are provided on a rear side of the first surface of the package substrate 1201, and the package substrate 1201 is connected to a motherboard 1203.

Storage devices such as a DRAM 1221 and a flash memory 1222 may be provided over the motherboard 1203. For example, the DOSRAM described in the above embodiment can be used as the DRAM 1221. This can make the DRAM 1221 have low power consumption, operate at high speed, and have a large capacity.

The CPU 1211 preferably includes a plurality of CPU cores. The GPU 1212 preferably includes a plurality of GPU cores. The CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a number of data and thus can be used for image processing or product-sum operation. When an image processing circuit or a product-sum operation circuit using the OS transistor described in the above embodiment is provided in the GPU 1212, image processing or product-sum operation can be performed with low power consumption.

Since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit for a LAN (Local Area Network) or the like. The network circuit 1216 may also include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 5

In this embodiment, electronic components, electronic appliances, a large computer, space equipment, and a data center (also referred to as DC) in which the semiconductor device described in the above embodiment can be used will be described. Electronic components, electronic appliances, a large computer, space equipment, and a data center in which the semiconductor device of one embodiment of the present invention is used are effective in improving performance, e.g., reducing power consumption.

### [Electronic Component]

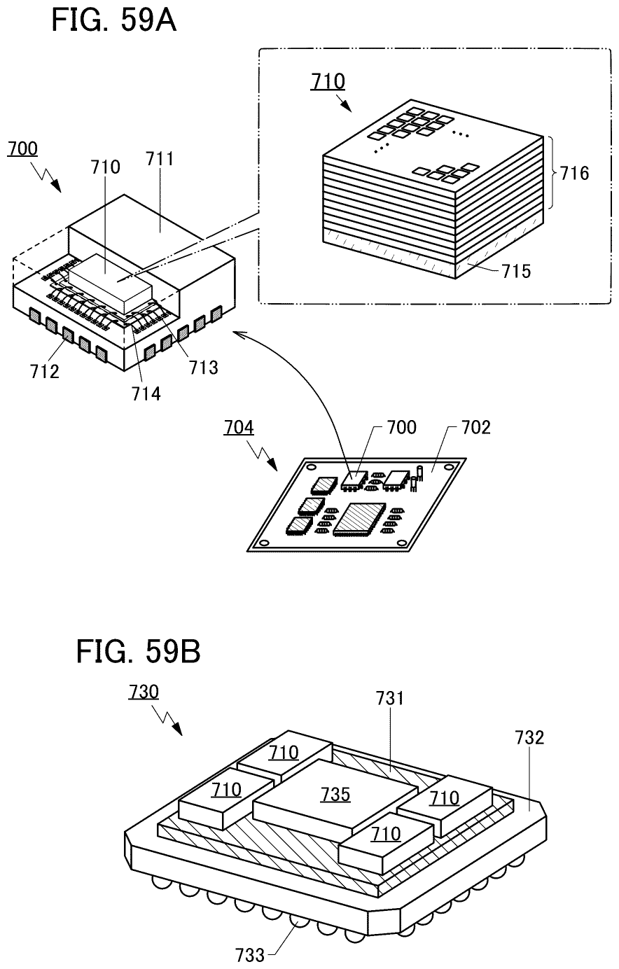

FIG. 59A is a perspective view of a substrate (a circuit board 704) on which an electronic component 700 is mounted. The electronic component 700 illustrated in FIG. 59A includes a semiconductor device 710 in a mold 711. Some components are omitted in FIG. 59A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 59B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU, a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 59B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Appliance]

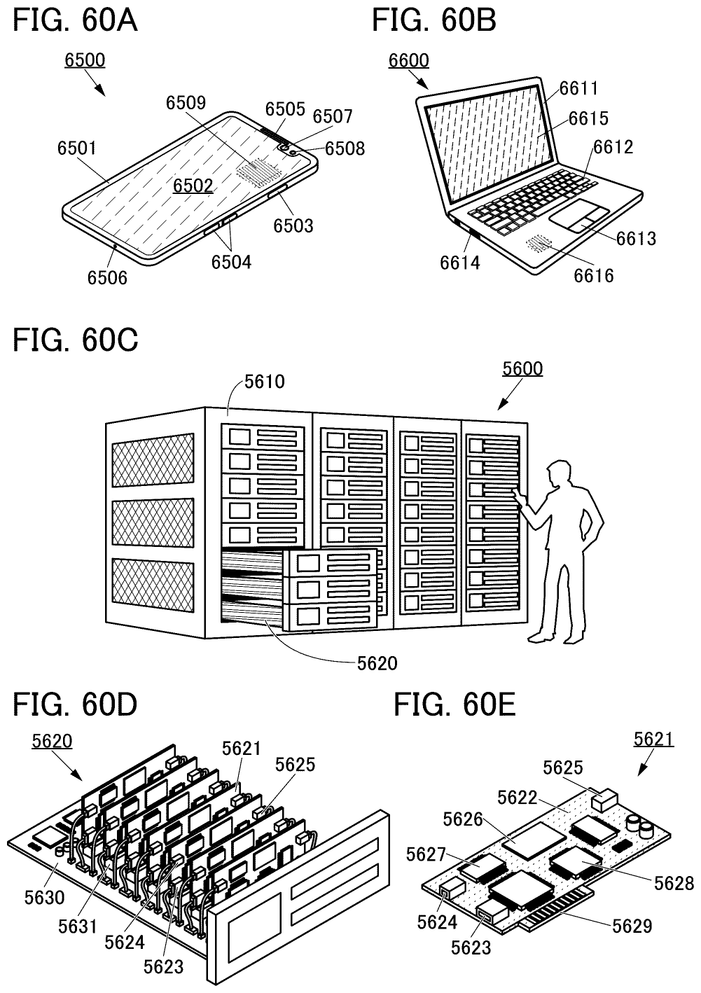

FIG. 60A is a perspective view of an electronic appliance 6500. The electronic appliance 6500 illustrated in FIG. 60A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a storage device are provided as the control device 6509, for example. The semiconductor device of one embodiment of the present invention can be used for the display portion 6502, the control device 6509, and the like, for example.

An electronic appliance 6600 illustrated in FIG. 60B is an information terminal that can be used as a laptop personal computer. The electronic appliance 6600 includes a housing 6611, a keyboard 6612, a pointing device 6613, an external connection port 6614, a display portion 6615, a control device 6616, and the like. One or more selected from a CPU, a GPU, and a storage device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 60C is a perspective view of a large computer 5600. In the large computer 5600 illustrated in FIG. 60C, a plurality of rack mount computers 5620 are stored in a rack 5610. Note that the large computer 5600 may be referred to as a supercomputer.

The computer 5620 can have a structure in a perspective view of FIG. 60D, for example. In FIG. 60D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 60E is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 60E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

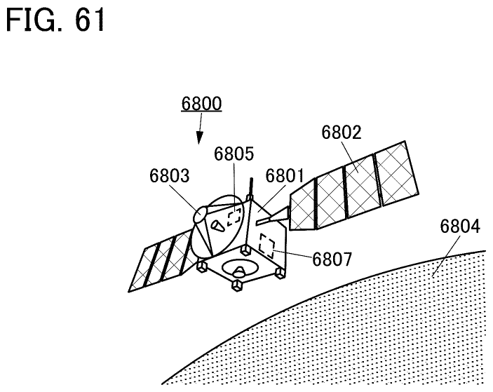

FIG. 61 illustrates an artificial satellite 6800 as an example of space equipment. The artificial satellite 6800 includes a body 6801, a solar panel 6802, an antenna 6803, a secondary battery 6805, and a control device 6807. FIG. 61 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 61, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed with one or more selected from a CPU, a GPU, and a storage device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for a device for space, such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. Long-term data management needs an increase in building size owing to installation of storages and servers for storing an enormous amount of data, stable electric power for data retention, cooling equipment necessary for data retention, and the like.

With use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

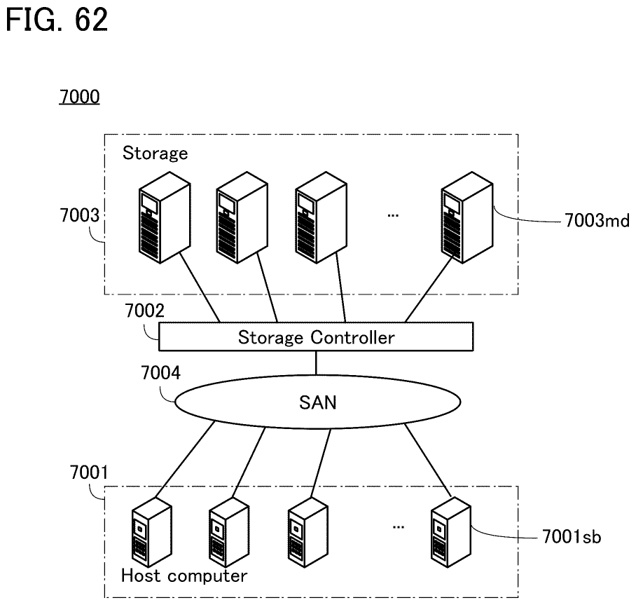

FIG. 62 illustrates a storage system that can be used in a data center. A storage system 7000 illustrated in FIG. 62 includes a plurality of servers 7001sb as a host 7001 (indicated as “Host Computer” in the diagram). The storage system 7000 includes a plurality of storage devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten time required for data storage and output.

The above-described cache memory is used in the storage control circuit 7002 and the storage 7003. The data transmitted between the host 7001 and the storage 7003 is stored in the cache memory in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic appliance, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. The semiconductor device of one embodiment of the present invention can be effectively used as one of the global warming countermeasures because of its low power consumption.

The configuration, structure, method, or the like described in this embodiment can be used in combination with the configuration, structure, method, or the like described in the other embodiments and the like as appropriate.

### EXAMPLE

In this example, the barrier property against oxygen and hydrogen of a silicon nitride film was evaluated. Specifically, samples (Sample 1A to Sample 1D and Sample 2A to Sample 2F) each including a stacked-layer film including a silicon nitride film were fabricated and analyzed by SIMS.

### [Fabrication of Samples]

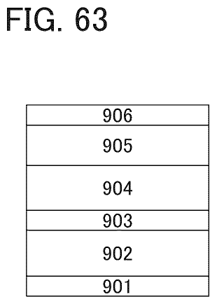

FIG. 63A shows a stacked-layer structure of the fabricated stacked film. As illustrated in FIG. 63A, the stacked-layer film includes a layer 901, a layer 902 over the layer 901, a layer 903 over the layer 902, a layer 904 over the layer 903, a layer 905 over the layer 904, and a layer 906 over the layer 905.

A silicon substrate was prepared as the layer 901 which is common between Sample 1A to Sample 1D and Sample 2A to Sample 2F. A stacked-layer structure of a 100-nm-thick silicon oxide film formed by thermal oxidation treatment and a 100-nm-thick silicon oxynitride film deposited over the silicon oxide film by a PECVD method was used as the layer 902.

In Sample 1A, Sample 1B, Sample 2A, and Sample 2B, a 1.4-nm-thick silicon nitride film deposited by a PEALD method was used as the layer 903. In Sample 1C, Sample 1D, Sample 2C, and Sample 2D, a 1.8-nm-thick silicon nitride film deposited by a PEALD method was used as the layer 903. In Sample 2E and Sample 2F, a 3.3-nm-thick silicon nitride film deposited by a PEALD method was used as the layer 903.

Note that the thickness of the layer 903 was calculated by length measurement on the basis of the observation results of the cross-sectional STEM images.

In all of Sample 1A to Sample 1D and Sample 2A to Sample 2F, a 50-nm-thick silicon oxynitride film deposited by a PECVD method was used as the layer 904.

In Sample 1A to Sample 1D, a 50-nm-thick silicon oxide film containing ¹⁸O deposited by a sputtering method was used as the layer 905. Here, for the deposition of the silicon oxide film, a silicon oxide (SiO₂) target was used as a target, and an ¹⁸O₂ gas was used as a deposition gas.

In Sample 2A and Sample 2F, a 50-nm-thick silicon oxynitride film deposited by a PECVD method was used as the layer 905. Here, the silicon oxynitride film was deposited using a deuterium (D₂) gas, a SiH₄ gas, and an N₂O gas as deposition gases.

In all of Sample 1A to Sample 1D and Sample 2A to Sample 2F, a 20-nm-thick silicon nitride film deposited by a sputtering method was used as the layer 906.

Next, Sample 1B, Sample 1D, Sample 2B, Sample 2D, and Sample 2F were subjected to heat treatment at 450° C. in a nitrogen atmosphere for one hour. Note that Sample 1A, Sample 1C, Sample 2A, Sample 2C, and Sample 2E were not subjected to the heat treatment. The oxygen (¹⁸O) concentration distributions in Sample 1A to Sample 1D are compared with each other to evaluate the oxygen barrier property of the silicon nitride film used as the layer 903 (how much oxygen passes through the layer 903 by thermal diffusion). In addition, the deuterium (D) concentration distributions in Sample 2A to Sample 2F are compared with each other to evaluate the hydrogen barrier property of the silicon nitride film used as the layer 903 (how much hydrogen passes through the layer 903 by thermal diffusion).

Through the above steps, Sample 1A to Sample 1D and Sample 2A to Sample 2F were fabricated. Table 1 shows structures of the samples.

TABLE 1

| Sample | Thickness of layer 903 | Layer 905 |
|---|---|---|
| 1A | 1.4 nm | Silicon oxide film |
| 1B | | including ¹⁸O) |
| 1C | 1.8 nm | |
| 1D | | |
| 2A | 1.4 nm | Silicon oxynitride film |
| 2B | | (including D) |
| 2C | 1.8 nm | |
| 2D | | |
| 2E | 3.3 nm | |
| 2F | | |

### [Measurement of Oxygen Concentration]

Sample 1A to Sample 1D were analyzed by SIMS. Note that the analysis direction of the SIMS analysis is a direction from the substrate toward the layer 906. The oxygen (¹⁸O) profiles were obtained by the SIMS analysis.

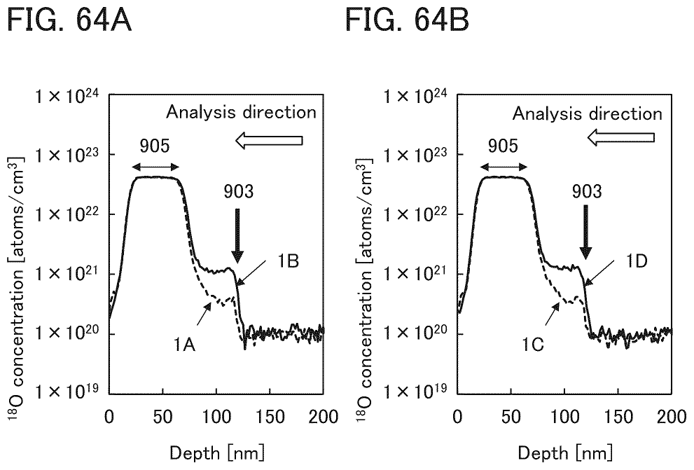

FIG. 64A and FIG. 64B show the results of the oxygen (¹⁸O) profiles of Sample 1A to Sample 1D. In FIG. 64A and FIG. 64B, the horizontal axis represents a depth [nm] from the sample surface, and the left-end position indicating a depth of 0 nm corresponds to the sample surface (the surface of the layer 906). The vertical axis represents the 180 concentration [atoms/cm³]. A dotted line shown in FIG. 64A is the oxygen (¹⁸O) profile of Sample 1A, and a solid line shown in FIG. 64A is the oxygen (¹⁸O) profile of Sample 1B. A dotted line shown in FIG. 64B is the oxygen (¹⁸O) profile of Sample 1C, and a solid line shown in FIG. 64B is the oxygen (¹⁸O) profile of Sample 1D.

FIG. 64A and FIG. 64B reveal that Sample 1B and Sample 1D subjected to the above heat treatment exhibit no diffusion of oxygen (¹⁸O) from the layer 905 into the silicon oxynitride film used as the layer 902. Thus, it can be seen that thermal diffusion of oxygen (¹⁸O) contained in the layer 905 is inhibited by the silicon nitride film used as the layer 903.

Accordingly, it can be seen that the silicon nitride film has a barrier property against oxygen. Specifically, it was found that when the thickness of the silicon nitride film is greater than or equal to 1.4 nm, the silicon nitride film has a high barrier property against oxygen. Thus, when a silicon nitride film having a barrier property against oxygen is used as each of the insulator 223 and the insulator 275 illustrated in FIG. 1B and the like, the amount of oxygen supplied to the source region and the drain region of the oxide semiconductor 230, which are surrounded by the insulator 223 and the insulator 275, can be reduced.

### [Measurement of Hydrogen Concentration]

Sample 2A to Sample 2F were analyzed by SIMS. Note that the analysis direction of the SIMS analysis is a direction from the substrate toward the layer 906. The deuterium (D) profiles were obtained by the SIMS analysis.

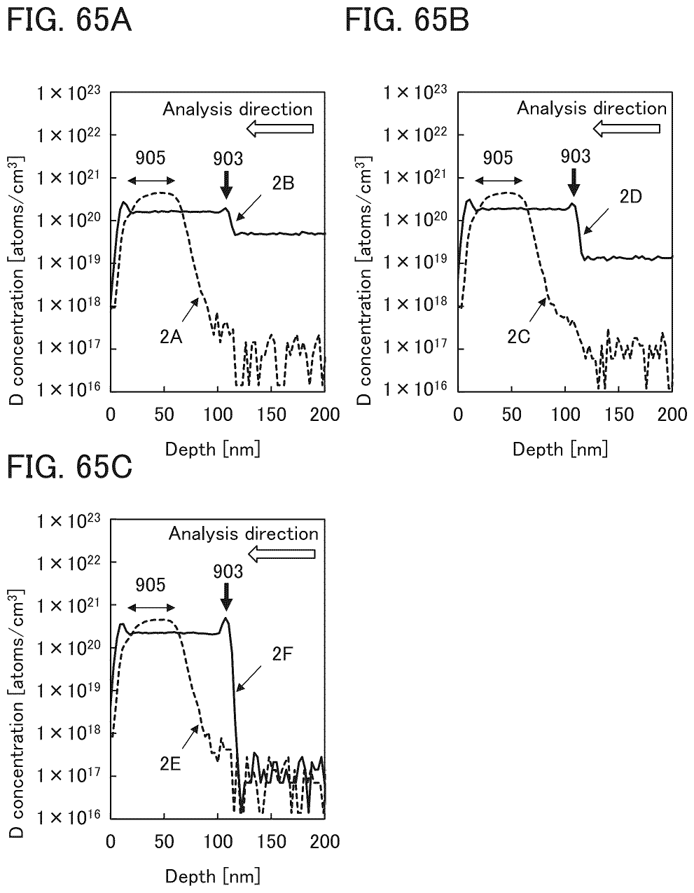

FIG. 65A to FIG. 65C show the results of the deuterium (D) profiles of Sample 2A to Sample 2F. In FIG. 65A to FIG. 65C, the horizontal axis represents a depth [nm] from the sample surface, and the left-end position indicating a depth of 0 nm corresponds to the sample surface (the surface of the layer 906). The vertical axis represents the D concentration [atoms/cm³]. A dotted line shown in FIG. 65A is the deuterium (D) profile of Sample 2A, and a solid line shown in FIG. 65A is the deuterium (D) profile of Sample 2B. A dotted line shown in FIG. 65B is the deuterium (D) profile of Sample 2C, and a solid line shown in FIG. 65B is the deuterium (D) profile of Sample 2D. A dotted line shown in FIG. 65C is the deuterium (D) profile of Sample 2E, and a solid line shown in FIG. 65C is the deuterium (D) profile of Sample 2F.

FIG. 65A to FIG. 65C reveal that Sample 2B and Sample 2D subjected to the above heat treatment exhibit diffusion of deuterium (D) from the layer 905 into the silicon oxynitride film used as the layer 902. Note that diffusion of deuterium (D) in Sample 2D was inhibited more than diffusion of deuterium (D) in Sample 2B. FIG. 65A to FIG. 65C reveal that Sample 2F subjected to the above heat treatment exhibit no diffusion of deuterium (D) from the layer 905 into the silicon oxynitride film used as the layer 902. Thus, it was found that thermal diffusion of deuterium (D) contained in the layer 905 is inhibited more severely with an increase in the thickness of the silicon nitride film used as the layer 903 is larger.

Accordingly, it can be seen that the silicon nitride film has a barrier property against hydrogen. Specifically, it was found that when the thickness of the silicon nitride film is greater than or equal to 3.3 nm, the silicon nitride film has a high barrier property against hydrogen. Accordingly, the use of a silicon nitride film having a barrier property against hydrogen for the insulator 223 and the insulator 275 illustrated in FIG. 1B or the like can inhibit diffusion of hydrogen into the channel formation region in the oxide semiconductor 230 and can keep a low donor concentration in the channel formation region.

The configuration, structure, method, or the like described in this example can be used in combination with the configuration, structure, method, or the like described in the other embodiments and the like as appropriate.

### REFERENCE NUMERALS

10_A: memory cell, 10_B: memory cell, 10: memory cell, 11: transistor, 12: capacitor, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51: functional circuit, 52_a: transistor, 52_b: transistor, 52: transistor, 53_a: transistor, 53_b: transistor, 53: transistor, 54_a: transistor, 54_b: transistor, 54: transistor, 55_a: transistor, 55_b: transistor, 55: transistor, 70: repeating unit, 71_A: pre-charge circuit, 71_B: pre-charge circuit, 72_A: switch circuit, 72_B: switch circuit, 73: writing reading circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 153: conductor, 154: insulator, 160a: conductor, 160b: conductor, 160: conductor, 200A: transistor, 200a: transistor, 200b: transistor, 200: transistor, 206: conductor, 207: conductor, 208: insulator, 209: conductor, 210: insulator, 212: insulator, 214: insulator, 215a: conductor, 215b: conductor, 215: conductor, 216: insulator, 222: insulator, 223a: insulator, 223b: insulator, 223c: insulator, 223: insulator, 225: insulator, 230a: oxide semiconductor, 230b: oxide semiconductor, 230c: oxide semiconductor, 230: oxide semiconductor, 231a: region, 231b: region, 231c: region, 240a: conductor, 240b: conductor, 240c: conductor, 241a: insulator, 241b: insulator, 241c: insulator, 242a1: conductor, 242a2: conductor, 242a: conductor, 242b1: conductor, 242b2: conductor, 242b: conductor, 246a: conductor, 246b: conductor, 250a: insulator, 250b: insulator, 250c: insulator, 250d: insulator, 250: insulator, 255a: insulator, 255b: insulator, 255: insulator, 260a: conductor, 260b: conductor, 260: conductor, 271a1: insulator, 271a2: insulator, 271a: insulator, 271b1: insulator, 271b2: insulator, 271b: insulator, 275: insulator, 280: insulator, 282: insulator, 283: insulator, 284: insulator, 285: insulator, 286: insulator, 287: insulator, 288: insulator, 289: insulator, 290: opening portion, 291: insulator, 292: insulator, 293: insulator, 294: conductor, 295: insulator, 300A: storage device, 300: storage device, 310: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 901: layer, 902: layer, 903: layer, 904: layer, 905: layer, 906: layer, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power supply button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: storage device, 7003: storage

1. A semiconductor device comprising:
a first insulator;
an oxide semiconductor over the first insulator;
a first conductor and a second conductor over the oxide semiconductor;
a second insulator over the first insulator, the first conductor, and the second conductor;
a third insulator over the oxide semiconductor; and
a third conductor over the third insulator,
wherein the oxide semiconductor includes a first region overlapping with the first conductor, a second region overlapping with the second conductor, and a third region positioned between the first region and the second region,
wherein the second insulator includes an opening portion in a region overlapping with the third region,
wherein at least part of each of the third insulator and the third conductor is provided in the opening portion,
wherein each of the first region and the second region is in contact with the first insulator and the second insulator,
wherein the third region is in contact with the first insulator and the third insulator,
wherein each of the first insulator and the second insulator contains silicon and nitrogen, and
wherein the first insulator includes a region with a thickness greater than or equal to 1.0 nm and less than or equal to 5.0 nm.

2. A semiconductor device comprising:
a first insulator;
an oxide semiconductor over the first insulator;
a first conductor and a second conductor over the oxide semiconductor;
a second insulator over the first insulator, the first conductor, and the second conductor;
a third insulator over the oxide semiconductor;
a third conductor over the third insulator; and
a fourth insulator over the third insulator and the third conductor;
wherein the oxide semiconductor includes a first region overlapping with the first conductor, a second region overlapping with the second conductor, and a third region positioned between the first region and the second region,
wherein the second insulator includes an opening portion in a region overlapping with the third region,
wherein at least part of each of the third insulator and the third conductor is provided in the opening portion,
wherein each of the first region and the second region is in contact with the first insulator and the second insulator,
wherein the third region is in contact with the first insulator and the third insulator,
wherein each of the first insulator, the second insulator, and the fourth insulator contains silicon and nitrogen,
wherein the first insulator includes a region with a thickness smaller than a thickness of the fourth insulator, and
wherein a concentration of an impurity element of the first insulator is higher than a concentration of the impurity element of the fourth insulator.

3. The semiconductor device according to claim 2,
wherein the impurity element is at least one of fluorine, chlorine, bromine, iodine, hydrogen, and carbon.

4. The semiconductor device according to claim 1, further comprising a fourth conductor below the first insulator,
wherein the fourth conductor includes a region overlapping with the third conductor with the first insulator, the oxide semiconductor, and the third insulator therebetween.

5. The semiconductor device according to claim 1,
wherein the first insulator has a belt-like shape and is provided to extend in a direction in which the third conductor extends.

6. The semiconductor device according to claim 1,
wherein the first insulator has an island shape,
wherein a side end portion of the first insulator is aligned with a side end portion of the oxide semiconductor, and
wherein the second insulator is in contact with a side surface of the first insulator.

7. The semiconductor device according to claim 1,
wherein the third region of the oxide semiconductor includes a crystal on its side surface in the vicinity of the third insulator,
wherein the crystal has a crystal structure in which a plurality of layers are stacked, and
wherein each of the layers included in the crystal extends parallel or substantially parallel to a side surface of the oxide semiconductor.

8. A semiconductor device comprising:
a first insulator;
a second insulator over the first insulator;
an oxide semiconductor being over the first insulator and covering a top surface and a side surface of the second insulator;
a first conductor and a second conductor over the oxide semiconductor;
a third insulator over the first insulator, the first conductor, and the second conductor;
a fourth insulator over the oxide semiconductor; and
a third conductor over the fourth insulator,
wherein the oxide semiconductor includes a first region overlapping with the first conductor, a second region overlapping with the second conductor, and a third region positioned between the first region and the second region,
wherein the third insulator includes an opening portion in a region overlapping with the third region,
wherein at least part of each of the fourth insulator and the third conductor is provided in the opening portion,
wherein each of the first region and the second region is in contact with the first insulator, the second insulator, and the third insulator,
wherein the third region is in contact with the first insulator, the second insulator, and the fourth insulator,
wherein each of the first insulator, the second insulator, and the third insulator contains silicon and nitrogen, and
wherein the first insulator includes a region with a thickness greater than or equal to 1.0 nm and less than or equal to 5.0 nm.

9. The semiconductor device according to claim 8,
wherein a height of the second insulator is larger than a length of the second insulator in a direction in which the third conductor extends.

10. The semiconductor device according to claim 9, further comprising a fifth insulator over the fourth insulator and the third conductor,
wherein the first insulator includes a region with a thickness smaller than a thickness of the fifth insulator, and
wherein a concentration of an impurity element of the first insulator is higher than a concentration of the impurity element of the fifth insulator.

11. The semiconductor device according to claim 10,
wherein the impurity element is at least one of fluorine, chlorine, bromine, iodine, hydrogen, and carbon.

12. The semiconductor device according to claim 9,
wherein the third region of the oxide semiconductor includes a crystal on its side surface in the vicinity of the fourth insulator,
wherein the crystal has a crystal structure in which a plurality of layers are stacked, and
wherein each of the layers included in the crystal extends parallel or substantially parallel to a surface of the oxide semiconductor.

13. A semiconductor device comprising:
a first insulator;
a second insulator and a third insulator over the first insulator and a fourth insulator positioned between the second insulator and the third insulator;
an oxide semiconductor over the second insulator, the third insulator, and the fourth insulator;
a first conductor and a second conductor over the oxide semiconductor;
a fifth insulator over the first insulator, the first conductor, and the second conductor;
a sixth insulator over the oxide semiconductor; and
a third conductor over the sixth insulator;
wherein the oxide semiconductor includes a first region overlapping with the first conductor, a second region overlapping with the second conductor, and a third region positioned between the first region and the second region,
wherein the fifth insulator includes an opening portion in a region overlapping with the third region,
wherein at least part of each of the sixth insulator and the third conductor is provided in the opening portion,
wherein the first region is in contact with the second insulator and the fifth insulator,
wherein the second region is in contact with the third insulator and the fifth insulator,
wherein the third region is in contact with the fourth insulator and the sixth insulator,
wherein each of the second insulator, the third insulator, and the fifth insulator contains silicon and nitrogen,
wherein thicknesses of the second insulator, the third insulator, and the fourth insulator are equal to each other, and
wherein the second insulator includes a region with a thickness greater than or equal to 1.0 nm and less than or equal to 5.0 nm.

14. A semiconductor device comprising:
a first insulator;
a second insulator and a third insulator over the first insulator and a fourth insulator positioned between the second insulator and the third insulator;
an oxide semiconductor over the second insulator, the third insulator, and the fourth insulator;
a first conductor and a second conductor over the oxide semiconductor;
a fifth insulator over the first insulator, the first conductor, and the second conductor;
a sixth insulator over the oxide semiconductor;
a third conductor over the sixth insulator; and
a seventh insulator over the sixth insulator and the third conductor,
wherein the oxide semiconductor includes a first region overlapping with the first conductor, a second region overlapping with the second conductor, and a third region positioned between the first region and the second region,
wherein the fifth insulator includes an opening portion in a region overlapping with the third region,
wherein at least part of each of the sixth insulator and the third conductor is provided in the opening portion,
wherein the first region is in contact with the second insulator and the fifth insulator,
wherein the second region is in contact with the third insulator and the fifth insulator,
wherein the third region is in contact with the fourth insulator and the sixth insulator,
wherein each of the second insulator, the third insulator, the fifth insulator, and the seventh insulator contains silicon and nitrogen,
wherein thicknesses of the second insulator, the third insulator, and the fourth insulator are equal to each other,
wherein the second insulator includes a region with a thickness smaller than a thickness of the seventh insulator, and
wherein a concentration of an impurity element of the second insulator is higher than a concentration of the impurity element of the seventh insulator.

15. The semiconductor device according to claim 14,
wherein the impurity element is at least one of fluorine, chlorine, bromine, iodine, hydrogen, and carbon.

16. The semiconductor device according to claim 13, further comprising a fourth conductor below the first insulator,
wherein the fourth conductor includes a region overlapping with the third conductor with the first insulator, the fourth insulator, the oxide semiconductor, and the sixth insulator therebetween.

17. The semiconductor device according to claim 13,
wherein each of the second insulator, the third insulator, and the fourth insulator has a belt-like shape and is provided to extend in a direction in which the third conductor extends.

18. The semiconductor device according to claim 13,
wherein each of the second insulator, the third insulator, and the fourth insulator has an island shape,
wherein a side end portion of the second insulator is aligned with a side end portion of the oxide semiconductor,
wherein a side end portion of the third insulator is aligned with a side end portion of the oxide semiconductor,
wherein a side end portion of the fourth insulator is aligned with a side end portion of the oxide semiconductor, and
wherein the fifth insulator is in contact with a side surface of the second insulator and a side surface of the third insulator.

19. The semiconductor device according to claim 13,
wherein the third region of the oxide semiconductor includes a crystal on its side surface in the vicinity of the sixth insulator,
wherein the crystal has a crystal structure in which a plurality of layers are stacked, and
wherein each of the layers included in the crystal extends parallel or substantially parallel to a side surface of the oxide semiconductor.

20. A semiconductor device comprising:
a first insulator;
a second insulator and a third insulator over the first insulator and a fourth insulator positioned between the second insulator and the third insulator;
a fifth insulator over the second insulator, the third insulator, and the fourth insulator;
an oxide semiconductor being over the second insulator, the third insulator, and the fourth insulator and covering a top surface and a side surface of the fifth insulator,
a first conductor and a second conductor over the oxide semiconductor;
a sixth insulator over the first insulator, the first conductor, and the second conductor;
a seventh insulator over the oxide semiconductor; and
a third conductor over the seventh insulator;
wherein the oxide semiconductor includes a first region overlapping with the first conductor, a second region overlapping with the second conductor, and a third region positioned between the first region and the second region,
wherein the sixth insulator includes an opening portion in a region overlapping with the third region,
wherein at least part of each of the seventh insulator and the third conductor is provided in the opening portion,
wherein the first region is in contact with the second insulator, the fifth insulator, and the sixth insulator,
wherein the second region is in contact with the third insulator, the fifth insulator, and the sixth insulator,
wherein the third region is in contact with the fourth insulator, the fifth insulator, and the seventh insulator,
wherein each of the second insulator, the third insulator, the fifth insulator, and the seventh insulator contains silicon and nitrogen,
wherein thicknesses of the second insulator, the third insulator, and the fourth insulator are equal to each other, and
wherein the second insulator includes a region with a thickness greater than or equal to 1.0 nm and less than or equal to 5.0 nm.

21. The semiconductor device according to claim 20,
wherein a height of the fifth insulator is larger than a length of the fifth insulator in a direction in which the third conductor extends.

22. The semiconductor device according to claim 21, further comprising an eighth insulator over the seventh insulator and the third conductor,
wherein the second insulator includes a region with a thickness smaller than a thickness of the eighth insulator, and
wherein a concentration of an impurity element of the second insulator is higher than a concentration of the impurity element of the eighth insulator.

23. The semiconductor device according to claim 22,
wherein the impurity element is at least one of fluorine, chlorine, bromine, iodine, hydrogen, and carbon.

24. The semiconductor device according to claim 21,
wherein the third region of the oxide semiconductor includes a crystal on its side surface in the vicinity of the seventh insulator,
wherein the crystal has a crystal structure in which a plurality of layers are stacked, and
wherein each of the layers included in the crystal extends parallel or substantially parallel to a surface of the oxide semiconductor.
